(19) United States
(12) Patent Application Publication
(10) Pub. No.: US 2023/0337453 A1
(43) Pub. Date: Oct. 19, 2023

(54) Light-Emitting Device, Display Panel, Light-Emitting Apparatus, Display Device, Electronic Device, and Lighting Device

(71) Applicant: Semiconductor Energy Laboratory Co., Ltd., Kanagawa-ken (JP)

(72) Inventors: Takeyoshi WATABE, Atsugi, Kanagawa (JP); Airi UEDA, Zama, Kanagawa (JP); Yuta KAWANO, Yokohama, Kanagawa (JP); Nobuharu OHSAWA, Zama, Kanagawa (JP); Satoshi SEO, Sagamihara, Kanagawa (JP)

(73) Assignee: Semiconductor Energy Laboratory Co., Ltd., Kanagawa-ken (JP)

(21) Appl. No.: 18/008,868

(22) PCT Filed: Jun. 3, 2021
(86) PCT No.: PCT/IB2021/054850

§ 371 Date: Dec. 7, 2022

(30) Foreign Application Priority Data
Jun. 12, 2020 (JP) 2020-102473

(51) Int. Cl. H10K 50/13; H10K 50/858; H10K 59/121

(52) U.S. Cl. CPC H10K 50/13; H10K 50/858; H10K 59/1213; H10K 2102/3026

(57) ABSTRACT

A novel optical functional device that is highly convenient, useful, or reliable is provided. A light-emitting device includes a first electrode, a second electrode, and an EL layer. The first electrode has a first transmittance; the second electrode overlaps with the first electrode. The second electrode has a second transmittance higher than the first transmittance. The EL layer is interposed between the first electrode and the second electrode and includes a first region, a second region, and a third region. The first region is interposed between the second region and the third region. The second region is interposed between the first electrode and the first region and has a first refractive index. The third region is interposed between the first region and the second electrode and has a second refractive index. The second refractive index is lower than the first refractive index. The EL layer includes a first unit, a second unit, and an intermediate layer. The intermediate layer is interposed between the first unit and the second unit and has a function of supplying a hole to one of the first unit and the second unit and supplying an electron to the other.

### TECHNICAL FIELD

One embodiment of the present invention relates to a light-emitting device, a display panel, a light-emitting apparatus, a light-emitting apparatus, an electronic device, or a lighting device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Thus, more specifically, examples of the technical field of one embodiment of the present invention disclosed in this specification include a semiconductor device, a display device, a light-emitting apparatus, a power storage device, a memory device, a driving method thereof, and a manufacturing method thereof.

### BACKGROUND ART

Light-emitting devices (organic EL elements) including organic compounds and utilizing electroluminescence (EL) have been put into practical use. In the basic structure of such light-emitting devices, an organic compound layer containing a light-emitting material (an EL layer) is interposed between a pair of electrodes. Carriers (hole and electrons) are injected by application of voltage to the element, and recombination energy of the carriers is used, whereby light emission can be obtained from the light-emitting material.

Such light-emitting devices are of self-light-emitting type and thus have advantages over liquid crystal, such as high visibility and no need for backlight when used for pixels of a display, and are suitable as flat panel display elements. Displays using such light-emitting devices are also highly advantageous in that they can be fabricated to be thin and lightweight. Moreover, an extremely fast response speed is also a feature.

Since light-emitting layers of such light-emitting devices can be successively formed two-dimensionally, planar light emission can be achieved. This feature is difficult to realize with point light sources typified by incandescent lamps and LEDs or linear light sources typified by fluorescent lamps; thus, the light-emitting devices also have great potential as planar light sources, which can be applied to lighting and the like.

Displays or lighting devices using light-emitting devices can be suitably used for a variety of electronic devices as described above, and research and development of light-emitting devices has progressed for more favorable characteristics.

Low light extraction efficiency is often a problem in an organic EL device. In particular, the attenuation due to reflection which is caused by a difference in refractive index between adjacent layers is a main cause of a reduction in device efficiency. In order to reduce this effect, a structure including a layer formed using a low refractive index material in an EL layer (see Non-Patent Document 1, for example) has been proposed.

A light-emitting device having this structure can have higher light extraction efficiency and higher external quantum efficiency than a light-emitting device having a conventional structure; however, it is not easy to form such a layer with a low refractive index in an EL layer without adversely affecting other critical characteristics of the light-emitting device. This is because a low refractive index is in a trade-off relationship with a high carrier-transport property or high reliability of a light-emitting device including a layer with a low refractive index. This problem is caused because the carrier-transport property and reliability of an organic compound largely depend on an unsaturated bond, and an organic compound having many unsaturated bonds tends to have a high refractive index.

### REFERENCES

### Patent Documents

[Patent Document 1] Japanese Published Patent Application No. H11-282181
[Patent Document 2] Japanese Published Patent Application No. 2009-91304
[Patent Document 3] U.S. Pat. Application Publication No. 2010/104969

### Non-Patent Document

[Non-Patent Document 1] Jaeho Lee and 12 others, “Synergetic electrode architecture for efficient graphene-based flexible organic light-emitting diodes”, nature COMMUNICATIONS, Jun. 2, 2016, DOI: 10.1038/ncomms 11791.

### SUMMARY OF THE INVENTION

### Problems to Be Solved by the Invention

An object of one embodiment of the present invention is to provide a novel light-emitting device that is highly convenient, useful, or reliable. Another object is to provide a novel display panel that is highly convenient, useful, or reliable. Another object is to provide a novel light-emitting apparatus that is highly convenient, useful, or reliable. Another object is to provide a novel display device that is highly convenient, useful, or reliable. Another object is to provide a novel electronic device that is highly convenient, useful, or reliable. Another object is to provide a novel lighting device that is highly convenient, useful, or reliable. Another object is to provide a novel light-emitting device, a novel display panel, a novel light-emitting apparatus, a novel display device, a novel electronic device, or a novel lighting device.

Note that the description of these objects does not preclude the existence of other objects. One embodiment of the present invention does not have to achieve all these objects. Other objects will be apparent from the description of the specification, the drawings, the claims, and the like, and other objects can be derived from the description of the specification, the drawings, the claims, and the like.

### Means for Solving the Problems

(1) One embodiment of the present invention includes a first electrode, a second electrode, and an EL layer.

The first electrode has a first transmittance T1. The second electrode includes a region overlapping with the first electrode, and the second electrode has a second transmittance T2. The second transmittance T2 is higher than the first transmittance T1.

The EL layer includes a region interposed between the first electrode and the second electrode; the EL layer includes a first region, a second region, and a third region; and the first region includes a portion interposed between the second region and the third region.

The second region includes a region interposed between the first electrode and the first region, and the second region has a first refractive index n1.

The third region includes a region interposed between the first region and the second electrode; the third region has a second refractive index n2; and the second refractive index n2 is lower than the first refractive index n1.

The EL layer includes a first unit, a second unit, and an intermediate layer, and the intermediate layer is interposed between the first unit and the second unit.

The intermediate layer has a function of supplying a hole to one of the first unit and the second unit and supplying an electron to the other.

The first unit is interposed between the first electrode and the intermediate layer, and the first unit includes a first layer including a light-emitting material.

The second unit is interposed between the intermediate layer and the second electrode, and the second unit includes a second layer including a light-emitting material.

The first region includes the first layer including a light-emitting material and the second layer including a light-emitting material.

Thus, light emitted from the first region can be efficiently extracted from the second electrode. This structure enables high luminance emission while the current density is kept low. Reliability can be improved. The driving voltage can be reduced in comparison with that of the light-emitting device with the same luminance. Power consumption can be reduced. As a result, a novel optical functional device that is highly convenient, useful, or reliable can be provided.

(2) Another embodiment of the present invention is the above light-emitting device in which the first layer including a light-emitting material has a function of emitting blue light and the second layer including a light-emitting material also has a function of emitting blue light.

Thus, the layer including a light-emitting material and the layer including a light-emitting material can be placed in positions such that light emitted from the layer and light emitted from the layer intensify each other. The layers each including a light-emitting material can be placed in a position such that the light emitted from the layers each including a light-emitting material and light reflected by the electrode intensify each other. Light emitted from the first region can be efficiently extracted from the second electrode. As a result, a novel optical functional device that is highly convenient, useful, or reliable can be provided.

(3) Another embodiment of the present invention is the above light-emitting device in which the second unit includes a third layer including a light-emitting material.

The first layer including a light-emitting material has a function of emitting blue light; the second layer including a light-emitting material has a function of emitting red light; and the third layer including a light-emitting material has a function of emitting green light.

Thus, light of a plurality of colors can be emitted from the first region. The layers each including a light-emitting material can be placed in a position such that the light emitted from the layers each including a light-emitting material and light reflected by the first electrode intensify each other. The layers each including a light-emitting material can be arranged in accordance with the wavelengths of light emitted from the layers each including a light-emitting material. The light-emitting device can have an excellent color rendering property. Light emitted from the first region can be efficiently extracted from the second electrode. As a result, a novel optical functional device that is highly convenient, useful, or reliable can be provided.

(4) Another embodiment of the present invention is the above light-emitting device in which the third region has a more excellent electron-transport property than the second region.

(5) Another embodiment of the present invention is the above light-emitting device in which the third region has a more excellent hole-transport property than the second region.

(6) One embodiment of the present invention is a display panel including a functional layer and a pixel.

The functional layer includes a pixel circuit, and the pixel includes the pixel circuit and the above light-emitting device. The first electrode includes a region interposed between the functional layer and the second electrode, and the first electrode is electrically connected to the pixel circuit.

Thus, light emission of the light-emitting device can be controlled using the pixel circuit. The image data can be displayed. As a result, a novel optical functional device that is highly convenient, useful, or reliable can be provided.

(7) One embodiment of the present invention is a light-emitting apparatus including the above light-emitting device and a transistor or a substrate.

(8) One embodiment of the present invention is a display device including the light-emitting device and a transistor or a substrate.

(9) One embodiment of the present invention is a lighting device including the light-emitting apparatus and a housing.

(10) One embodiment of the present invention is an electronic device including the above display device, and a sensor, an operation button, a speaker, or a microphone.

Although a block diagram in which components are classified by their functions and shown as independent blocks is shown in the drawing attached to this specification, it is difficult to completely separate actual components according to their functions and one component can relate to a plurality of functions.

Note that the light-emitting apparatus in this specification includes an image display device using a light-emitting element. Moreover, the light-emitting apparatus may also include a module in which a connector such as an anisotropic conductive film or a TCP (Tape Carrier Package) is connected to a light-emitting element, a module in which a printed wiring board is provided on the tip of a TCP, or a module in which an IC (integrated circuit) is directly mounted on a light-emitting element by a COG (Chip On Glass) method. Furthermore, in some cases, lighting equipment or the like includes the light-emitting apparatus.

### Effect of the Invention

According to one embodiment of the present invention, a novel light-emitting device that is highly convenient, useful, or reliable can be provided. A novel display panel that is highly convenient, useful, or reliable can be provided. A novel light-emitting apparatus that is highly convenient, useful, or reliable can be provided. A novel display device that is highly convenient, useful, or reliable can be provided. A novel electronic device that is highly convenient, useful, or reliable can be provided. A novel lighting device that is highly convenient, useful, or reliable can be provided. A novel light-emitting device, a novel display panel, a novel light-emitting apparatus, a novel display device, a novel electronic device, or a novel lighting device can be provided.

Note that the description of these effects does not preclude the existence of other effects. One embodiment of the present invention does not have to have all of these effects. Other effects will be apparent from the description of the specification, the drawings, the claims, and the like and other effects can be derived from the description of the specification, the drawings, the claims, and the like.

### BRIEF DESCRIPTION OF THE DRAWINGS

FIG. 1A and FIG. 1B are diagrams each illustrating a structure of a light-emitting device of an embodiment.

FIG. 2A and FIG. 2B are diagrams each illustrating a structure of a light-emitting device of an embodiment.

FIG. 3A and FIG. 3B are diagrams each illustrating a structure of a light-emitting device of an embodiment.

FIG. 4A and FIG. 4B are diagrams each illustrating a structure of a light-emitting device of an embodiment.

FIG. 5A and FIG. 5B are diagrams each illustrating a structure of a light-emitting device of an embodiment.

FIG. 6A and FIG. 6B are diagrams illustrating a structure of a functional panel of an embodiment.

FIG. 7A to FIG. 7C are diagrams illustrating a structure of a functional panel of an embodiment.

FIG. 8 is a circuit diagram illustrating a structure of a functional panel of an embodiment.

FIG. 9 is a cross-sectional view illustrating a structure of a functional panel of an embodiment.

FIG. 10A and FIG. 10B are cross-sectional views illustrating a structure of a functional panel of an embodiment.

FIG. 11A and FIG. 11B are cross-sectional views illustrating a structure of a functional panel of an embodiment.

FIG. 12A and FIG. 12B are cross-sectional views illustrating a structure of a functional panel of an embodiment.

FIG. 13A and FIG. 13B are conceptual diagrams of an active matrix light-emitting apparatus.

FIG. 14A and FIG. 14B are conceptual diagrams of an active matrix light-emitting apparatus.

FIG. 15 is a conceptual diagram of an active matrix light-emitting apparatus.

FIG. 16A and FIG. 16B are conceptual diagrams of a passive matrix light-emitting apparatus.

FIG. 17A and FIG. 17B are diagrams illustrating a lighting device.

FIG. 18A, FIG. 18B1, FIG. 18B2, and FIG. 18C are diagrams each illustrating an electronic device.

FIG. 19A to FIG. 19C are diagrams each illustrating an electronic device.

FIG. 20 is a diagram illustrating a lighting device.

FIG. 21 is a diagram illustrating a lighting device.

FIG. 22 is a diagram illustrating in-vehicle display devices and lighting devices.

FIG. 23A to FIG. 23C are diagrams illustrating an electronic device.

FIG. 24 is a diagram illustrating structures of light-emitting devices of an example.

FIG. 25 is a diagram illustrating wavelength-ordinary refractive index characteristics of materials used for Light-emitting device 1 to Light-emitting device 3.

FIG. 26 is a diagram illustrating structures of light-emitting devices of an example.

### MODE FOR CARRYING OUT THE INVENTION

A light-emitting device includes a first electrode, a second electrode, and an EL layer; the first electrode has a first transmittance; the second electrode includes a region overlapping with the first electrode; the second electrode has a second transmittance; and the second transmittance is higher than the first transmittance. The EL layer includes a region interposed between the first electrode and the second electrode; the EL layer includes a first region, a second region, and a third region; the first region includes a portion interposed between the second region and the third region; the second region includes a region interposed between the first electrode and the first region; the second region has a first refractive index; the third region includes a region interposed between the first region and the second electrode; the third region has a second refractive index; and the second refractive index is lower than the first refractive index. The EL layer includes a first unit, a second unit, and an intermediate layer; the intermediate layer is interposed between the first unit and the second unit; the intermediate layer has a function of supplying a hole to one of the first unit and the second unit and supplying an electron to the other; the first unit is interposed between the first electrode and the intermediate layer; the first unit includes a first layer including a light-emitting material; the second unit is interposed between the intermediate layer and the second electrode, and the second unit includes a second layer including a light-emitting material. Note that the first region includes the first layer including a light-emitting material and the second layer including a light-emitting material.

Thus, light emitted from the first region can be efficiently extracted from the second electrode. This structure enables high luminance emission while the current density is kept low. Reliability can be improved. The driving voltage can be reduced in comparison with that of the light-emitting device with the same luminance. Power consumption can be reduced. Consequently, a novel optical functional device that is highly convenient, useful, or reliable can be provided.

Embodiments are described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments. Note that in structures of the invention described below, the same portions or portions having similar functions are denoted by the same reference numerals in different drawings, and a description thereof is not repeated.

### Embodiment 1

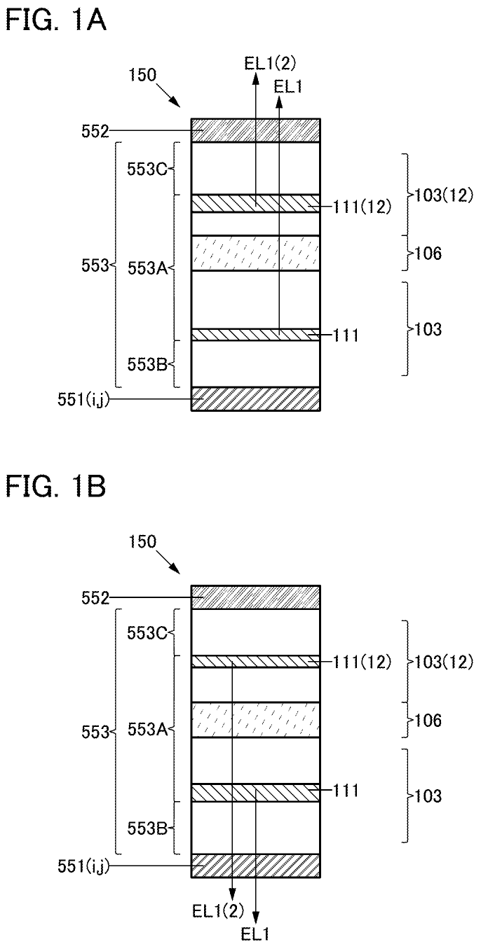

In this embodiment, a structure of a light-emitting device 150 of one embodiment of the present invention is described with reference to FIG. 1 to FIG. 3.

FIG. 1A is a diagram illustrating a structure of the light-emitting device of one embodiment of the present invention, and FIG. 1B is a diagram illustrating a structure of the light-emitting device of one embodiment of the present invention which is different from the structure in FIG. 1A.

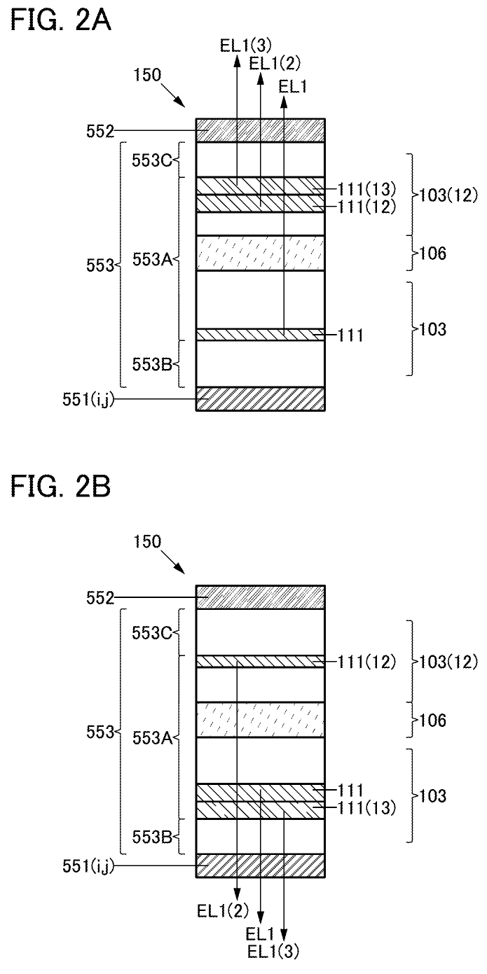

FIG. 2A is a diagram illustrating a structure of the light-emitting device of one embodiment of the present invention, and FIG. 2B is a diagram illustrating a structure of the light-emitting device of one embodiment of the present invention which is different from the structure in FIG. 2A.

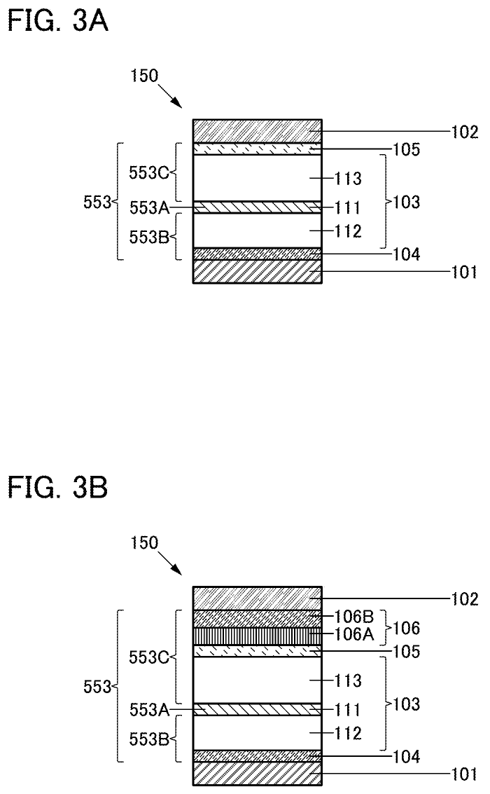

FIG. 3A is a cross-sectional view illustrating a structure of the light-emitting device of one embodiment of the present invention, and FIG. 3B is a cross-sectional view illustrating a structure of the light-emitting device of one embodiment of the present invention which is different from the structure in FIG. 3A.

### Structure Example 1 of Light-Emitting Device 150

The light-emitting device 150 described in this embodiment includes an electrode 551(i, j), an electrode 552, and an EL layer 553 (see FIG. 1A).

The electrode 551(i, j) has a transmittance T1. The electrode 552 includes a region overlapping with the electrode 551(i, j), and the electrode 552 has a transmittance T2. The transmittance T2 is higher than the transmittance T1. Note that the electrode 551(i, j) has a higher reflectance than the electrode 552.

### Structure Example 1 of EL Layer 553

The EL layer 553 includes a region interposed between the electrode 551(i, j) and the electrode 552. The EL layer 553 includes a region 553A, a region 553B, and a region 553C.

The region 553A includes a portion interposed between the region 553B and the region 553C. Note that the region 553A includes a layer 111 and a layer 111(12) each including a light-emitting material.

The region 553B includes a region interposed between the electrode 551(i, j) and the region 553A, and the region 553B has a refractive index n1.

The region 553C includes a region interposed between the region 553A and the electrode 552, and the region 553C has a refractive index n2. The refractive index n2 is lower than the refractive index n1.

### Structure Example 2 of EL Layer 553

The EL layer 553 includes a unit 103, a unit 103(12), and an intermediate layer 106 (see FIG. 1A).

### Structure Example of Intermediate Layer 106

The intermediate layer 106 is interposed between the unit 103 and the unit 103(12). The intermediate layer 106 has a function of supplying holes to one of the unit 103 and the unit 103(12) and supplying electrons to the other thereof.

### Structure Example 1 of Unit 103

The unit 103 is interposed between the electrode 551(i, j) and the intermediate layer 106, and the unit 103 includes the layer 111 including a light-emitting material.

### Structure Example 1 of Unit 103(12)

The unit 103(12) is interposed between the intermediate layer 106 and the electrode 552, and the unit 103(12) includes the layer 111(12) including a light-emitting material.

### Structure Example of Region 553A

The region 553A includes the layer 111 including a light-emitting material and the layer 111(12) including a light-emitting material. For example, layer 111(12) including a light-emitting material includes a portion interposed between the layer 111 including a light-emitting material and the electrode 552.

Thus, light emitted from the region 553A can be efficiently extracted from the electrode 552. This structure enables high luminance emission while the current density is kept low. Reliability can be improved. The driving voltage can be reduced in comparison with that of the light-emitting device with the same luminance. Power consumption can be reduced. Consequently, a novel optical functional device that is highly convenient, useful, or reliable can be provided.

### Structure Example 2 of Unit 103(12)

For example, a structure that emits light of the same color as the light emitted from the unit 103 can be employed for the unit 103(12). Specifically, a light-emitting material emitting blue light can be used for each of the layer 111 including a light-emitting material and the layer 111(12) including a light-emitting material.

Thus, the layer 111 including a light-emitting material and the layer 111(12) including a light-emitting material can be placed in positions such that light emitted from the layer 111 and light emitted from the layer 111(12) intensify each other. The layers each including a light-emitting material can be placed in a position such that the light emitted from the layers each including a light-emitting material and light reflected by the electrode 551(i, j) intensify each other. Light emitted from the region 553A can be efficiently extracted from the electrode 552. Consequently, a novel optical functional device that is highly convenient, useful, or reliable can be provided.

### Structure Example 3 of Unit 103(12)

The unit 103(12) includes a layer 111(13) including a light-emitting material (see FIG. 2A). For example, the layer 111(12) including a light-emitting material includes a region interposed between the layer 111 including a light-emitting material and the electrode 552, and the layer 111(13) including a light-emitting material includes a region interposed between the layer 111(12) including a light-emitting material and the electrode 552.

### Structure Example 1 of Layers Including Light-Emitting Material

The layer 111 including a light-emitting material has a function of emitting blue light; the layer 111(12) including a light-emitting material has a function of emitting red light; and the layer 111(13) including a light-emitting material has a function of emitting green light. For example, the layer 111(12) including a light-emitting material includes a region interposed between the layer 111 including a light-emitting material and the electrode 552, and the layer 111(13) including a light-emitting material includes a region interposed between the layer 111 including a light-emitting material and the layer 111(12) including a light-emitting material.

Thus, light of a plurality of colors can be emitted from the region 553A. The layers each including a light-emitting material can be placed in a position such that the light emitted from the layers each including a light-emitting material and light reflected by the electrode 551(i, j) intensify each other. The layers each including a light-emitting material can be arranged in accordance with the wavelengths of light emitted from the layers each including a light-emitting material. The light-emitting device can have an excellent color rendering property. Light emitted from the region 553A can be efficiently extracted from the electrode 552. Consequently, a novel optical functional device that is highly convenient, useful, or reliable can be provided.

### Structure Example 2 of Light-Emitting Device 150

The light-emitting device 150 described in this embodiment includes the electrode 551(i, j), the electrode 552, and the EL layer 553 (see FIG. 1B).

Structure example 2 of the light-emitting device 150 is different from the light-emitting device described with reference to FIG. 1A in that the transmittance T2 of the electrode 552 is lower than the transmittance T1 of the electrode 551(i, j) and that the refractive index n1 of the region 553B is lower than the refractive index n2 of the region 553C. Different portions will be described in detail here, and the above description is referred to for portions that can use similar structures.

Thus, light emitted from the region 553A can be efficiently extracted from the electrode 551(i, j). This structure enables high luminance emission while the current density is kept low. Reliability can be improved. The driving voltage can be reduced in comparison with that of the light-emitting device with the same luminance. Power consumption can be reduced. Consequently, a novel optical functional device that is highly convenient, useful, or reliable can be provided.

### Structure Example 4 of Unit 103(12)

For example, a structure that emits light of the same color as the light emitted from the unit 103 can be employed for the unit 103(12). Specifically, a light-emitting material emitting blue light can be used for each of the layer 111 including a light-emitting material and the layer 111(12) including a light-emitting material.

Thus, the layer 111 including a light-emitting material and the layer 111(12) including a light-emitting material can be placed in positions such that light emitted from the layer 111 and light emitted from the layer 111(12) intensify each other. The layers each including a light-emitting material can be placed in a position such that the light emitted from the layers each including a light-emitting material and light reflected by the electrode 552 intensify each other. Light emitted from the region 553A can be efficiently extracted from the electrode 551(i, j). Consequently, a novel optical functional device that is highly convenient, useful, or reliable can be provided.

### Structure Example 2 of Unit 103

The unit 103 includes the layer 111(13) including a light-emitting material (see FIG. 2B). For example, the layer 111(12) including a light-emitting material includes a region interposed between the layer 111 including a light-emitting material and the electrode 552, and the layer 111(13) including a light-emitting material includes a region interposed between the layer 111 including a light-emitting material and the electrode 551(i, j).

### Structure Example 2 of Layers Including Light-Emitting Material

The layer 111 including a light-emitting material has a function of emitting red light; the layer 111(12) including a light-emitting material has a function of emitting blue light; and the layer 111(13) including a light-emitting material has a function of emitting green light.

Thus, light of a plurality of colors can be emitted from the region 553A. The layers each including a light-emitting material can be placed in a position such that the light emitted from the layers each including a light-emitting material and light reflected by the electrode 552 intensify each other. The layers each including a light-emitting material can be arranged in accordance with the wavelengths of light emitted from the layers each including a light-emitting material. The light-emitting device can have an excellent color rendering property. Light emitted from the region 553A can be efficiently extracted from the electrode 551(i, j). Consequently, a novel optical functional device that is highly convenient, useful, or reliable can be provided.

### Structure Example 3 of Light-Emitting Device 150

The light-emitting device 150 described in this embodiment includes the electrode 101, the electrode 102, and the EL layer 553 (see FIG. 3A). The electrode 102 includes a region overlapping with the electrode 101.

The EL layer 553 includes a region interposed between the electrode 101 and the electrode 102. The EL layer 553 includes the region 553A, the region 553B, and the region 553C. The region 553A includes a portion interposed between the region 553B and the region 553C.

### Structure Example 4 of Light-Emitting Device 150

The light-emitting device 150 described in this embodiment includes the electrode 101, the electrode 102, and the EL layer 553 (see FIG. 3B). The light-emitting device 150 is different from the light-emitting device described with reference to FIG. 3A in that the region 553C includes the intermediate layer 106 and that the intermediate layer 106 is in contract with the electrode 102.

Note that this embodiment can be combined with any of the other embodiments in this specification as appropriate.

### Embodiment 2

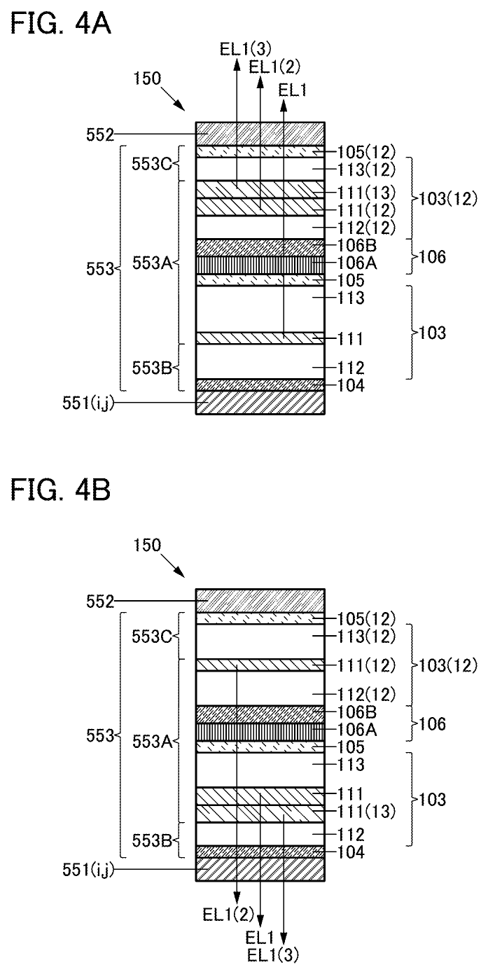

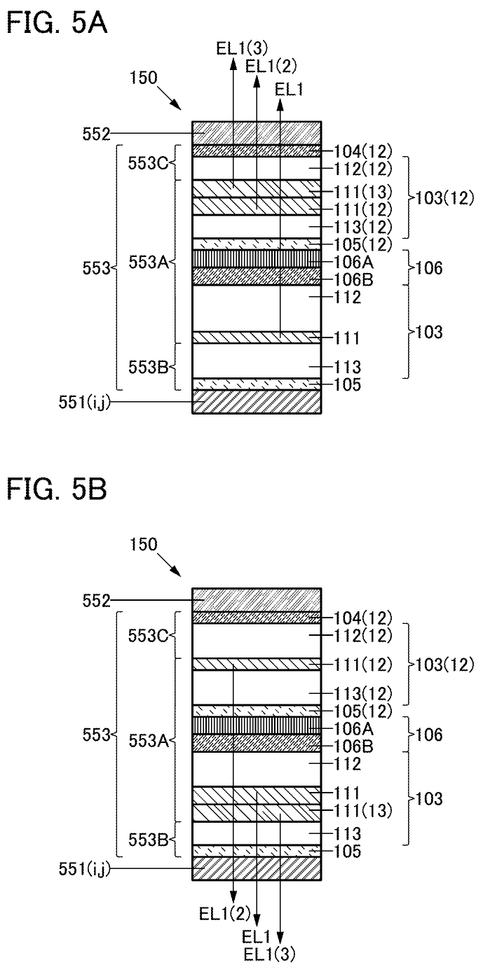

In this embodiment, a structure of the light-emitting device 150 of one embodiment of the present invention is described with reference to FIG. 4 and FIG. 5.

FIG. 4A is a diagram illustrating a structure of the light-emitting device of one embodiment of the present invention, and FIG. 4B is a diagram illustrating a structure of the light-emitting device of one embodiment of the present invention which is different from the structure in FIG. 4A.

FIG. 5A is a diagram illustrating a structure of the light-emitting device of one embodiment of the present invention, and FIG. 5B is a diagram illustrating a structure of the light-emitting device of one embodiment of the present invention which is different from the structure in FIG. 5A.

### Structure Example 1 of Light-Emitting Device 150

The light-emitting device 150 described in this embodiment includes the electrode 551(i, j), the electrode 552, and the EL layer 553 (see FIG. 4A).

The electrode 551(i, j) has the transmittance T1. The electrode 552 includes a region overlapping with the electrode 551(i, j), and the electrode 552 has the transmittance T2. The transmittance T2 is higher than the transmittance T1. Note that the electrode 551(i, j) has a higher reflectance than the electrode 552.

Any one of the electrode 551(i, j) and the electrode 552 can be used as an anode and the other thereof can be used as a cathode.

For example, a material having a work function higher than or equal to 4.0 eV can be suitably used for the anode.

For example, a material having a lower work function than the anode can be used for the cathode. Specifically, a material having a work function less than or equal to 3.8 eV can be favorably used.

For example, an element belonging to Group 1 of the periodic table, an element belonging to Group 2 of the periodic table, a rare earth metal, or an alloy containing any of these elements can be used for the cathode.

Specifically, lithium (Li), cesium (Cs), or the like; magnesium (Mg), calcium (Ca), strontium (Sr), or the like; europium (Eu), ytterbium (Yb), or the like; or an alloy containing any of these (MgAg or AlLi) can be used for the cathode.

### Structure Example 1 of Electrode 551(i, j)

For example, a conductive material can be used for the electrode 551(i, j). A material in which a reflective film and a conductive film are stacked can be used for the electrode 551(i, j).

Specifically, a metal, an alloy, a conductive compound, a mixture of these, or the like can be used.

For example, indium oxide-tin oxide (ITO: Indium Tin Oxide), indium oxide-tin oxide containing silicon or silicon oxide, indium oxide-zinc oxide, indium oxide containing tungsten oxide and zinc oxide (IWZO), or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), a nitride of a metal material (such as titanium nitride), or the like can be used. Alternatively, graphene can be used.

### Structure Example 1 of Electrode 552

A metal, an alloy, an electrically conductive compound, a mixture of these, or the like can be used for the electrode 552.

### Structure Example 1 of EL Layer 553

The EL layer 553 includes a region interposed between the electrode 551(i, j) and the electrode 552 (see FIG. 4A). The EL layer 553 includes the region 553A, the region 553B, and the region 553C. The region 553A includes a portion interposed between the region 553B and the region 553C.

The EL layer 553 includes the unit 103, the unit 103(12), a layer 104, a layer 105, a layer 105(12), and the intermediate layer 106. The unit 103 includes the layer 111, the layer 112, and the layer 113. The unit 103(12) includes the layer 111(12), the layer 111(13), a layer 112(12), and a layer 113(12). The intermediate layer 106 includes a layer 106A and a layer 106B.

### Structure Example 1 of Region 553C

For the region 553C, a material that enables the refractive index n2 of the region 553C to be lower than the refractive index n1 of the region 553B and the electron-transport property of the region 553C to be higher than the electron-transport property of the region 553B can be used (see FIG. 4A). Decreasing the refractive index n2 of the region 553C can increase the light extraction efficiency of the light-emitting device 150. The difference between the refractive index n2 and the refractive index n1 is preferably 0.05 or more, further preferably 0.1 or more, still further preferably 0.15 or more. Note that the region 553C includes the layer 113(12) and the layer 105(12).

In the light-emitting device 150 described in this embodiment, the electrode 551(i, j) and the electrode 552 can be used as an anode and a cathode, respectively. The intermediate layer 106 can supply electrons to the unit 103 and supply holes to the unit 103(12).

For example, a material having an electron-transport property with an ordinary refractive index higher than or equal to 1.50 and lower than or equal to 1.75 in a blue light emission range (455 nm to 465 nm) or an ordinary refractive index higher than or equal to 1.45 and lower than or equal to 1.70 with respect to light of wavelength 633 nm, which is usually used for measurement of refractive indices, can be used for the region 553C.

In the case where the material has anisotropy, the refractive index with respect to an ordinary ray might differ from that with respect to an extraordinary ray. When a thin film to be measured is in such a state, anisotropy analysis can be performed to separately calculate the ordinary refractive index and the extraordinary refractive index. In this specification, when the measured material has both the ordinary refractive index and the extraordinary refractive index, the ordinary refractive index is used as an indicator.

### Material Having Electron-Transport Property

An example of the material having an electron-transport property is an organic compound which includes at least one six-membered heteroaromatic ring having 1 to 3 nitrogen atoms; a plurality of aromatic hydrocarbon rings each having 6 to 14 carbon atoms in a ring, at least two of which are benzene rings; and a plurality of hydrocarbon groups forming a bond by sp³ hybrid orbitals.

In the above organic compound, a proportion of carbon atoms forming a bond by sp³ hybrid orbitals in total carbon atoms in molecules of the organic compound is preferably higher than or equal to 10% and lower than or equal to 60%, further preferably higher than or equal to 10% and lower than or equal to 50%. Alternatively, when the above organic compound is subjected to ¹H-NMR measurement, the integral value of signals at lower than 4 ppm is preferably ½ or more of the integral value of signals at 4 ppm or higher.

It is preferable that all the hydrocarbon groups forming a bond by sp³ hybrid orbitals in the above organic compound be bonded to the aromatic hydrocarbon rings each having 6 to 14 carbon atoms in a ring, and the LUMO of the organic compound not be distributed in the aromatic hydrocarbon rings.

The organic compound having an electron-transport property is preferably an organic compound represented by General formula (Gₑ₁1) or (Gₑ₁2).

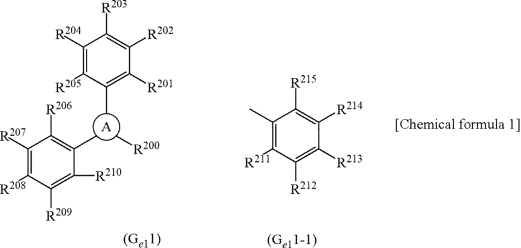

In the formula, A represents a six-membered heteroaromatic ring having 1 to 3 nitrogen atoms, and is preferably any of a pyridine ring, a pyrimidine ring, a pyrazine ring, a pyridazine ring, and a triazine ring.

In addition, R²⁰⁰ represents any of hydrogen, an alkyl group having 1 to 6 carbon atoms, an alicyclic group having 3 to 10 carbon atoms, and a substituent represented by Formula (Gₑ₁1-1).

At least one of R²⁰¹ to R²¹⁵ represents a phenyl group having a substituent and the others each independently represent any of hydrogen, an alkyl group having 1 to 6 carbon atoms, an alicyclic group having 3 to 10 carbon atoms, a substituted or unsubstituted aromatic hydrocarbon group having 6 to 14 carbon atoms in a ring, and a substituted or unsubstituted pyridyl group. Note that R²⁰¹, R²⁰³, R²⁰⁵, R²⁰⁶, R²⁰⁸, R²¹⁰, R²¹¹, R²¹³, and R²¹⁵ are preferably hydrogen. The phenyl group having a substituent has one or two substituents, which each independently represent any of an alkyl group having 1 to 6 carbon atoms, an alicyclic group having 3 to 10 carbon atoms, and a substituted or unsubstituted aromatic hydrocarbon group having 6 to 14 carbon atoms in a ring.

The organic compound represented by General Formula (Gₑ₁1) above has a plurality of hydrocarbon groups selected from an alkyl group having 1 to 6 carbon atoms and an alicyclic group having 3 to 10 carbon atoms, and a proportion of carbon atoms forming a bond by sp³ hybrid orbitals in total carbon atoms in molecules of the organic compound is higher than or equal to 10% and lower than or equal to 60%.

The organic compound having an electron-transport property is preferably an organic compound represented by General Formula (Gₑ₁2).

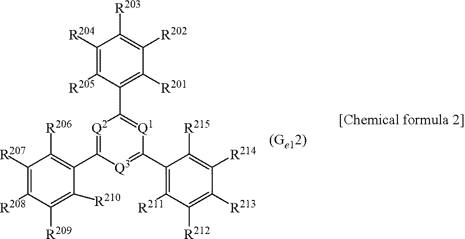

In the formula, two or three of Q¹ to Q³ represent N; in the case where two of Q¹ to Q³ are N, the remaining one represents CH.

At least any one of R²⁰¹ to R²¹⁵ represents a phenyl group having a substituent and the others each independently represent any of hydrogen, an alkyl group having 1 to 6 carbon atoms, an alicyclic group having 3 to 10 carbon atoms, a substituted or unsubstituted aromatic hydrocarbon group having 6 to 14 carbon atoms in a ring, and a substituted or unsubstituted pyridyl group. Note that R²⁰¹, R²⁰³, R²⁰⁵, R²⁰⁶, R²⁰⁸, R²¹⁰, R²¹¹, R²¹³, and R²¹⁵ are preferably hydrogen. The phenyl group having a substituent has one or two substituents, which each independently represent any of an alkyl group having 1 to 6 carbon atoms, an alicyclic group having 3 to 10 carbon atoms, and a substituted or unsubstituted aromatic hydrocarbon group having 6 to 14 carbon atoms in a ring.

The organic compound represented by General Formula (Gₑ₁2) above has a plurality of hydrocarbon groups selected from an alkyl group having 1 to 6 carbon atoms and an alicyclic group having 3 to 10 carbon atoms, and a proportion of carbon atoms forming a bond by sp³ hybrid orbitals in carbon atoms in molecules of the organic compound is preferably higher than or equal to 10% and lower than or equal to 60%.

In the organic compound represented by General formula (Gₑ₁1) or (Gₑ₁2) above, the phenyl group having a substituent is preferably a group represented by Formula (Gₑ₁1-2) below. [Chemical formula 3]

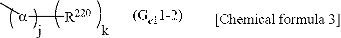

In the formula, α represents a substituted or unsubstituted phenylene group and is preferably a meta-substituted phenylene group. In the case where the meta-substituted phenylene group has a substituent, the substituent is also preferably meta-substituted. The substituent is preferably an alkyl group having 1 to 6 carbon atoms or an alicyclic group having 3 to 10 carbon atoms, further preferably an alkyl group having 1 to 6 carbon atoms, and still further preferably a t-butyl group.

R²²⁰ represents an alkyl group having 1 to 6 carbon atoms, an alicyclic group having 3 to 10 carbon atoms, or a substituted or unsubstituted aromatic hydrocarbon group having 6 to 14 carbon atoms in a ring.

In addition,j and k each represent 1 or 2. In the case where j is 2, a plurality of α may be the same or different from each other. In the case where k is 2, a plurality of R²²⁰ may be the same or different from each other. Note that R²²⁰ is preferably a phenyl group and is a phenyl group that has an alkyl group having 1 to 6 carbon atoms or an alicyclic group having 3 to 10 carbon atoms at one or both of the two meta-positons. The substituent at one or both of the two meta-positons of the phenyl group is preferably an alkyl group having 1 to 6 carbon atoms, further preferably a t-butyl group.

Specifically, 2-{(3′,5′-di-tert-butyl)-1, 1′-biphenyl-3-yl}-4,6-bis(3,5-di-tert-butylphenyl)-1,3,5-triazine (abbreviation: mmtBumBP-dmmtBuPTzn), 2-{(3′,5′-di-tert-butyl)-1,1′-biphenyl-3-yl}-4,6-diphenyl-1,3,5-triazine (abbreviation: mmtBumBPTzn), 2-(3,3″,5′,5″-tetra-tert-butyl-1,1′:3′,1″-phenyl-5′-yl)-4,6-diphenyl-1,3,5-triazine (abbreviation: mmtBumTPTzn), 2-{(3′,5′-di-tert-butyl)-1,1′-biphenyl-3-yl}-4,6-bis(3,5-di-tert-butylphenyl)-1,3-pyrimidine (abbreviation: mmtBumBP-dmmtBuPPm), 2-(3,3″,5′,5″-tetra-tert-butyl-1,1′:3′,1″-terphenyl-5-yl)-4,6-diphenyl-1,3,5-triazine (abbreviation: mmtBumTPTzn-02), or the like can be used for the region 553C.

### Structure Example 2 of EL layer 553

The EL layer 553 includes the unit 103, the unit 103(12), the layer 105, the layer 105(12), a layer 104(12), and the intermediate layer 106 (see FIG. 5A). The unit 103 includes the layer 111, the layer 112, and the layer 113. The unit 103(12) includes the layer 111(12), the layer 111(13), a layer 112(12), and a layer 113(12). The intermediate layer 106 includes the layer 106A and the layer 106B.

### Structure Example 2 of Region 553C

For the region 553C, a material that enables the refractive index n2 of the region 553C to be lower than the refractive index n1 of the region 553B and the hole-transport property of the region 553C to be higher than the hole-transport property of the region 553B can be used (see FIG. 5A). Decreasing the refractive index n2 of the region 553C can increase the light extraction efficiency of the light-emitting device 150. The difference between the refractive index n2 and the refractive index n1 is preferably 0.05 or more, further preferably 0.1 or more, still further preferably 0.15 or more. Note that in the light-emitting device 150 described in this embodiment, the electrode 551(i, j) and the electrode 552 can be used as a cathode and an anode, respectively. The intermediate layer 106 can supply holes to the unit 103 and supply electrons to the unit 103(12).

For example, a material having a hole-transport property with an ordinary refractive index higher than or equal to 1.50 and lower than or equal to 1.75 in a blue light emission range (455 nm to 465 nm) or an ordinary refractive index higher than or equal to 1.45 and lower than or equal to 1.70 with respect to light of wavelength 633 nm, which is usually used for measurement of refractive indices, can be used for the region 553C.

### Material Having Hole-Transport Property

An example of the material having a hole-transport property is a monoamine compound including a first aromatic group, a second aromatic group, and a third aromatic group, in which the first aromatic group, the second aromatic group, and the third aromatic group are bonded to the same nitrogen atom.

In the monoamine compound, the proportion of carbon atoms each forming a bond by the sp³ hybrid orbitals to the total number of carbon atoms in the molecule is preferably higher than or equal to 23% and lower than or equal to 55%. In addition, it is preferable that the integral value of signals at lower than 4 ppm exceed the integral value of signals at 4 ppm or higher in the results of ¹H-NMR measurement conducted on the monoamine compound.

The monoamine compound preferably has at least one fluorene skeleton. One or more of the first aromatic group, the second aromatic group, and the third aromatic group are preferably a fluorene skeleton.

Examples of the above-described material having a hole-transport property include organic compounds having structures represented by General Formulae (Gₕ₁1) to (Gₕ₁4) shown below.

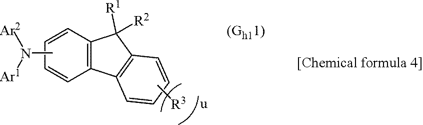

In General Formula (Gₕ₁1), Ar¹ and Ar² each independently represent a substituent with a benzene ring or a substituent in which two or three benzene rings are bonded to each other. Note that one or both of Ar¹ and Ar² have one or more hydrocarbon groups each having 1 to 12 carbon atoms each forming a bond only by the sp³ hybrid orbitals. The total number of carbon atoms contained in all of the hydrocarbon groups bonded to Ar¹ and Ar² is 8 or more and the total number of carbon atoms contained in all of the hydrocarbon groups bonded to Ar¹ or Ar² is 6 or more. Note that in the case where a plurality of straight-chain alkyl groups each having one or two carbon atoms are bonded to Ar¹ or Ar² as the hydrocarbon groups, the straight-chain alkyl groups may be bonded to each other to form a ring.

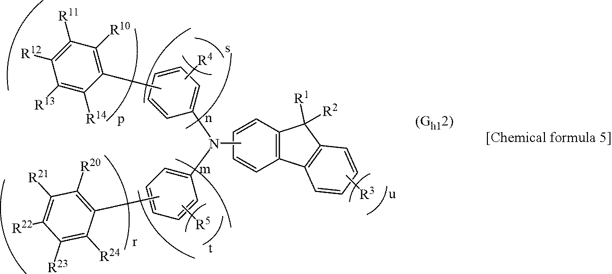

In General Formula (Gₕ₁2), m and r each independently represent 1 or 2 and m+r is 2 or 3. Furthermore, t represents an integer of 0 to 4 and is preferably 0. In addition, R⁵ represents hydrogen or a hydrocarbon group having 1 to 3 carbon atoms. When m is 2, the kind and number of substituents and the position of bonds included in one phenylene group may be the same as or different from those of the other phenylene group; and when r is 2, the kind and number of substituents and the position of bonds included in one phenyl group may be the same as or different from those of the other phenyl group. In the case where t is an integer of 2 to 4, R⁵s may be the same as or different from each other; and adjacent groups of R⁵s may be bonded to each other to form a ring.

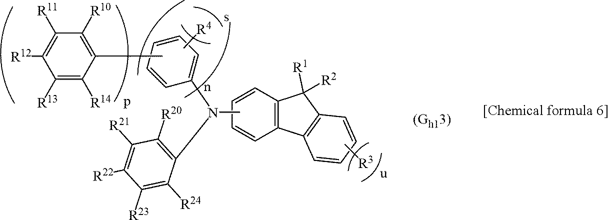

In General Formulae (Gₕ₁2) and (Gₕ₁3), n and p each independently represent 1 or 2 and n+p is 2 or 3. In addition, s represents an integer of 0 to 4 and is preferably 0. R⁴ represents hydrogen or a hydrocarbon group having 1 to 3 carbon atoms. When n is 2, the kind and number of substituents and the position of bonds in one phenylene group may be the same as or different from those of the other phenylene group; and when p is 2, the kind and number of substituents and the position of bonds in one phenyl group may be the same as or different from those of the other phenyl group. In the case where s is an integer of 2 to 4, R⁴s may be the same as or different from each other.

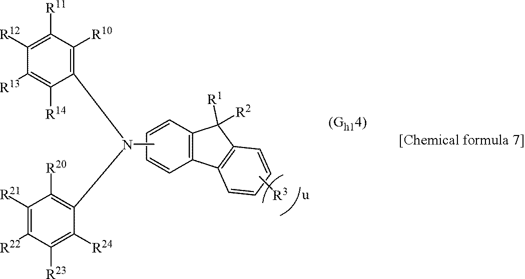

In General Formulae (Gₕ₁2) to (Gₕ₁4), R¹⁰ to R¹⁴ and R²⁰ to R²⁴ each independently represent hydrogen or a hydrocarbon group having 1 to 12 carbon atoms each forming a bond only by the sp³ hybrid orbitals. Note that at least three of R¹⁰ to R¹⁴ and at least three of R²⁰ to R²⁴ are preferably hydrogen. As the hydrocarbon group having 1 to 12 carbon atoms each forming a bond only by the sp³ hybrid orbitals, a tert-butyl group and a cyclohexyl group are preferable because the molecular refractive index can be lowered. The total number of carbon atoms contained in R¹⁰ to R¹⁴ and R²⁰ to R²⁴ is 8 or more and the total number of carbon atoms contained in either R¹⁰ to R¹⁴ or R²⁰ to R²⁴ is 6 or more. Note that adjacent groups of R⁴, R¹⁰ to R¹⁴ and R²⁰ to R²⁴ may be bonded to each other to form a ring.

In General Formulae (Gₕ₁1) to (Gₕ₁4), u represents an integer of 0 to 4 and is preferably 0. Note that in the case where u is an integer of 2 to 4, R³s may be the same as or different from each other. In addition, R¹, R², and R³ each independently represent an alkyl group having 1 to 4 carbon atoms and R¹ and R² may be bonded to each other to form a ring.

An arylamine compound that has at least one aromatic group having first to third benzene ring and at least three alkyl groups is preferable as one of the materials having a hole-transport property. Note that the first to third benzene rings are bonded in this order and the first benzene ring is directly bonded to nitrogen of amine.

The first benzene ring may further include a substituted or unsubstituted phenyl group and preferably includes an unsubstituted phenyl group. Furthermore, the second benzene ring or the third benzene ring may include a phenyl group substituted by an alkyl group.

Note that hydrogen is not directly bonded to carbon atoms at 1- and 3-positions in two or more of benzene rings, preferably all of the first to third benzene rings, and the carbon atoms are bonded to any of the first to third benzene rings, the phenyl group substituted by the alkyl group, the at least three alkyl groups, and the nitrogen of the amine.

It is preferable that the arylamine compound further include a second aromatic group. It is preferable that the second aromatic group have an unsubstituted monocyclic ring or a substituted or unsubstituted bicyclic or tricyclic condensed ring; in particular, it is further preferable that the second aromatic group be a group having a substituted or unsubstituted bicyclic or tricyclic condensed ring where the number of carbon atoms forming the ring is 6 to 13. It is still further preferable that the second aromatic group be a group including a fluorene ring. Note that a dimethylfluorenyl group is preferable as the second aromatic group.

It is preferable that the arylamine compound further include a third aromatic group. The third aromatic group is a group having 1 to 3 substituted or unsubstituted benzene rings.

It is preferable that the at least three alkyl groups and the alkyl group substituted for the phenyl group be each a chain alkyl group having 2 to 5 carbon atoms. In particular, the alkyl group is preferably a chain alkyl group having a branch formed of 3 to 5 carbon atoms, and is further preferably a t-butyl group.

Examples of the above-described material having a hole-transport property include organic compounds having structures represented by (Gₕ₂1) to (Gₕ₂3) shown below.

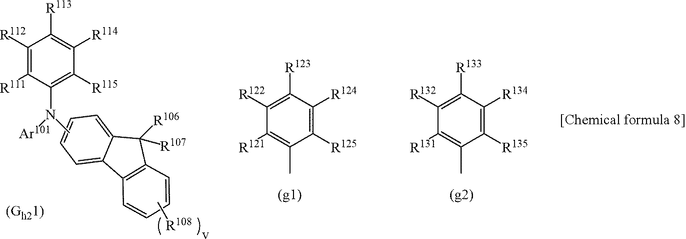

Note that in General Formula (Gₕ₂1), Ar¹⁰¹ represents a substituted or unsubstituted benzene ring or a substituent in which two or three substituted or unsubstituted benzene rings are bonded to one another.

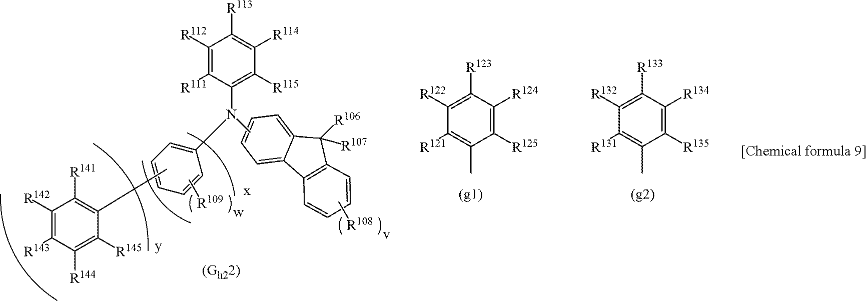

Note that in General Formula (Gₕ₂2), x and y each independently represent 1 or 2 and x+y is 2 or 3. Furthermore, R¹⁰⁹ represents an alkyl group having 1 to 4 carbon atoms, and w represents an integer of 0 to 4. In addition, R¹⁴¹ to R¹⁴⁵ each independently represent any one of hydrogen, an alkyl group having 1 to 6 carbon atoms, and a cycloalkyl group having 5 to 12 carbon atoms. When w is an integer of 2 or more, R¹⁰⁹s may be the same as or different from each other. When x is 2, the kind and number of substituents and the position of bonds included in one phenylene group may be the same as or different from those of the other phenylene group. When y is 2, the kind and number of substituents and the position of bonds included in one phenyl group including R¹⁴¹ to R¹⁴⁵ may be the same as or different from those of the other phenyl group including R¹⁴¹ to R¹⁴⁵.

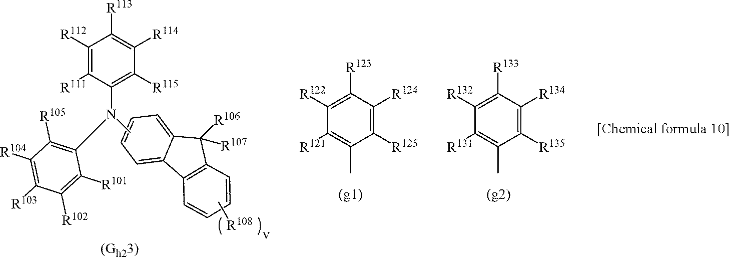

In General Formula (Gₕ₂3), R¹⁰¹ to R¹⁰⁵ each independently represent any one of hydrogen, an alkyl group having 1 to 6 carbon atoms, a cycloalkyl group having 6 to 12 carbon atoms, and a substituted or unsubstituted phenyl group.

In General Formulae (Gₕ₂1) to (Gₕ₂3), R¹⁰⁶, R¹⁰⁷, and R¹⁰⁸ each independently represent an alkyl group having 1 to 4 carbon atoms, and v represents an integer of 0 to 4. Note that when v is 2 or more, R¹⁰⁸s may be the same as or different from each other. One of R¹¹¹ to R¹¹⁵ represents a substituent represented by General Formula (g1), and the others each independently represent any one of hydrogen, an alkyl group having 1 to 6 carbon atoms, and a substituted or unsubstituted phenyl group. In General Formula (g1), one of R¹²¹ to R¹²⁵ represents a substituent represented by General Formula (g2), and the others each independently represent any one of hydrogen, an alkyl group having 1 to 6 carbon atoms, and a phenyl group substituted by an alkyl group having 1 to 6 carbon atoms. In General Formula (g2), R¹³¹ to R¹³⁵ each independently represent any one of hydrogen, an alkyl group having 1 to 6 carbon atoms, and a phenyl group substituted by an alkyl group having 1 to 6 carbon atoms. Note that at least three of R¹¹¹ to R¹¹⁵, R¹²¹ to R¹²⁵, and R¹³¹ to R¹³⁵ are each an alkyl group having 1 to 6 carbon atoms; the number of substituted or unsubstituted phenyl groups in R¹¹¹ to R¹¹⁵ is one or less; and the number of phenyl groups substituted by an alkyl group having 1 to 6 carbon atoms in R¹²¹ to R¹²⁵ and R¹³¹ to R¹³⁵ is one or less. In at least two combinations of the three combinations R¹¹² and R¹¹⁴, R¹²² and R¹²⁴, and R¹³² and R¹³⁴, at least one R represents any of the substituents other than hydrogen.

Specifically, N,N-bis(4-cyclohexylphenyl)-N-(9,9-dimethyl-9H-fluoren-2yl)amine (abbreviation: dchPAF), N-(4-cyclohexylphenyl)-N-(3″,5″-ditertiarybutyl-1,1″-biphenyl-4-yl)-N-(9,9-dimethyl-9H-fluoren-2yl)amine (abbreviation: mmtBuBichPAF), N-(3,3″,5,5″-tetra-t-butyl-1,1′:3′,1″-terphenyl-5′-yl)-N-(4-cyclohexylphenyl)-9,9-dimethyl-9H-fluoren-2-amine (abbreviation: mmtBumTPchPAF), N-[(3,3′,5′-t-butyl)-1,1′-biphenyl-5-yl]-N-(4-cyclohexylphenyl)-9,9-dimethyl-9H-fluoren-2-amine (abbreviation: mmtBumBichPAF, N-(1,1′-biphenyl-2-yl)-N-[(3,3′,5′-tri-t-butyl)-1,1′-biphenyl-5-yl]-9,9-dimethyl-9H-fluoren-2-amine (abbreviation: mmtBumBioFBi), N-(4-tert-butylphenyl)-N-(3,3″,5,5″-tetra-t-butyl-1,1′:3′,1″-terphenyl-5′-yl)-9,9,-dimethyl-9H-fluoren-2-amine (abbreviation: mmtBumTPtBuPAF), N-(1,1′-biphenyl-2-yl)-N-(3,3″,5′,5″-tetra-t-butyl-1,1′:3′,1″-terphenyl-5-yl)-9,9-dimethyl-9H-fluoren-2-amine (abbreviation: mmtBumTPoFBi-02), N-(4-cyclohexylphenyl)-N-(3,3″,5′,5″-tetra-t-butyl-1,1′:3′,1″-terphenyl-5-yl)-9,9-dimethyl-9H-fluoren-2-amine (abbreviation: mmtBumTPchPAF-02), N-(1,1′-biphenyl-2-yl)-N (3″,5′,5″-tri-t-butyl-1,1′:3′,1″-terphenyl-5-yl)-9,9-dimethyl-9H-fluoren-2-amine (abbreviation: mmtBumTPoFBi-03), N-(4-cyclohexylphenyl)-N-(3″,5′,5″-tri-t-butyl-1,1′:3′,1″-terphenyl-5-yl)-9,9-dimethyl-9H-fluoren-2-amine (abbreviation: mmtBumTPchPAF-03), or the like can be used for the region 553C.

### Structure Example 1 of Region 553B

For the region 553B, a material that enables the refractive index n1 of the region 553B to be lower than the refractive index n2 of the region 553C and the hole-transport property of the region 553B to be higher than the hole-transport property of the region 553C can be used (see FIG. 4A). Decreasing the refractive index n1 of the region 553B can increase the reflectance of the electrode 551(i, j), whereby light emitted from the region 553A can be efficiently extracted from the electrode 552. The difference between the refractive index n1 and the refractive index n2 is preferably 0.05 or more, further preferably 0.1 or more, still further preferably 0.15 or more.

For example, the above material having a hole-transport property with an ordinary refractive index higher than or equal to 1.50 and lower than or equal to 1.75 in a blue light emission range (455 nm to 465 nm) or an ordinary refractive index higher than or equal to 1.45 and less than or equal to 1.70 with respect to light of wavelength 633 nm, which is usually used for measurement of refractive indices, can be used for the region .

### Structure Example 2 of Region 553B

For the region 553B, a material that enables the refractive index n1 of the region 553B to be lower than the refractive index n2 of the region 553C and the electron-transport property of the region 553B to be higher than the electron-transport property of the region 553C can be used (see FIG. 5A). Decreasing the refractive index n1 of the region 553B can increase the reflectance of the electrode 551(i, j), whereby light emitted from the region 553A can be efficiently extracted from the electrode 552. The difference between the refractive index n1 and the refractive index n2 is preferably 0.05 or more, further preferably 0.1 or more, still further preferably 0.15 or more.

For example, the above material having an electron-transport property with an ordinary refractive index higher than or equal to 1.50 and lower than or equal to 1.75 in a blue light emission range (455 nm to 465 nm) or an ordinary refractive index higher than or equal to 1.45 and less than or equal to 1.70 with respect to light of wavelength 633 nm, which is usually used for measurement of refractive indices, can be used for the region 553B.

### Structure Example 2 of Light-Emitting Device 150

The light-emitting device 150 described in this embodiment includes the electrode 551(i, j), the electrode 552, and the EL layer 553 (see FIG. 4B).

The light-emitting device 150 described with reference to FIG. 4B is different from the light-emitting device described with reference to FIG. 4A in that the transmittance T2 of the electrode 552 is lower than the transmittance T1 of the electrode 551(i, j). Different portions will be described in detail here, and the above description is referred to for portions that can use similar structures. Note that the electrode 552 has a higher reflectance than the electrode 551(i, j).

### Structure Example 2 of Electrode 551(i, j)

A metal, an alloy, an electrically conductive compound, a mixture of these, or the like can be used for the electrode 551(i, j).

### Structure Example 2 of Electrode 552

For example, a conductive material can be used for the electrode 552. A material in which a reflective film and a conductive film are stacked can be used for the electrode 552.

### Structure Example 1 of Region 553B

For the region 553B, a material that enables the refractive index n1 of the region 553B to be lower than the refractive index n2 of the region 553C and the hole-transport property of the region 553B to be higher than the hole-transport property of the region 553C can be used (see FIG. 4B). Decreasing the refractive index n1 of the region 553B can increase the light extraction efficiency of the light-emitting device 150. The difference between the refractive index n1 and the refractive index n2 is preferably 0.05 or more, further preferably 0.1 or more, still further preferably 0.15 or more. In the light-emitting device 150 described in this embodiment, the electrode 551(i, j) and the electrode 552 can be used as an anode and a cathode, respectively. The intermediate layer 106 can supply electrons to the unit 103 and supply holes to the unit 103(12).

For example, the above material having a hole-transport property with an ordinary refractive index higher than or equal to 1.50 and lower than or equal to 1.75 in a blue light emission range (455 nm to 465 nm) or an ordinary refractive index higher than or equal to 1.45 and less than or equal to 1.70 with respect to light of wavelength 633 nm, which is usually used for measurement of refractive indices, can be used for the region 553B.

### Structure Example 2 of Region 553B

For the region 553B, a material that enables the refractive index n1 of the region 553B to be lower than the refractive index n2 of the region 553C and the electron-transport property of the region 553B to be higher than that of the region 553C can be used (see FIG. 5B). Decreasing the refractive index n1 of the region 553B can increase the light extraction efficiency of the light-emitting device 150. The difference between the refractive index n1 and the refractive index n2 is preferably 0.05 or more, further preferably 0.1 or more, still further preferably 0.15 or more. Note that in the light-emitting device 150 described in this embodiment, the electrode 551(i, j) and the electrode 552 can be used as a cathode and an anode, respectively. The intermediate layer 106 can supply holes to the unit 103 and supply electrons to the unit 103(12).

For example, the above material having an electron-transport property with an ordinary refractive index higher than or equal to 1.50 and lower than or equal to 1.75 in a blue light emission range (455 nm to 465 nm) or an ordinary refractive index higher than or equal to 1.45 and less than or equal to 1.70 with respect to light of wavelength 633 nm, which is usually used for measurement of refractive indices, can be used for the region 553B.

### Structure Example 1 of Region 553C

For the region 553C, a material that enables the refractive index n2 of the region 553C to be lower than the refractive index n1 of the region 553B and the electron-transport property of the region 553C to be higher than the electron-transport property of the region 553B can be used (see FIG. 4B). Decreasing the refractive index n1 of the region 553C can increase the reflectance of the electrode 552, whereby light emitted from the region 553A can be efficiently extracted from the electrode 551(i, j). The difference between the refractive index n2 and the refractive index n1 is preferably 0.05 or more, further preferably 0.1 or more, still further preferably 0.15 or more.

For example, the above material having an electron-transport property with an ordinary refractive index higher than or equal to 1.50 and lower than or equal to 1.75 in a blue light emission range (455 nm to 465 nm) or an ordinary refractive index higher than or equal to 1.45 and less than or equal to 1.70 with respect to light of wavelength 633 nm, which is usually used for measurement of refractive indices, can be used for the region 553C.

### Structure Example 2 of Region 553C

For the region 553C, a material that enables the refractive index n2 of the region 553C to be lower than the refractive index n1 of the region 553B and the hole-transport property of the region 553C to be higher than the hole-transport property of the region 553B can be used (see FIG. 5B). Decreasing the refractive index n2 of the region 553C can increase the reflectance of the electrode 552, whereby light emitted from the region 553A can be efficiently extracted from the electrode 551(i, j). The difference between the refractive index n2 and the refractive index n1 is preferably 0.05 or more, further preferably 0.1 or more, still further preferably 0.15 or more.

For example, the above material having a hole-transport property with an ordinary refractive index higher than or equal to 1.50 and lower than or equal to 1.75 in a blue light emission range (455 nm to 465 nm) or an ordinary refractive index higher than or equal to 1.45 and less than or equal to 1.70 with respect to light of wavelength 633 nm, which is usually used for measurement of refractive indices, can be used for the region 553C.

Note that this embodiment can be combined with any of the other embodiments in this specification as appropriate.

### Embodiment 3

In this embodiment, a structure of the light-emitting device 150 of one embodiment of the present invention is described with reference to FIG. 3A.

FIG. 3A is a cross-sectional view illustrating a structure of the light-emitting device of one embodiment of the present invention.

### Structure Example of Light-Emitting Device 150

The light-emitting device 150 described in this embodiment includes the electrode 101, the electrode 102, and the unit 103 (see FIG. 3A).

### Structure Example of Unit 103

The unit 103 has a single-layer structure or a stacked-layer structure. For example, the unit 103 includes the layer 111, the layer 112, and the layer 113. The layer 111 includes a region interposed between the layer 112 and the layer 113, the layer 112 includes a region interposed between the electrode 101 and the layer 111, and the layer 113 includes a region interposed between the electrode 102 and the layer 111. For example, a layer selected from functional layers such as a hole-transport layer, an electron-transport layer, a hole-injection layer, an electron-injection layer, a carrier-blocking layer, an exciton-blocking layer, and a charge-generation layer can be used in the unit 103.

The structure of the unit 103 described in this embodiment can be applied to the light-emitting device 150 described in another embodiment. Specifically, the structure can be applied to the unit 103(12), the layer 111(12), the layer 111(13), the layer 112(12), the layer 113(12), and the like.

### Structure Example of Layer 112

For example, a material having a hole-transport property can be used for the layer 112. The layer 112 can be referred to as a hole-transport layer. A material having a wider band gap than the light-emitting material included in the layer 111 is preferably used for the layer 112. In that case, energy transfer from excitons generated in the layer 111 to the layer 112 can be inhibited.

### Material Having Hole-Transport Property

The material having a hole-transport property preferably has a hole mobility of 1 × 10⁻⁶ cm²/Vs or more.

The material having a hole-transport property is preferably an amine compound or an organic compound having a π-electron rich heteroaromatic ring skeleton. For example, a compound having an aromatic amine skeleton, a compound having a carbazole skeleton, a compound having a thiophene skeleton, a compound having a furan skeleton, or the like can be used.

The following are examples that can be used as a compound having an aromatic amine skeleton: 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBilBP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]spiro-9,9′-bifluoren-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), or the like can be used.

As a compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or the like can be used.

As a compound having a furan skeleton, for example, 4,4′,4″-(benzene-1,3,5-triyl)tri(dibenzofuran) (abbreviation: DBF3P-II), 4-{3-[3-(9-phenyl-9H-fluoren-9-yl)phenyl]phenyl}dibenzofuran (abbreviation: mmDBFFLBi-II), or the like can be used.

Among the above, the compound having an aromatic amine skeleton and the compound having a carbazole skeleton are preferable because these have favorable reliability, have high hole-transport properties, and contribute to a reduction in driving voltage.

### Structure Example of Layer 113

For example, a material having an electron-transport property, a material having an anthracene skeleton, and a mixed material can be used for the layer 113. The layer 113 can be referred to as an electron-transport layer. A material having a wider band gap than the light-emitting material contained in the layer 111 is preferably used for the layer 113. In that case, energy transfer from excitons generated in the layer 111 to the layer 113 can be inhibited.

### Material Having Electron-Transport Property

As the material having an electron-transport property, a metal complex or an organic compound having a π-electron deficient heteroaromatic ring skeleton is preferably used. As examples of the organic compound having a π-electron deficient heteroaromatic ring skeleton, a heterocyclic compound having a polyazole skeleton, a heterocyclic compound having a diazine skeleton, and a heterocyclic compound having a pyridine skeleton are preferable. In particular, the heterocyclic compound having a diazine skeleton or the heterocyclic compound having a pyridine skeleton has favorable reliability and thus is preferable. Furthermore, the heterocyclic compound having a diazine (pyrimidine or pyrazine) skeleton has a high electron-transport property and contributes to a reduction in driving voltage.

As the metal complex, bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), bis[2-(2-benzothiazolyl)phenolato]zinc(II) (abbreviation: ZnBTZ), or the like can be used, for example.

As the heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or the like can be used, for example.

As the heterocyclic compound having a diazine skeleton, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,8-bis[3-(dibenzothiophen-4-yl)phenyl]benzo[h]quinazoline (abbreviation: 4,8mDBtP2Bqn), or the like can be used, for example.

As the heterocyclic compound having a pyridine skeleton, 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), or the like can be used, for example.

### Material Having Anthracene Skeleton

An organic compound having an anthracene skeleton can be used for the layer 113. In particular, an organic compound having both an anthracene skeleton and a heterocyclic skeleton can be preferably used.

For example, it is possible to use an organic compound having both an anthracene skeleton and a nitrogen-containing five-membered ring skeleton or an organic compound having both an anthracene skeleton and a nitrogen-containing six-membered ring skeleton. Alternatively, it is possible to use an organic compound having both an anthracene skeleton and a nitrogen-containing five-membered ring skeleton where two heteroatoms are included in a ring or an organic compound having a nitrogen-containing six-membered ring skeleton where two heteroatoms are included in a ring. Specifically, it is preferable, as the heterocyclic skeleton, to use a pyrazole ring, an imidazole ring, an oxazole ring, a thiazole ring, a pyrazine ring, a pyrimidine ring, a pyridazine ring, or the like.

### Structure Example of Mixed Material

A material in which a plurality of kinds of substances are mixed can be used for the layer 113. Specifically, a material in which an alkali metal, an alkali metal compound, or an alkali metal complex and a substance having an electron-transport property are mixed can be used. Using such a material is preferable particularly when a composite material is used for the layer 104 and the composite material includes a substance having a relatively deep HOMO level that is greater than or equal to –5.7 eV and less than or equal to –5.4 eV. It is further preferable that the HOMO level of the material having an electron-transport property be greater than or equal to –6.0 eV. As a result, the reliability of the light-emitting device can be improved.

For example, an 8-hydroxyquinolinato structure is preferably included as the metal complex. Note that in the case where the 8-hydroxyquinolinato structure is included, a methyl-substituted product (e.g., a 2-methyl-substituted product or a 5-methyl-substituted product) thereof or the like can also be used. Specifically, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

The concentration of an elemental substance, a compound, or a complex of an alkali metal or an alkali metal preferably changes in the thickness direction of the layer 113 (including the case where the concentration is 0).

### Structure Example of Layer 111

The layer 111 includes a light-emitting material and a host material. The layer 111 can be referred to as a light-emitting layer. The layer 111 is preferably provided in a region where holes and electrons are recombined. This allows efficient conversion of energy generated by recombination of carriers into light and emission of the light. Furthermore, the layer 111 is preferably provided apart from a metal used for the electrode or the like. In that case, a quenching phenomenon caused by the metal used for the electrode or the like can be inhibited.

For example, a fluorescent substance, a phosphorescent substance, or a substance exhibiting thermally activated delayed fluorescence (Thermally Delayed Fluorescence) (also referred to as a TADF material) can be used as the light-emitting material. Thus, energy generated by recombination of carriers can be released as light from the light-emitting material.

### Fluorescent Substance

A fluorescent substance can be used for the layer 111. For example, the following fluorescent substances can be used for the layer 111. Note that fluorescent substances that can be used for the layer 111 are not limited to the following, and a variety of known fluorescent substances can be used.

Specifically, any of the following can be used: 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N-triphenyl-1,4-phenylenediamine (abbreviation: 2DPAPPA), N,N,N′,N′,N″,N″,N‴,N‴-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone, (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij] quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij] quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-(pyrene-1,6-diyl)bis[(6,N-diphenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), and the like.

In particular, a condensed aromatic diamine compound typified by a pyrenediamine compound such as 1,6FLPAPrn, 1,6mMemFLPAPrn, or 1,6BnfAPrn-03 is preferable because of its high hole-trapping property, high emission efficiency, or high reliability.

### Phosphorescent Substance 1

A phosphorescent substance can be used for the layer 111. For example, the following phosphorescent substances can be used for the layer 111. Note that phosphorescent substances that can be used for the layer 111 are not limited to the following, and a variety of known phosphorescent substances can be used.

Specifically, an organometallic iridium complex having a 4H-triazole skeleton, or the like can be used for the layer 111. Specifically, tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

Alternatively, for example, an organometallic iridium complex having a 1H-triazole skeleton, or the like can be used. Specifically, tris[3-methyl-1-(2-methylphenyl)-5-phenyl-1H-1,2,4-triazolato]iridium(III) (abbreviation: [Ir(Mptzl-mp)₃]), tris(1-methyl-5-phenyl-3-propyl-1H-1,2,4-triazolato]iridium(III) (abbreviation: [Ir(Prptzl-Me)₃]), or the like can be used.

Alternatively, for example, an organometallic iridium complex having an imidazole skeleton, or the like can be used. Specifically, fac-tris[1-(2,6-diisopropylphenyl)-2-phenyl-1H-imidazole]iridium(III) (abbreviation: [Ir(iPrpmi)₃]), tris[3-(2,6-dimethylphenyl)-7-methylimidazo[1,2-f]phenanthridinato]iridium(III) (abbreviation: [Ir(dmpimpt-Me)₃]), or the like can be used.

Alternatively, for example, an organometallic iridium complex having a phenylpyridine derivative with an electron-withdrawing group as a ligand, or the like can be used. Specific examples include bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac).

Note that these are compounds exhibiting blue phosphorescence, and are compounds having an emission wavelength peak at 440 nm to 520 nm.

### Phosphorescent Substance 2

For example, an organometallic iridium complex having a pyrimidine skeleton, or the like can be used for the layer 111. Specifically, any of the following can be used: tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbomyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), and the like.

For example, an organometallic iridium complex having a pyrazine skeleton, or the like can be used. Specifically, any of the following can be used: (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), and the like.

For example, an organometallic iridium complex having a pyridine skeleton, or the like can be used. Specifically, any of the following can be used: tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²′)iridium(III) acetylacetonate (abbreviation: [Ir(pq)₂(acac)]), [2-d3-methyl-(2-pyridinyl-κN)benzofuro[2,3-b]pyridine-κC]bis[2-(5-d3-methyl-2-pyridyl-κN2)phenyl-κ]iridium(III) (abbreviation: [Ir(5mppy-d3)2(mbfpypy-d3)]), [2-d3-methyl-(2-pyridinyl-κN)benzofuro[2,3-Z>]pyridine-κC]bis[2-(2-pyridinyl-κN)phenyl-κC]iridium(III) (abbreviation: [Ir(ppy)2(mbfpypy-d3)]), and the like.

For example, a rare earth metal complex or the like can be used. Specifically, tris(acetylacetonato) (monophenanthroline)terbium(III) (abbreviation: [Tb(acac)₃(Phen)]) or the like can be given.

Note that these are compounds mainly exhibiting green phosphorescence, and have an emission wavelength peak at 500 nm to 600 nm. Note that an organometallic iridium complex having a pyrimidine skeleton is particularly preferable because of its distinctively high reliability or emission efficiency.

### Phosphorescent Substance 3

For example, an organometallic iridium complex having a pyrimidine skeleton, or the like can be used for the layer 111. Specifically, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato] (dipivaloylmethanato)iridium(III) (abbreviation: [Ir(5mdppm)₂(dpm)]), bis[4,6-di(naphthalen-1-yl)pyrimidinato] (dipivaloylmethanato)iridium(III) (abbreviation: [Ir(dlnpm)₂(dpm)]), or the like can be used.

For example, an organometallic iridium complex having a pyrazine skeleton, or the like can be used. Specifically, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

For example, an organometallic iridium complex having a pyridine skeleton, or the like can be used. Specifically, tris(1-phenylisoquinolinato-N,C²′)iridium(III) (abbreviation: [Ir(piq)₃]), bis(1-phenylisoquinolinato-N,C²′)iridium(III) acetylacetonate (abbreviation: [Ir(piq)₂(acac)]), or the like can be used.

For example, a platinum complex or the like can be used. Specifically, 2,3,7,8,12,13,17,18-octaethyl-21H,23H-porphyrin platinum(II) (abbreviation: PtOEP) or the like can be used.

For example, a rare earth metal complex or the like can be used. Specifically, tris(1,3-diphenyl-1,3-propanedionato)(monophenanthroline)europium(III) (abbreviation: [Eu(DBM)₃(Phen)]), tris[1-(2-thenoyl)-3,3,3-trifluoroacetonato] (monophenanthroline)europium(III) (abbreviation: [Eu(TTA)₃(Phen)]), or the like can be used.

Note that these are compounds exhibiting red phosphorescence, and have an emission peak at 600 nm to 700 nm. Furthermore, from the organometallic iridium complex having a pyrazine skeleton, red light emission with chromaticity favorably used for display devices can be obtained.

### Substance Exhibiting Thermally Activated Delayed Fluorescence (TADF)

A variety of known TADF materials can be used as the light-emitting material.

The TADF material has a small difference between the S1 level and the T1 level and is capable of converting triplet excitation energy into singlet excitation energy by reverse intersystem crossing. Thus, it is possible to upconvert triplet excitation energy into singlet excitation energy (reverse intersystem crossing) using a little thermal energy and to efficiently generate a singlet excited state. In addition, the triplet excitation energy can be converted into light emission.

An exciplex whose excited state is formed by two kinds of substances has an extremely small difference between the S1 level and the T1 level and has a function of a TADF material that can convert triplet excitation energy into singlet excitation energy.

Note that a phosphorescent spectrum observed at low temperatures (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between S1 and T1 of the TADF material is preferably less than or equal to 0.3 eV, further preferably less than or equal to 0.2 eV.

When the TADF material is used as a light-emitting substance, the S1 level of the host material is preferably higher than the S1 level of the TADF material. In addition, the T1 level of the host material is preferably higher than the T1 level of the TADF material.

For example, a fullerene, a derivative thereof, an acridine, a derivative thereof, an eosin derivative, or the like can be used as the TADF material. Furthermore, porphyrin containing a metal such as magnesium (Mg), zinc (Zn), cadmium (Cd), tin (Sn), platinum (Pt), indium (In), or palladium (Pd) can be used as the TADF material.

Specifically, any of the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

Chemical formula 11

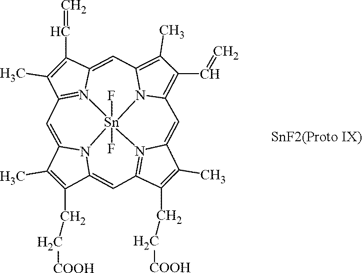

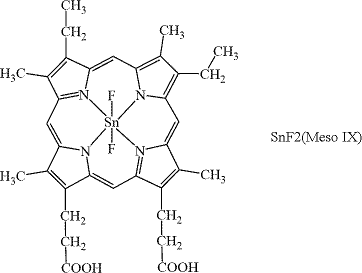

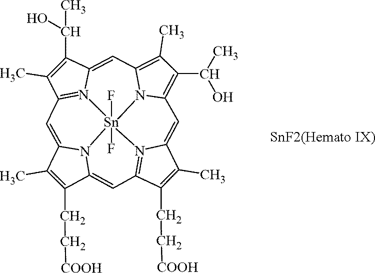

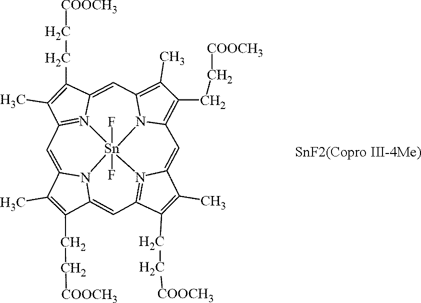

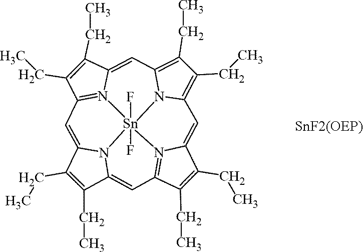

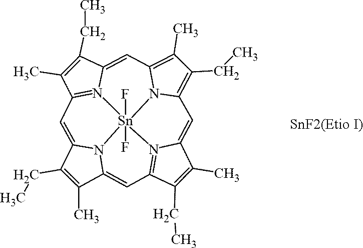

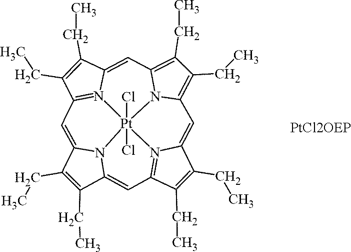

Furthermore, a heterocyclic compound including one or both of a π-electron rich heteroaromatic ring and a π-electron deficient heteroaromatic ring can be used, for example, as the TADF material.

Specifically, any of the following materials whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazine-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

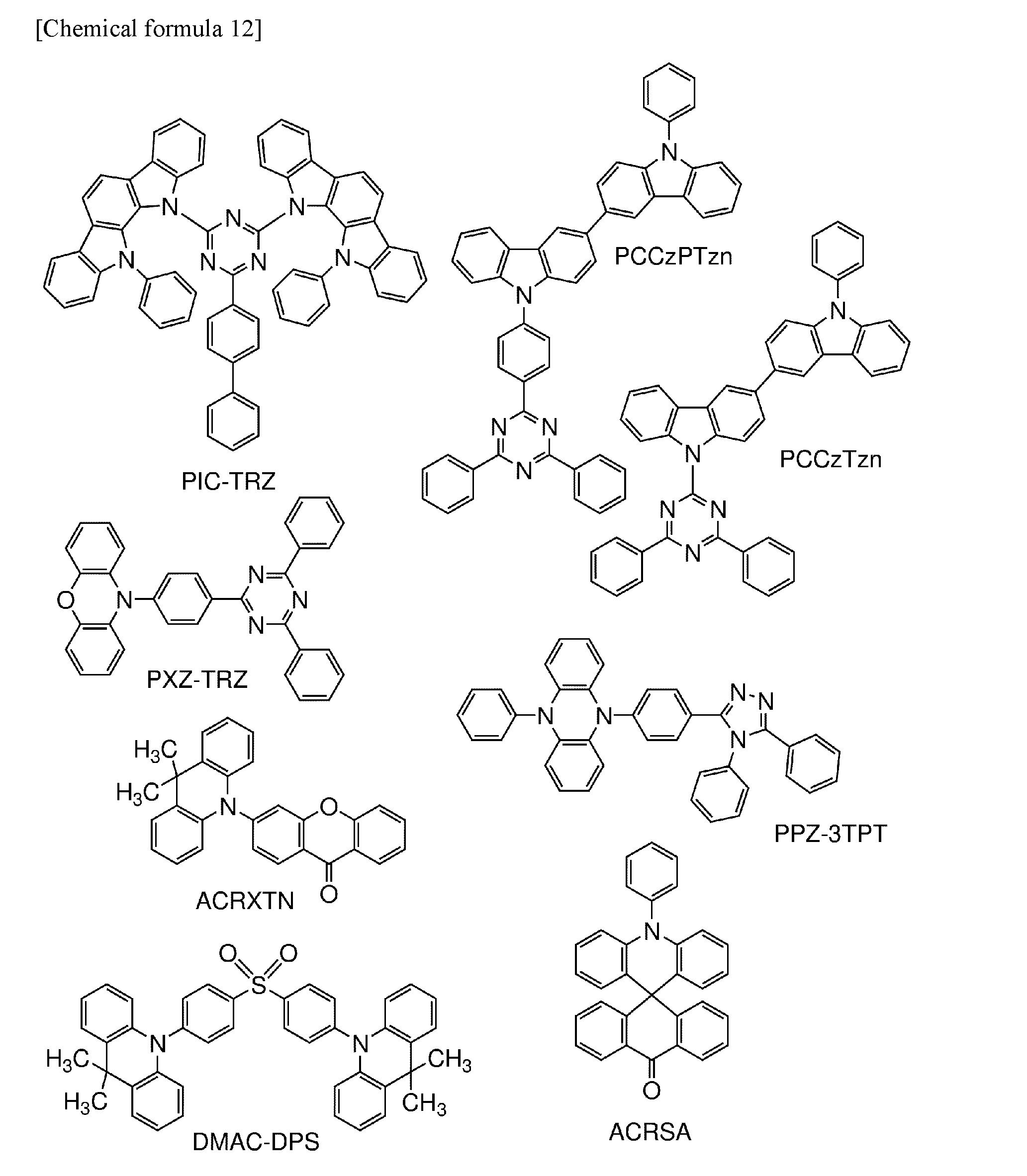 [SMILES: c1ccc2c(c1)sc1c(-c3cc(-c4cccc5c4sc4ccccc45)cc(-c4cccc5c4sc4ccccc45)c3)cccc12 ; "DBT3P-II"]

These heterocyclic compounds are preferable because of having both a high electron-transport property and a high hole-transport property owing to the π-electron rich heteroaromatic ring and the π-electron deficient heteroaromatic ring. Among skeletons having a π-electron deficient heteroaromatic ring, a pyridine skeleton, a diazine skeleton (a pyrimidine skeleton, a pyrazine skeleton, and a pyridazine skeleton), and a triazine skeleton are particularly preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and reliability.

Among skeletons having a π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. Note that a dibenzofuran skeleton and a dibenzothiophene skeleton are preferable as the furan skeleton and the thiophene skeleton, respectively. As the pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which a π-electron rich heteroaromatic ring and a π-electron deficient heteroaromatic ring are directly bonded to each other is particularly preferable because the electron-donating property of the π-electron rich heteroaromatic ring and the electron-accepting property of the π-electron deficient heteroaromatic ring are both increased and the energy difference between the S1 level and the T1 level becomes small, and thus thermally activated delayed fluorescence can be obtained efficiently. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a boron-containing skeleton such as phenylborane or boranthrene, an aromatic ring or a heteroaromatic ring having a nitrile group or a cyano group, such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

### Structure Example 2 of Layer 111

A material having a carrier-transport property can be used as the host material. For example, a material having a hole-transport property, a material having an electron-transport property, a substance exhibiting thermally activated delayed fluorescence TADF (Thermally Delayed Fluorescence), a material having an anthracene skeleton, or a mixed material can be used as the host material.

### Material Having Hole-Transport Property

For example, a material having a hole-transport property that can be used for the layer 112 can be used for the layer 112. Specifically, a material having a hole-transport property that can be used for the hole-transport layer can be used for the layer 111.

### Material Having Electron-Transport Property

For example, a material having an electron-transport property that can be used for the layer 113 can be used for the layer 111. Specifically, a material having an electron-transport property that can be used for the electron-transport layer can be used for the layer 111.

### Substance Exhibiting Thermally Activated Delayed Fluorescence (TADF)

A variety of known TADF materials can be used as the host material.

When the TADF material is used as the host material, triplet excitation energy generated in the TADF material is converted into singlet excitation energy by reverse intersystem crossing and transferred to the light-emitting substance, whereby the emission efficiency of the light-emitting device can be increased. At this time, the TADF material functions as an energy donor, and the light-emitting substance functions as an energy acceptor.

This is very effective in the case where the light-emitting substance is a fluorescent substance. In that case, the S1 level of the TADF material is preferably higher than the S1 level of the fluorescent substance in order to achieve high emission efficiency. Furthermore, the T1 level of the TADF material is preferably higher than the S1 level of the fluorescent substance. Therefore, the T1 level of the TADF material is preferably higher than the T1 level of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In order that singlet excitation energy is efficiently generated from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that causes light emission) of the fluorescent substance. As the protective group, a substituent having no π bond and saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituent having no π bond has a poor carrier-transport property; thus, the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a π bond, further preferably includes an aromatic ring, still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, a phenothiazine skeleton, and the like. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

For example, the TADF material that can be used as the light-emitting material can be used as the host material.

### Material Having Anthracene Skeleton

A material having an anthracene skeleton is particularly preferable as the host material in the case where a fluorescent substance is used as the light-emitting substance. The use of a substance having an anthracene skeleton as a host material for a fluorescent substance makes it possible to achieve a light-emitting layer with favorable emission efficiency and durability.

As the substance having an anthracene skeleton that is used as the host material, a substance having a diphenylanthracene skeleton, in particular, a substance having a 9,10-diphenylanthracene skeleton, is preferable because of its chemical stability.

The host material preferably has a carbazole skeleton because the hole-injection/transport properties are improved. In particular, the host material having a dibenzocarbazole skeleton is preferable because its HOMO level is shallower than that of carbazole by approximately 0.1 eV so that holes enter the host material easily, the hole-transport property is improved, and the heat resistance is increased. Thus, a substance having both of a 9,10-diphenylanthracene skeleton, which is an anthracene skeleton, and a carbazole skeleton (or a benzocarbazole skeleton or a dibenzocarbazole skeleton) is preferable as the host material. Note that in terms of the hole-injection/transport properties described above, instead of a carbazole skeleton, a benzofluorene skeleton or a dibenzofluorene skeleton may be used.

Examples of the substance having an anthracene skeleton include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), and 9-(1-naphthyl)-10-[4-(2-naphthyl)phenyl]anthracene (abbreviation: αN-βNPAnth).

In particular, CzPA, cgDBCzPA, 2mBnfPPA, and PCzPA have excellent characteristics.

### Structure Example 1 of Mixed Material

A material in which a plurality of kinds of substances are mixed can be used as the host material. For example, a material in which a material having an electron-transport property and a material having a hole-transport property are mixed can be favorably used as the host material. When the material having an electron-transport property is mixed with the material having a hole-transport property, the carrier-transport property of the layer 111 can be easily adjusted. A recombination region can also be controlled easily. The weight ratio of the material having a hole-transport property to the material having an electron-transport property in the mixed material is the material having a hole-transport property: the material having an electron-transport property = 1:19 to 19:1 inclusive.

### Structure Example 2 of Mixed Material

In addition, a material mixed with a phosphorescent substance can be used as the host material. When a fluorescent substance is used as the light-emitting substance, a phosphorescent substance can be used as an energy donor for supplying excitation energy to the fluorescent substance.

A mixed material containing a material to form an exciplex can be used as the host material. For example, a material in which an emission spectrum of a formed exciplex overlaps with a wavelength of the absorption band on the lowest energy side of the light-emitting substance can be used as the host material. This enables smooth energy transfer and improves emission efficiency. Alternatively, the driving voltage can be reduced.

Note that at least one of the materials forming an exciplex may be a phosphorescent substance. In this case, triplet excitation energy can be efficiently converted into singlet excitation energy by reverse intersystem crossing.

A combination of a material having an electron-transport property and a material having a hole-transport property whose HOMO level is higher than or equal to the HOMO level of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

Note that the formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side), observed by comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed by comparison of the transient EL of the material having a hole-transport property, the transient EL of the material having an electron-transport property, and the transient EL of the mixed film of these materials.

Note that this embodiment can be combined with any of the other embodiments in this specification as appropriate.

### Embodiment 4

In this embodiment, a structure of the light-emitting device 150 of one embodiment of the present invention is described with reference to FIG. 3A.

FIG. 3A is a cross-sectional view illustrating a structure of the light-emitting device of one embodiment of the present invention.

### Structure Example of Light-Emitting Device 150

The light-emitting device 150 described in this embodiment includes the electrode 101, the electrode 102, the unit 103, the layer 104, and a layer 105 (see FIG. 3A). The electrode 102 includes a region overlapping with the electrode 101, and the layer 104 includes the region interposed between the unit 103 and the electrode 101.

For example, the structure described in Embodiment 3 can be used for the unit 103.

### Structure Example of Electrode 101

A conductive material can be used for the electrode 101. Specifically, a metal, an alloy, a conductive compound, a mixture of these, or the like can be used for the electrode 101. For example, a material having a work function higher than or equal to 4.0 eV can be suitably used.

The structure of the electrode 101 described in this embodiment can be applied to the light-emitting device 150 described in another embodiment. Specifically, the structure can also be used for the electrode 551(i, j).

For example, indium oxide-tin oxide (ITO: Indium Tin Oxide), indium oxide-tin oxide containing silicon or silicon oxide, indium oxide-zinc oxide, indium oxide containing tungsten oxide and zinc oxide (IWZO), or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), a nitride of a metal material (such as titanium nitride), or the like can be used. Alternatively, graphene can be used.

### Structure Example of Layer 104

The layer 104 includes a region interposed between the electrode 101 and the unit 103. Note that the layer 104 can be referred to as a hole-injection layer.

The structure of the layer 104 described in this embodiment can be applied to the light-emitting device 150 described in another embodiment. Specifically, the structure can also be applied to the layer 104(12) and the like.

For example, a material having a hole-injection property can be used for the layer 104. Specifically, a substance having an acceptor property and a composite material can be used for the layer 104. Note that an organic compound and an inorganic compound can be used as the substance having an acceptor property. The material having an acceptor property can extract electrons from an adjacent hole-transport layer (or a hole-transport material) by the application of an electric field.

### Example 1 of Material Having Hole-Injection Property

The substance having an acceptor property can be used as the material having a hole-injection property. This can facilitate injection of holes from the electrode 101, for example. Alternatively, the driving voltage of the light-emitting device can be reduced.

For example, a compound having an electron-withdrawing group (a halogen group or a cyano group) can be used as the substance having an acceptor property. Note that an organic compound having an acceptor property is easily evaporated and deposited. As a result, the productivity of the light-emitting device can be increased.

Specifically, any of the following materials can be used as the hole-injection material: 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylen-1,3,4,5,6,8,9,10-octafluoro-7H-pyren-2-ylidene)malononitrile, and the like.

A compound in which electron-withdrawing groups are bonded to a condensed aromatic ring having a plurality of heteroatoms, such as HAT-CN, is particularly preferable because it is thermally stable.

Alternatively, a [3]radialene derivative including an electron-withdrawing group (in particular, a cyano group or a halogen group such as a fluoro group) is preferable because it has a very high electron-accepting property.

Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like can be used.

As the substance having an acceptor property, a molybdenum oxide, a vanadium oxide, a ruthenium oxide, a tungsten oxide, a manganese oxide, or the like can be used.

Alternatively, it is possible to use any of the following: phthalocyanine-based complex compounds such as phthalocyanine (abbreviation: H₂Pc) and copper phthalocyanine (CuPc); and compounds having an aromatic amine skeleton such as 4,4′-bis[N-(4-diphenylaminophenyl)-N-phenylamino]biphenyl (abbreviation: DPAB) and N,N′-bis{4-[bis(3-methylphenyl)amino]phenyl }-N,N-diphenyl-(1, 1′-biphenyl)-4,4′-diamine (abbreviation: DNTPD).

In addition, a high molecular compound such as poly(3,4-ethylenedioxythiophene)/poly(styrenesulfonic acid) (PEDOT/PSS), or the like can be used.

### Example 2 of Material Having Hole-Injection Property

A composite material can be used as the material having a hole-injection property. For example, a composite material in which a material having a hole-transport property contains a substance having an acceptor property can be used. Thus, selection of a material used to form an electrode can be carried out in a wide range regardless of work function. Specifically, besides a material having a high work function, a material having a low work function can also be used for the electrode 101.

A variety of organic compounds can be used as a material having a hole-transport property in the composite material. As the material having a hole-transport property in the composite material, for example, a compound having an aromatic amine skeleton, a carbazole derivative, an aromatic hydrocarbon, a high molecular compound (such as an oligomer, a dendrimer, or a polymer), or the like can be used. A substance having a hole mobility higher than or equal to 1 × 10⁻⁶ cm²/Vs can be favorably used.

Alternatively, for example, a substance having a relatively deep HOMO level that is greater than or equal to –5.7 eV and less than or equal to –5.4 eV can be favorably used as the material having a hole-transport property in the composite material. Accordingly, hole injection to the hole-transport layer can be facilitated. Furthermore, reliability of the light-emitting device can be improved.

Examples of the compounds having an aromatic amine skeleton include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl }-N,N-diphenyl-(1, 1′-biphenyl)-4,4′-diamine (abbreviation: DNTPD), 1,3,5-tris[N-(4-diphenylaminophenyl)-N-phenylamino]benzene (abbreviation: DPA3B), and the like.

Examples of the carbazole derivative include 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(N-carbazolyl)]phenyl-10-phenylanthracene (abbreviation: CzPA), 1,4-bis[4-(N-carbazolyl)phenyl]-2,3,5,6-tetraphenylbenzene, and the like.

Examples of the aromatic hydrocarbon include 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, and the like.

As an aromatic hydrocarbon having a vinyl group, the following can be given for example: 4,4′-bis(2,2-diphenylvinyl)biphenyl (abbreviation: DPVBi), 9,10-bis[4-(2,2-diphenylvinyl)phenyl]anthracene (abbreviation: DPVPA), and the like.

Other examples include pentacene and coronene.

As the high molecular compound, poly(N-vinylcarbazole) (abbreviation: PVK), poly(4-vinyltriphenylamine) (abbreviation: PVTPA), poly[N(4-{N′-[4-(4-diphenylamino)phenyl]phenyl-N′-phenylamino}phenyl)methacrylamide] (abbreviation: PTPDMA), poly[N,N′-bis(4-butylphenyl)-N,N′-bis(phenyl)benzidine] (abbreviation: Poly-TPD), or the like can be used.

Furthermore, a substance having any of a carbazole skeleton, a dibenzofuran skeleton, a dibenzothiophene skeleton, or an anthracene skeleton can be favorably used as the material having a hole-transport property in the composite material, for example. Moreover, a substance including any of the following can be used: an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With the use of a substance including a N,N-bis(4-biphenyl)amino group, reliability of the light-emitting device can be improved.

Examples of the material having a hole-transport property in the composite material include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-diphenyl-4′-(2-naphthyl)-4″-{9-(4-biphenylyl)carbazole)}triphenylamine (abbreviation: YGTBiβNB), N-[4-(9-phenyl-9H-carbazol-3-yl)phenyl]-N-[4-(1-naphthyl)phenyl]-9,9′-spirobi(9H-fluoren)-2-amine (abbreviation: PCBNBSF), N,Nbis(4-biphenylyl)-9,9′-spirobi[9H-fluoren]-2-amine (abbreviation: BBASF), N,N-bis(1,1′-biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi(9H-fluoren)-4-amine (abbreviation: oFBiSF), N-(4-biphenyl)-N-(dibenzofuran-4-yl)-9,9-dimethyl-9H-fluoren-2-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-9,9-dimethyl-N-[4-(9-phenyl-9H-carbazol-3-yl)phenyl]-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, and the like.

### Example 3 of Material Having Hole-Injection Property

A composite material including a material having a hole-transport property, a substance having an acceptor property, and a fluoride of an alkali metal or an alkaline earth metal can be used as the material having a hole-injection property. In particular, a composite material in which the proportion of fluorine atoms is higher than or equal to 20% can be favorably used. Thus, the refractive index of the layer 104 can be reduced. Alternatively, a layer with a low refractive index can be formed inside the light-emitting device. Alternatively, the external quantum efficiency of the light-emitting device can be improved.

Note that this embodiment can be combined with any of the other embodiments in this specification as appropriate.

### Embodiment 5

In this embodiment, a structure of the light-emitting device 150 of one embodiment of the present invention is described with reference to FIG. 3A.

FIG. 3A is a cross-sectional view illustrating a structure of the light-emitting device of one embodiment of the present invention.

### Structure Example of Light-Emitting Device 150

The light-emitting device 150 described in this embodiment includes the electrode 101, the electrode 102, the unit 103, the layer 104, and the layer 105 (see FIG. 3A). The electrode 102 includes a region overlapping with the electrode 101, and the layer 105 includes a region interposed between the unit 103 and the electrode 102.

For example, the structure described in Embodiment 3 can be used for the unit 103.

### Structure Example of Electrode 102

A conductive material can be used for the electrode 102. Specifically, a metal, an alloy, an electrically conductive compound, a mixture of these, or the like can be used for the electrode 102. For example, a material having a lower work function than the electrode 101 can be used for the electrode 102. Specifically, a material having a work function less than or equal to 3.8 eV can be favorably used.

The structure of the electrode 102 described in this embodiment can be applied to the light-emitting device 150 described in another embodiment. Specifically, the structure can also be used for the electrode 552.

For example, an element belonging to Group 1 of the periodic table, an element belonging to Group 2 of the periodic table, a rare earth metal, or an alloy containing any of these elements can be used for the electrode 102.

Specifically, lithium (Li), cesium (Cs), or the like; magnesium (Mg), calcium (Ca), strontium (Sr), or the like; europium (Eu), ytterbium (Yb), or the like; or an alloy containing any of these (MgAg or AlLi) can be used for the electrode 102.

### Structure Example of Layer 105

The layer 105 includes a region interposed between the electrode 101 and the unit 103. Note that the layer 104 can be referred to as a hole-injection layer.

The structure of the layer 105 described in this embodiment can be applied to the light-emitting device 150 described in another embodiment. Specifically, the structure can also be applied to the layer 105(12) and the like.

A material having an electron-injection property can be used for the layer 105, for example. Specifically, a substance having a donor property can be used for the layer 105. Alternatively, a composite material in which a substance having a donor property is contained in the material having an electron-transport property can be used for the layer 105. This can facilitate injection of electrons from the electrode 102, for example. Alternatively, the driving voltage of the light-emitting device can be reduced. Alternatively, a variety of conductive materials can be used for the electrode 102 regardless of the work function. Specifically, Al, Ag, ITO, indium oxide-tin oxide containing silicon or silicon oxide, or the like can be used for the electrode 102.

### Material Having Electron-Injection Property 1

For example, an alkali metal, an alkaline earth metal, a rare earth metal, or a compound thereof can be used as the substance having a donor property. Alternatively, an organic compound such as tetrathianaphthacene (abbreviation: TTN), nickelocene, or decamethylnickelocene can be used as the substance having a donor property.

Specifically, an alkali metal compound (including an oxide, a halide, and a carbonate), an alkaline earth metal compound (including an oxide, a halide, and a carbonate), a rare earth metal compound (including an oxide, a halide, and a carbonate)), or the like can be used as the material having an electron-injection property.

Specifically, lithium oxide, lithium fluoride (LiF), cesium fluoride (CsF), calcium fluoride (CaF₂), lithium carbonate, cesium carbonate, 8-hydroxyquinolinato-lithium (abbreviation: Liq), or the like can be used as the material having an electron-injection property.

### Material Having Electron-Injection Property 2

For example, a composite material that contains a substance having an electron-transport property and any of an alkali metal, an alkaline earth metal, or a compound thereof can be used as the material having an electron-injection property.

For example, a material having an electron-transport property capable of being used for the unit 103 can be used as the material having an electron-injection property.

Furthermore, as the material having an electron-injection property, a material that includes a fluoride of an alkali metal in a microcrystalline state and a substance having an electron-transport property, or a material that includes a fluoride of an alkali earth metal in a microcrystalline state and a substance having an electron-transport property can be used.

In particular, a material including a fluoride of an alkali metal or a fluoride of an alkaline earth metal at 50 wt% or higher can be suitably used. Alternatively, an organic compound having a bipyridine skeleton can be suitably used. Thus, the refractive index of the layer 105 can be reduced. Alternatively, the external quantum efficiency of the light-emitting device can be improved.

### Material 3 Having Electron-Injection Property

Furthermore, electride can be used as the material having an electron-injection property. For example, a substance obtained by adding electrons at high concentration to an oxide where calcium and aluminum are mixed can be used, for example, as the material having an electron-injection property.

Note that this embodiment can be combined with any of the other embodiments in this specification as appropriate.

### Embodiment 6

In this embodiment, a structure of the light-emitting device 150 of one embodiment of the present invention is described with reference to FIG. 3B.

FIG. 3B is a diagram illustrating a structure of the light-emitting device of one embodiment of the present invention which is different from the structure in FIG. 3A.

### Structure Example of Light-Emitting Device 150

The light-emitting device 150 described in this embodiment includes the electrode 101, the electrode 102, the unit 103, and the intermediate layer 106 (see FIG. 3B).

For example, the structure described in Embodiment 3 can be used for the unit 103.

### Structure Example of Intermediate Layer 106

The intermediate layer 106 includes a region interposed between the unit 103 and the electrode 102, and the intermediate layer 106 includes the layer 106A and a layer 106B.

The structure of the intermediate layer 106 described in this embodiment can be applied to the light-emitting device 150 described in another embodiment.

### Structure Example of Layer 106A

The layer 106A includes a region interposed between the unit 103 and the layer 106B. Note that the layer 106A can be referred to, for example, an electron-relay layer.

For example, a substance having an electron-transport property can be used for the electron-relay layer. Accordingly, a layer that is on the anode side and in contact with the electron-relay layer can be distanced from a layer that is on the cathode side and in contact with the electron-relay layer. Alternatively, interaction between the layer that is on the anode side and in contact with the electron-relay layer and the layer that is on the cathode side and in contact with the electron-relay layer can be reduced. Alternatively, electrons can be smoothly supplied to the layer that is on the anode side and in contact with the electron-relay layer.

For example, a substance having an electron-transport property can be favorably used for the electron-relay layer. Specifically, a substance whose LUMO level is positioned between the LUMO level of the substance having an acceptor property in the composite material given as the material having a hole-injection property and the LUMO level of the substance included in the layer that is on the cathode side and in contact with the electron-relay layer can be favorably used for the electron-relay layer.

For example, a substance having an electron-transport property, which has a LUMO level in a range higher than or equal to –5.0 eV, preferably higher than or equal to –5.0 eV and lower than or equal to –3.0 eV, can be used for the electron-relay layer.

Specifically, a phthalocyanine-based material can be used for the electron-relay layer. Alternatively, a metal complex having a metal-oxygen bond and an aromatic ligand can be used for the electron-relay layer.

### Structure Example of Layer 106B

The layer 106B can be referred to, for example, as a charge-generation layer. The charge-generation layer has a function of supplying electrons to the anode side and supplying holes to the cathode side by applying voltages. Specifically, electrons can be supplied to the unit 103 that is positioned on the anode side.

For example, any of the composite materials exemplified as the material having a hole-injection property can be used for the charge-generation layer. In addition, for example, a stacked film in which a film including the composite material and a film including a material having a hole-transport property are stacked can be used as the charge-generation layer.

Note that this embodiment can be combined with any of the other embodiments in this specification as appropriate.

### Embodiment 7

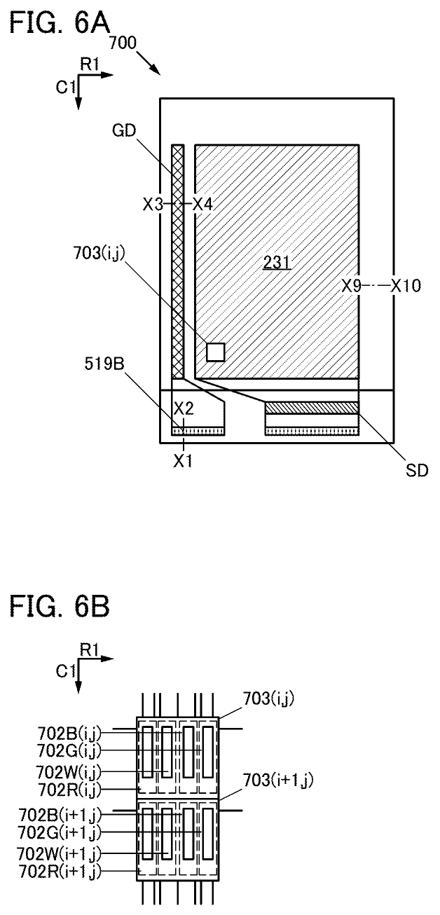

In this embodiment, structures of a functional panel of one embodiment of the present invention will be described with reference to FIG. 6 to FIG. 8.

FIG. 6A is a top view illustrating a structure of the functional panel of one embodiment of the present invention, and FIG. 6B is a diagram illustrating part of FIG. 6A.

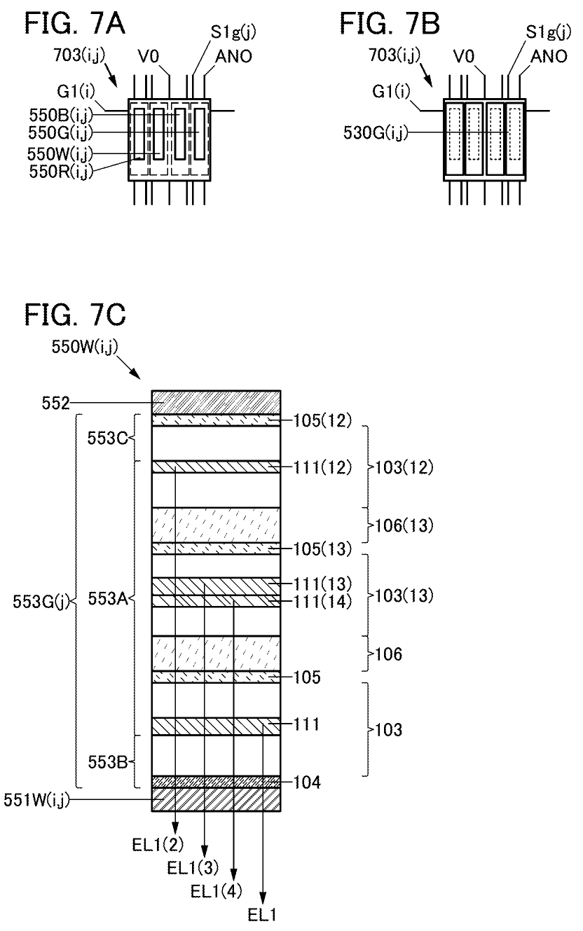

FIG. 7A is a diagram illustrating part of FIG. 6A. FIG. 7B is a cross-sectional view illustrating part of FIG. 7A, and FIG. 7C is a diagram illustrating another part of FIG. 7A.

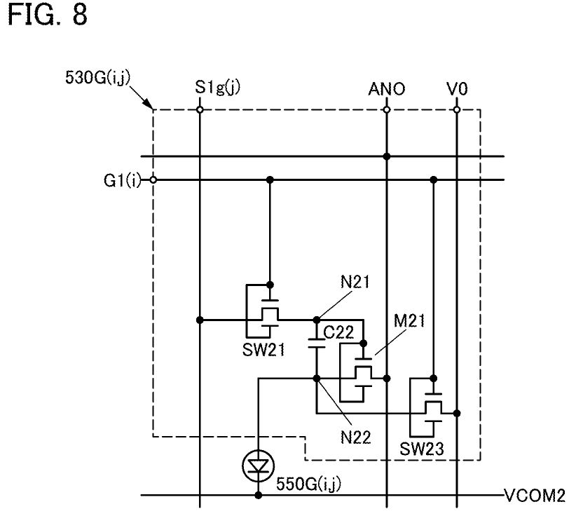

FIG. 8 is a circuit diagram illustrating a structure of a pixel circuit that can be used for the functional panel of one embodiment of the present invention.

### Structure Example 1 of Functional Panel 700

The functional panel 700 includes a region 231. The region 231 includes a set of pixels 703(i, j) (see FIG. 6A).

The functional panel 700 includes a conductive film G1(i), a conductive film S1g(j), a conductive film ANO, and a conductive film VCOM2 (see FIG. 8). The functional panel 700 includes a conductive film V0.

For example, the conductive film G1(i) is supplied with a first selection signal, and the conductive film Slg(j) is supplied with an image signal.

### Structure Example 1 of Pixel 703(i, j)

The set of pixels 703(i, j) includes the pixel 702G(i, j) (see FIG. 6B). The pixel 702G(i, j) includes a pixel circuit 530G(i, j) and a light-emitting device 550G(i, j) (see FIG. 7A and FIG. 7B). In addition, the pixel set 703(i, j) includes a pixel 702B(i, j), a pixel 702R(i, j), and a pixel 702W(i, j), the pixel 702B(i, j) includes a light-emitting device 550B(i, j), and the pixel 702R(i, j) includes a light-emitting device 550R(i, j). The pixel 702W(i, j) includes a pixel circuit 530W(i, j) and the light-emitting device 550W(i, j).

### Structure Example of Pixel Circuit 530G(i, j)

The pixel circuit 530G(i, j) is supplied with the first selection signal, and the pixel circuit 530G(i, j) obtains an image signal on the basis of the first selection signal. For example, the first selection signal can be supplied using the conductive film G1(i) (see FIG. 7B). The image signal can be supplied using the conductive film S1g(j). Note that the operation of supplying the first selection signal and making the pixel circuit 530G(i, j) obtain an image signal can be referred to as “writing”.

The pixel circuit 530G(i, j) includes a switch SW21, a transistor M21, a capacitor C22, and a node N21 (see FIG. 8). In addition, the pixel circuit 530G(i, j) includes a node N22 and a switch SW23.

The transistor M21 includes a gate electrode electrically connected to the node N21, a first electrode electrically connected to the light-emitting device 550G(i, j), and a second electrode electrically connected to a conductive film ANO.

The switch SW21 includes a first terminal electrically connected to the node N21 and a second terminal electrically connected to the conductive film S1g(j), and has a function of controlling the conduction state or the non-conduction state on the basis of a potential of the conductive film G1(i).

The capacitor C22 includes a conductive film electrically connected to the node N21 and a conductive film electrically connected to a first electrode of the transistor M21.

The switch SW23 includes a first terminal electrically connected to the conductive film V0 and a second terminal electrically connected to the first electrode of the transistor M21, and has a function of controlling the conduction state or the non-conduction state on the basis of the potential of the conductive film G1(i). Note that the first terminal of the switch SW23 is electrically connected to the node N22.

Thus, an image signal can be stored in the node N21. The potential of the node N22 can be changed using the switch SW23. The intensity of light emitted from the light-emitting device 550G(i, j) can be controlled with the potential of the node N21. As a result, a novel functional panel that is highly convenient or reliable can be provided.

### Structure Example of Light-Emitting Device 550G(i,j)

The light-emitting device 550G(i, j) is electrically connected to the pixel circuit 530G(i, j) (see FIG. 7A and FIG. 8).

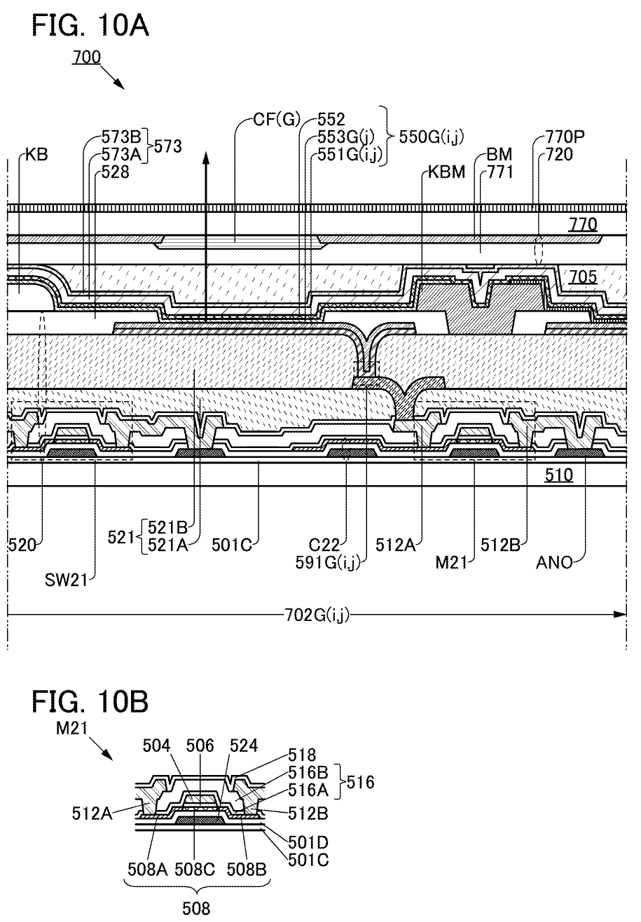

The light-emitting device 550G(i, j) includes the electrode 551G(i, j) electrically connected to the pixel circuit 530G(i, j), and the electrode 552 electrically connected to the conductive film VCOM2 (see FIG. 8 and FIG. 10A). Note that the light-emitting device 550G(i, j) has a function of operating on the basis of the potential of the node N21.

For example, an organic electroluminescence element, an inorganic electroluminescence element, a light-emitting diode, a QDLED (Quantum Dot LED), or the like can be used as the light-emitting device 550G(i, j).

Specifically, the structure described in Embodiment 1 to Embodiment 6 can be used for the light-emitting device 550G(i, j).

### Structure Example 2 of Pixel 703(i, j)

A plurality of pixels can be used in the pixel 703(i, j). For example, a plurality of pixels capable of displaying colors with different hues can be used. Note that the plurality of pixels can be referred to as subpixels. A set of subpixels can be referred to as a pixel.

This enables additive mixture of colors displayed by the plurality of pixels. It is possible to display a color of a hue that an individual pixel cannot display.

Specifically, a pixel 702B(i, j) displaying blue, the pixel 702G(i, j) displaying green, and a pixel 702R(i, j) displaying red can be used in the pixel 703(i, j). The pixel 702B(i, j), the pixel 702G(i, j), and the pixel 702R(i, j) can each be referred to as a subpixel (see FIG. 6B).

The pixel 702W(i, j) displaying white or the like can be used in addition to the above set in the pixel 703(i, j), for example. A pixel displaying cyan, a pixel displaying magenta, and a pixel displaying yellow can be used in the pixel 703(i, j).

A pixel emitting infrared rays can be used in addition to the above set in the pixel 703(i, j), for example. Specifically, a pixel that emits light including light with a wavelength of greater than or equal to 650 nm and less than or equal to 1000 nm can be used in the pixel 703(i, j).

### Structure Example 2 of Functional Panel 700

The functional panel described in this embodiment includes a driver circuit GD and a driver circuit SD (see FIG. 6A).

### Structure Example of Driver Circuit GD

The driver circuit GD has a function of supplying the first selection signal. For example, the driver circuit GD is electrically connected to the conductive film G1(i) and supplies the first selection signal.

### Structure Example of Driver Circuit SD

The driver circuit SD is electrically connected to the conductive film S1g(j) and supplies the image signal.

Note that this embodiment can be combined with any of the other embodiments in this specification as appropriate.

### Embodiment 8

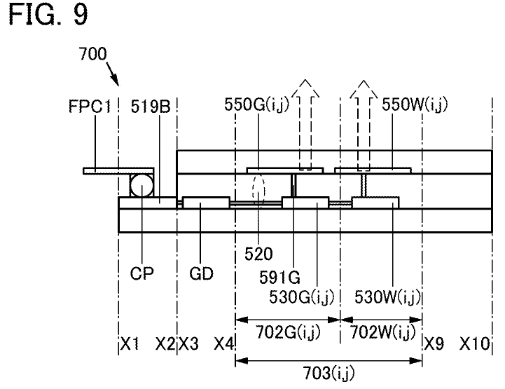

In this embodiment, structures of the functional panel of one embodiment of the present invention are described with reference to FIG. 9 to FIG. 11.

FIG. 9 is a diagram illustrating a structure of the functional panel of one embodiment of the present invention and is a cross-sectional view taken along cutting lines X1-X2, X3-X4, and X9-X10 in FIG. 6A and in the pixel set 703(i, j).

FIG. 10A is a diagram illustrating a structure of the functional panel of one embodiment of the present invention and is a cross-sectional view of the pixel 702G(i, j) illustrated in FIG. 6B. FIG. 10B is a cross-sectional view illustrating part of FIG. 10A.

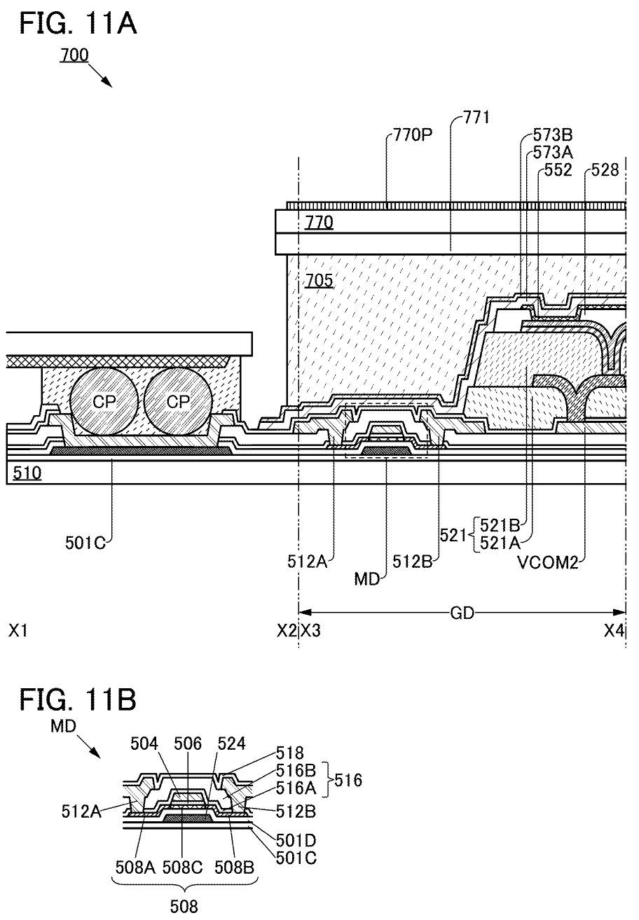

FIG. 11A is a diagram illustrating a structure of the functional panel of one embodiment of the present invention and is a cross-sectional view taken along the cutting line X1-X2 and the cutting line X3-X4 in FIG. 6A. FIG. 11B is a diagram illustrating part of FIG. 11A.

### Structure Example 1 of Functional Panel 700

The functional panel described in this embodiment includes a functional layer 520 (see FIG. 9).

### Structure Example 1 of Functional Layer 520

The functional layer 520 includes the pixel circuit 530G(i, j) and the pixel circuit 530W(i, j) (see FIG. 9). The functional layer 520 includes, for example, the transistor M21 used in the pixel circuit 530G(i, j) (see FIG. 8 and FIG. 10A or FIG. 12B).

The functional layer 520 includes an opening portion 591G(i, j). The pixel circuit 530G(i, j) is electrically connected to the light-emitting device 550G(i, j) through the opening portion 591G(i, j) (see FIG. 9 and FIG. 10A).

Thus, the pixel circuit 530G(i, j) can be formed in the pixel 702G(i, j). As a result, a novel functional panel that is highly convenient, useful, or reliable can be provided.

### Structure Example 2 of Functional Layer 520

The functional layer 520 includes the driver circuit GD (see FIG. 6A and FIG. 9). The functional layer 520 includes, for example, a transistor MD used in the driver circuit GD (see FIG. 9 and FIG. 11A).

Thus, the semiconductor film used in the driver circuit GD can be formed in the step of forming the semiconductor film used in the pixel circuit 530G(i, j), for example. The semiconductor film used in the driver circuit GD can be formed in a step different from the step of forming the semiconductor film used in the pixel circuit 530G(i, j). The manufacturing process of the functional panel can be simplified. As a result, a novel functional panel that is highly convenient, useful, or reliable can be provided.

### Structure Example of Transistor

A bottom-gate transistor, a top-gate transistor, or the like can be used in the functional layer 520. Specifically, a transistor can be used as a switch.

The transistor includes a semiconductor film 508, a conductive film 504, a conductive film 512A, and a conductive film 512B (see FIG. 10B).

The semiconductor film 508 includes a region 508A electrically connected to the conductive film 512A and a region 508B electrically connected to the conductive film 512B. The semiconductor film 508 includes a region 508C between the region 508A and the region 508B.

The conductive film 504 includes a region overlapping with the region 508C, and the conductive film 504 has a function of a gate electrode.

An insulating film 506 includes a region interposed between the semiconductor film 508 and the conductive film 504. The insulating film 506 has a function of a gate insulating film.

The conductive film 512A has one of a function of a source electrode and a function of a drain electrode, and the conductive film 512B has the other of the function of the source electrode and the function of the drain electrode.

A conductive film 524 can be used for the transistor. The semiconductor film 508 is interposed between a region of the conductive film 524 and the conductive film 504. The conductive film 524 has a function of a second gate electrode.

### Structure Example 1 of Semiconductor Film 508

A semiconductor containing a Group 14 element can be used for the semiconductor film 508, for example. Specifically, a semiconductor containing silicon can be used for the semiconductor film 508.

### Hydrogenated Amorphous Silicon

For example, hydrogenated amorphous silicon can be used for the semiconductor film 508. Microcrystalline silicon or the like can be used for the semiconductor film 508. Thus, a functional panel having less display unevenness than a functional panel using polysilicon for the semiconductor film 508, for example, can be provided. The size of the functional panel can be easily increased.

### Polysilicon

For example, polysilicon can be used for the semiconductor film 508. In this case, the field-effect mobility of the transistor can be higher than that of a transistor using hydrogenated amorphous silicon for the semiconductor film 508, for example. The driving capability can be higher than that of a transistor using hydrogenated amorphous silicon for the semiconductor film 508, for example. The aperture ratio of the pixel can be higher than that in the case of using a transistor that uses hydrogenated amorphous silicon for the semiconductor film 508, for example.

The reliability of the transistor can be higher than that of a transistor using hydrogenated amorphous silicon for the semiconductor film 508, for example.

The temperature required for manufacture of the transistor can be lower than that required for a transistor using single crystal silicon, for example.

The semiconductor film used in the transistor of the driver circuit can be formed in the same step as the semiconductor film used in the transistor of the pixel circuit. The driver circuit can be formed over the same substrate where the pixel circuit is formed. The number of components included in an electronic device can be reduced.

### Single Crystal Silicon

For example, single crystal silicon can be used for the semiconductor film 508. In this case, a functional panel can have higher resolution than a functional panel using hydrogenated amorphous silicon for the semiconductor film 508, for example. A functional panel having less display unevenness than a functional panel using polysilicon for the semiconductor film 508, for example, can be provided. Smart glasses or a head-mounted display can be provided, for example.

### Structure Example 2 of Semiconductor Film 508

For example, a metal oxide can be used for the semiconductor film 508. In this case, the pixel circuit can hold an image signal for a longer time than a pixel circuit utilizing a transistor using amorphous silicon for a semiconductor film. Specifically, a selection signal can be supplied at a frequency of lower than 30 Hz, preferably lower than 1 Hz, further preferably less than once per minute with the suppressed occurrence of flickers. Consequently, fatigue accumulation in a user of a data processing device can be reduced. Moreover, power consumption for driving can be reduced.

A transistor using an oxide semiconductor can be used, for example. Specifically, an oxide semiconductor containing indium, an oxide semiconductor containing indium, gallium, and zinc, an oxide semiconductor containing indium, gallium, zinc, and tin can be used for the semiconductor film.

A transistor having a lower leakage current in an off state than a transistor using amorphous silicon for a semiconductor film can be used, for example. Specifically, a transistor using an oxide semiconductor for a semiconductor film can be used as a switch or the like. In that case, a potential of a floating node can be held for a longer time than in a circuit in which a transistor using amorphous silicon is used as a switch.

A 25-nm-thick film containing indium, gallium, and zinc can be used as the semiconductor film 508, for example.

A conductive film in which a 10-nm-thick film containing tantalum and nitrogen and a 300-nm-thick film containing copper are stacked can be used as the conductive film 504, for example. Note that the film containing tantalum and nitrogen is interposed between a region of the film containing copper and the insulating film 506.

A stacked film in which a 400-nm-thick film containing silicon and nitrogen and a 200-nm-thick film containing silicon, oxygen, and nitrogen are stacked can be used as the insulating film 506, for example. Note that the film containing silicon, oxygen, and nitrogen is interposed between a region of the film containing silicon and nitrogen and the semiconductor film 508.

A conductive film in which a 50-nm-thick film containing tungsten, a 400-nm-thick film containing aluminum, and a 100-nm-thick film containing titanium are stacked in this order can be used as the conductive film 512A or the conductive film 512B, for example. Note that the film containing tungsten includes a region in contact with the semiconductor film 508.

A manufacturing line for a bottom-gate transistor using amorphous silicon for a semiconductor can be easily remodeled into a manufacturing line for a bottom-gate transistor using an oxide semiconductor for a semiconductor, for example. Furthermore, a manufacturing line for a top-gate transistor using polysilicon for a semiconductor can be easily remodeled into a manufacturing line for a top-gate transistor using an oxide semiconductor for a semiconductor, for example. In either remodeling, an existing manufacturing line can be effectively utilized.

Accordingly, flickering of a display can be inhibited. Power consumption can be reduced. A moving image with quick movements can be smoothly displayed. A photograph and the like can be displayed with a wide range of grayscale. As a result, a novel functional panel that is highly convenient, useful, or reliable can be provided.

### Structure Example 3 of Semiconductor Film 508

For example, a compound semiconductor can be used for the semiconductor of the transistor. Specifically, a semiconductor containing gallium arsenide can be used.

For example, an organic semiconductor can be used for the semiconductor of the transistor. Specifically, an organic semiconductor containing any of polyacenes or graphene can be used for the semiconductor film.

### Structure Example of Capacitor

A capacitor includes one conductive film, a different conductive film, and an insulating film. The insulating film includes a region interposed between the one conductive film and the different conductive film.

For example, a conductive film used as the source electrode or the drain electrode of the transistor, a conductive film used as the gate electrode, and an insulating film used as the gate insulating film can be used for the capacitor.

### Structure Example 3 of Functional Layer 520

The functional layer 520 includes an insulating film 521, an insulating film 518, an insulating film 516, the insulating film 506, an insulating film 501C, and the like (see FIG. 10A and FIG. 10B).

The insulating film 521 includes a region interposed between the pixel circuit 530G(i, j) and the light-emitting device 550G(i, j).

The insulating film 518 includes a region interposed between the insulating film 521 and the insulating film 501C.

The insulating film 516 includes a region interposed between the insulating film 518 and the insulating film 501C.

The insulating film 506 includes a region interposed between the insulating film 516 and the insulating film 501C.

### Insulating Film 521

An insulating inorganic material, an insulating organic material, or an insulating composite material containing an inorganic material and an organic material can be used for the insulating film 521.

Specifically, an inorganic oxide film, an inorganic nitride film, an inorganic oxynitride film, or the like, or a stacked-layer material in which a plurality of films selected from these films are stacked can be used as the insulating film 521. For example, a film in which an insulating film 521A and an insulating film 521B are stacked can be used as the insulating film 521.

For example, a film including a silicon oxide film, a silicon nitride film, a silicon oxynitride film, an aluminum oxide film, or the like, or a film including a stacked-layer material in which a plurality of films selected from these films are stacked can be used as the insulating film 521. Note that the silicon nitride film is a dense film and has an excellent function of inhibiting diffusion of impurities.

For example, for the insulating film 521, polyester, polyolefin, polyamide, polyimide, polycarbonate, polysiloxane, an acrylic resin, or the like, or a stacked-layer material, a composite material, or the like of a plurality of resins selected from these resins can be used. Note that polyimide is excellent in thermal stability, insulating property, toughness, low dielectric constant, low coefficient of thermal expansion, chemical resistance, and other properties compared with other organic materials. Accordingly, in particular, polyimide can be suitably used for the insulating film 521 or the like.

The insulating film 521 may be formed using a photosensitive material. Specifically, a film formed using photosensitive polyimide, a photosensitive acrylic resin, or the like can be used as the insulating film 521.

Thus, the insulating film 521 can eliminate a level difference due to various components overlapping with the insulating film 521, for example.

### Insulating Film 518

The material that can be used for the insulating film 521, for example, can be used for the insulating film 518.

For example, a material having a function of inhibiting diffusion of oxygen, hydrogen, water, an alkali metal, an alkaline earth metal, and the like can be used for the insulating film 518. Specifically, a nitride insulating film can be used as the insulating film 518. For example, silicon nitride, silicon nitride oxide, aluminum nitride, aluminum nitride oxide, or the like can be used for the insulating film 518. Thus, diffusion of impurities into the semiconductor film of the transistor can be inhibited.

### Insulating Film 516

The material that can be used for the insulating film 521, for example, can be used for the insulating film 516. For example, a film in which an insulating film 516A and an insulating film 516B are stacked can be used as the insulating film 516.

Specifically, a film formed by a fabrication method different from that of the insulating film 518 can be used as the insulating film 516.

### Insulating Film 506

The material that can be used for the insulating film 521, for example, can be used for the insulating film 506.

Specifically, a film including a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film can be used as the insulating film 506.

### Insulating Film 501D

An insulating film 501D includes a region interposed between the insulating film 501C and the insulating film 516.

The material that can be used for the insulating film 506, for example, can be used for the insulating film 501D.

### Insulating Film 501C

The material that can be used for the insulating film 521, for example, can be used for the insulating film 501C. Specifically, a material containing silicon and oxygen can be used for the insulating film 501C. Thus, diffusion of impurities into the pixel circuit, the light-emitting device 550G(i, j) or the like can be inhibited.

### Structure Example 4 of Functional Layer 520

The functional layer 520 includes a conductive film, a wiring, and a terminal. A material having conductivity can be used for the wiring, an electrode, the terminal, the conductive film, and the like.

### Wiring and the Like

For example, an inorganic conductive material, an organic conductive material, a metal, a conductive ceramic, or the like can be used for the wiring and the like.

Specifically, a metal element selected from aluminum, gold, platinum, silver, copper, chromium, tantalum, titanium, molybdenum, tungsten, nickel, iron, cobalt, palladium, and manganese, or the like can be used for the wiring and the like. Alternatively, an alloy containing the above-described metal element, or the like can be used for the wiring and the like. In particular, an alloy of copper and manganese is suitable for microfabrication using a wet etching method.

Specifically, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure of a titanium film, an aluminum film stacked over the titanium film, and a titanium film further formed thereover, or the like can be used for the wiring and the like.

Specifically, a conductive oxide such as indium oxide, indium tin oxide, indium zinc oxide, zinc oxide, or zinc oxide to which gallium is added can be used for the wiring and the like.

Specifically, a film containing graphene or graphite can be used for the wiring and the like.

For example, a film containing graphene oxide is formed and the film containing graphene oxide is reduced, so that a film containing graphene can be formed. As a reducing method, a method with application of heat, a method using a reducing agent, or the like can be given.

For example, a film including a metal nanowire can be used for the wiring and the like. Specifically, a nanowire containing silver can be used.

Specifically, a conductive polymer can be used for the wiring and the like.

Note that a terminal 519B can be electrically connected to a flexible printed circuit FPC1 using a conductive material, for example (see FIG. 9). Specifically, the terminal 519B can be electrically connected to the flexible printed circuit FPC1 using a conductive material CP.

### Structure Example 2 of Functional Panel 700

The functional panel 700 includes a base material 510, the base material 770, and a sealant 705 (see FIG. 10A). In addition, the functional panel 700 includes a structure body KB.

### Base Material 510 and Base Material 770

A material having a light-transmitting property can be used for the base material 510 or the base material 770.

For example, a flexible material can be used for the base material 510 or the base material 770. Thus, a flexible functional panel can be provided.

For example, a material with a thickness less than or equal to 0.7 mm and greater than or equal to 0.1 mm can be used. Specifically, a material polished to a thickness of approximately 0.1 mm can be used. Thus, the weight can be reduced.

A glass substrate of the 6th generation (1500 mm × 1850 mm), the 7th generation (1870 mm × 2200 mm), the 8th generation (2200 mm × 2400 mm), the 9th generation (2400 mm × 2800 mm), the 10th generation (2950 mm × 3400 mm), or the like can be used as the base material 510 or the base material 770. Thus, a large-sized display device can be fabricated.

For the base material 510 or the base material 770, an organic material, an inorganic material, a composite material of an organic material and an inorganic material, or the like can be used.

For example, an inorganic material such as glass, ceramic, or a metal can be used. Specifically, non-alkali glass, soda-lime glass, potash glass, crystal glass, aluminosilicate glass, tempered glass, chemically tempered glass, quartz, sapphire, or the like can be used for the base material 510 or the base material 770. Aluminosilicate glass, tempered glass, chemically tempered glass, sapphire, or the like can be suitably used for the base material 510 or the base material 770 that is provided on the side close to a user of the functional panel. Thus, the functional panel can be prevented from being broken or damaged by the use thereof.

Specifically, an inorganic oxide film, an inorganic nitride film, an inorganic oxynitride film, or the like can be used. For example, a silicon oxide film, a silicon nitride film, a silicon oxynitride film, an aluminum oxide film, or the like can be used. Stainless steel, aluminum, or the like can be used for the base material 510 or the base material 770.

For example, a single crystal semiconductor substrate or a polycrystalline semiconductor substrate of silicon or silicon carbide, a compound semiconductor substrate of silicon germanium or the like, an SOI substrate, or the like can be used as the base material 510 or the base material 770. Thus, a semiconductor element can be formed on the base material 510 or the base material 770.

For example, an organic material such as a resin, a resin film, or plastic can be used for the base material 510 or the base material 770. Specifically, a material containing polyester, polyolefin, polyamide (e.g., nylon or aramid), polyimide, polycarbonate, polyurethane, an acrylic resin, an epoxy resin, or a resin having a siloxane bond, such as silicone, can be used for the base material 510 or the base material 770. For example, a resin film, a resin plate, a stacked-layer material, or the like containing any of these materials can be used. Thus, the weight can be reduced. The frequency of occurrence of breakage or the like due to dropping can be reduced, for example.

Specifically, polyethylene terephthalate (PET), polyethylene naphthalate (PEN), polyethersulfone (PES), a cycloolefin polymer (COP), a cycloolefin copolymer (COC), or the like can be used for the base material 510 or the base material 770.

For example, a composite material formed by attaching a metal plate, a thin glass plate, or a film of an inorganic material or the like and a resin film or the like to each other can be used for the base material 510 or the base material 770. For example, a composite material formed by dispersing a fibrous or particulate metal, glass, an inorganic material, or the like into a resin can be used for the base material 510 or the base material 770. For example, a composite material formed by dispersing a fibrous or particulate resin, an organic material, or the like into an inorganic material can be used for the base material 510 or the base material 770.

Furthermore, a single-layer material or a material in which a plurality of layers are stacked can be used for the base material 510 or the base material 770. For example, a material in which insulating films and the like are stacked can be used. Specifically, a material in which one or a plurality of films selected from a silicon oxide layer, a silicon nitride layer, a silicon oxynitride layer, and the like are stacked can be used. Thus, diffusion of impurities contained in the base materials can be prevented, for example. Diffusion of impurities contained in glass or a resin can be prevented. Diffusion of impurities that pass through a resin can be prevented.

Furthermore, paper, wood, or the like can be used for the base material 510 or the base material 770.

For example, a material having heat resistance high enough to withstand heat treatment in the fabricating process can be used for the base material 510 or the base material 770. Specifically, a material having heat resistance to heat applied in the formation process of directly forming the transistor, the capacitor, or the like can be used for the base material 510 or the base material 770.

For example, it is possible to employ a method in which an insulating film, a transistor, a capacitor, or the like is formed on a process substrate having heat resistance to heat applied in the fabricating process, and the formed insulating film, transistor, capacitor, or the like is transferred to the base material 510 or the base material 770. Accordingly, an insulating film, a transistor, a capacitor, or the like can be formed on a flexible substrate, for example.

### Sealant 705

The sealant 705 includes a region interposed between the functional layer 520 and the base material 770 and has a function of bonding the functional layer 520 and the base material 770 together (see FIG. 10A).

An inorganic material, an organic material, a composite material of an inorganic material and an organic material, or the like can be used for the sealant 705.

For example, an organic material such as a thermally fusible resin or a curable resin can be used for the sealant 705.

For example, an organic material such as a reactive curable adhesive, a photocurable adhesive, a thermosetting adhesive, and/or an anaerobic adhesive can be used for the sealant 705.

Specifically, an adhesive containing an epoxy resin, an acrylic resin, a silicone resin, a phenol resin, a polyimide resin, an imide resin, a PVC (polyvinyl chloride) resin, a PVB (polyvinyl butyral) resin, an EVA (ethylene vinyl acetate) resin, or the like can be used for the sealant 705.

### Structure Body KB

The structure body KB includes a region interposed between the functional layer 520 and the base material 770. The structure body KB has a function of providing a predetermined space between the functional layer 520 and the base material 770.

Note that this embodiment can be combined with any of the other embodiments in this specification as appropriate.

### Embodiment 9

In this embodiment, a structure of a functional panel of one embodiment of the present invention will be described with reference to FIG. 10.

### Structure Example 1 of Functional Panel 700

The functional panel 700 includes the light-emitting device 550G(i, j) (see FIG. 10).

### Structure Example 1 of Light-Emitting Device 550G(i, j)

The light-emitting device 550G(i, j) includes the electrode 551G(i, j), the electrode 552, and a layer 553G(j) including a light-emitting material. The layer 553G(j) including a light-emitting material includes a region interposed between the electrode 551G(i, j) and the electrode 552.

### Structure Example 1 of Layer 553G(j) Including Light-Emitting Material

A stacked-layer material can be used for the layer 553G(j) including a light-emitting material, for example.

For example, a material emitting blue light, a material emitting green light, or a material emitting red light can be used for the layer 553G(j) including a light-emitting material. A material that emits infrared light or a material that emits ultraviolet light can be used for the layer 553G(j) including a light-emitting material.

A stacked-layer material in which a layer including a fluorescent substance and a layer including a phosphorescent substance are stacked can be used for the layer 553G(j) including a light-emitting material.

Specifically, the structure described in Embodiment 1 to Embodiment 6 can be used for the light-emitting device 550G(i, j).

### Structure Example 2 of Layer 553G(j) Including Light-Emitting Material

A stacked-layer material stacked to emit white light can be used for the layer 553G(j) including a light-emitting material, for example.

Specifically, a plurality of materials emitting light with different hues can be used for the layer 553G(j) including a light-emitting material. For example, a stacked-layer material in which a layer including a material emitting blue light and a layer including a material emitting yellow light are stacked can be used for the layer 553G(j) including a light-emitting material. A stacked-layer material in which a layer including a material emitting blue light, a layer including a material emitting red light, and a layer including a material emitting green light are stacked can be used for the layer 553G(j) including a light-emitting material.

Note that the light-emitting device 550G(i, j) can be used with a coloring film CF overlapping, for example. Thus, light of a predetermined hue can be extracted from white light, for example.

### Structure Example 3 of Layer 553G(j) Including Light-Emitting Material

A stacked-layer material stacked to emit blue light or ultraviolet rays can be used for the layer 553G(j) including a light-emitting material, for example.

Note that a color conversion layer can be used to overlap with the light-emitting device 550G(i, j). Thus, light of a predetermined hue can be extracted from blue light or ultraviolet rays, for example.

### Structure Example 4 of Layer 553G(j) Including Light-Emitting Material

The layer 553G(j) including a light-emitting material includes a light-emitting unit. The light-emitting unit includes one region where electrons injected from one side are recombined with holes injected from the other side. The light-emitting unit contains a light-emitting material, and the light-emitting material releases energy generated by recombination of electrons and holes as light.

A plurality of light-emitting units and an intermediate layer can be used for the layer 553G(j) including a light-emitting material, for example. An intermediate layer includes a region interposed between two light-emitting units. The intermediate layer includes a charge-generation region, and the intermediate layer has functions of supplying holes to the light-emitting unit placed on the cathode side and supplying electrons to the light-emitting unit placed on the anode side. Furthermore, a structure including a plurality of light-emitting units and an intermediate layer is referred to as a tandem light-emitting element in some cases.

Accordingly, the current efficiency of light emission can be increased. The density of current flowing through the light-emitting element at the same luminance can be reduced. The reliability of the light-emitting element can be increased.

For example, a light-emitting unit containing a material emitting light with one hue and a light-emitting unit containing a material emitting light with a different hue can be stacked and used for the layer 553G(j) including a light-emitting material. A light-emitting unit containing a material emitting light with one hue and a light-emitting unit containing a material emitting light with the same hue can be stacked and used for the layer 553G(j) including a light-emitting material. Specifically, two light-emitting units each containing a material emitting blue light can be stacked and used.

For the layer 553G(j) including a light-emitting material, a high molecular compound (e.g., an oligomer, a dendrimer, or a polymer), a middle molecular compound (a compound between a low molecular compound and a high molecular compound with a molecular weight greater than or equal to 400 and less than or equal to 4000), or the like can be used.

### Electrode 551G(i, j) and Electrode 552

The material that can be used for the wiring or the like, for example, can be used for the electrode 551G(i, j) or the electrode 552. Specifically, a material having a visible-light-transmitting property can be used for the electrode 551G(i, j) or the electrode 552.

For example, a conductive oxide, a conductive oxide containing indium, indium oxide, indium tin oxide, indium zinc oxide, zinc oxide, zinc oxide to which gallium is added, or the like can be used. A metal film thin enough to transmit light can be used. A material having a visible-light-transmitting property can be used.

For example, a metal film that transmits part of light and reflects another part of the light can be used for the electrode 551G(i, j) or the electrode 552. The distance between the electrode 551G(i, j) and the electrode 552 is adjusted using the layer 553G(j) including a light-emitting material, for example.

Thus, a microcavity structure can be provided in the light-emitting device 550G(i, j). Light of a predetermined wavelength can be extracted more efficiently than other light. Light with a narrow half width of a spectrum can be extracted. Light of a bright color can be extracted.

A film that efficiently reflects light, for example, can be used for the electrode 551G(i, j) or the electrode 552. Specifically, a material containing silver, palladium, and the like or a material containing silver, copper, and the like can be used for the metal film.

The electrode 551G(i, j) is electrically connected to the pixel circuit 530G(i, j) through the opening portion 591G(i, j) (see FIG. 10A). For example, the electrode 551G(i, j) overlaps with the opening portion formed in the insulating film 528, and the insulating film 528 is at the periphery of the electrode 551G(i, j).

Thus, a short circuit between the electrode 551G(i, j) and the electrode 552 can be prevented.

### Structure Example 2 of Functional Panel 700

The functional panel 700 includes the insulating film 528 and an insulating film 573 (see FIG. 10A).

### Structure Example 1 of Insulating Film 528

The insulating film 528 includes a region interposed between the functional layer 520 and the base material 770, and the insulating film 528 includes an opening portion in a region overlapping with the light-emitting device 550G(i, j) (see FIG. 10A).

The material that can be used for the insulating film 521, for example, can be used for the insulating film 528. Specifically, a silicon oxide film, a film containing an acrylic resin, a film containing polyimide, or the like can be used as the insulating film 528.

### Insulating Film 573

The light-emitting device 550G(i, j) is interposed between a region of the insulating film 573 and the functional layer 520 (see FIG. 10A).

For example, a single film or a stacked film in which a plurality of films are stacked can be used as the insulating film 573. Specifically, a stacked film, in which an insulating film 573A which can be formed by a method that hardly damages the light-emitting device 550G(i, j) and a dense insulating film 573B with a few defects are stacked, can be used as the insulating film 573. For example, an organic material can be used for the insulating film 573A. An inorganic material can be used for the insulating film 573B.

Thus, diffusion of impurities into the light-emitting device 550G(i, j) can be inhibited. The reliability of the light-emitting device 550G(i, j) can be increased.

### Structure Example 3 of Functional Panel 700

The functional panel 700 includes a functional layer 720 (see FIG. 10A).

### Functional Layer 720

The functional layer 720 includes a light-blocking film BM, a coloring film CF(G), and an insulating film 771. A color conversion layer can also be used.

### Light-Blocking Film BM

The light-blocking film BM includes an opening portion in a region overlapping with the pixel 702G(i, j). A material of a dark color can be used for the light-blocking film BM, for example. Thus, the display contrast can be increased.

### Coloring Film CF(G)

The coloring film CF(G) includes a region interposed between the base material 770 and the light-emitting device 550G(i, j). A material that selectively transmits light of a predetermined color, for example, can be used for the coloring film CF(G). Specifically, a material that transmits red light, green light, or blue light can be used for the coloring film CF(G).

### Structure Example of Insulating Film 771

The insulating film 771 includes a region interposed between the base material 770 and the light-emitting device 550G(i, j).

The insulating film 771 includes a region where the light-blocking film BM and the coloring film CF(G) are interposed between the insulating film 771 and the base material 770. Thus, unevenness due to the thicknesses of the light-blocking film BM and the coloring film CF(G) can be reduced.

### Color Conversion Layer

The color conversion layer includes a region interposed between the base material 770 and the light-emitting device 550G(i, j). The color conversion layer includes a region interposed between the coloring film CF(G) and the light-emitting device 550G(i, j).

For example, a material that emits light with a wavelength longer than a wavelength of incident light can be used for the color conversion layer. For example, a material that absorbs blue light or ultraviolet rays, converts it into green light, and emits the green light, a material that absorbs blue light or ultraviolet rays, converts it into red light, and emits the red light, or a material that absorbs ultraviolet rays, converts it into blue light, and emits the blue light can be used for the color conversion layer.

Specifically, a quantum dot with a diameter of several nanometers can be used for the color conversion layer. Thus, light having a spectrum with a narrow half width can be emitted. Light with high saturation can be emitted.

### Structure Example 4 of Functional Panel 700

The functional panel 700 includes a light-blocking film KBM (see FIG. 10A).

### Light-Blocking Film KBM

The light-blocking film KBM includes an opening portion in a region overlapping with the pixel 702G(i, j) and an opening portion in a region overlapping with another pixel adjacent to the pixel 702G(i, j). Moreover, the light-blocking film KBM includes a region interposed between the functional layer 520 and the base material 770, and has a function of providing a predetermined space between the functional layer 520 and the base material 770. A material of a dark color can be used for the light-blocking film KBM, for example. Thus, stray light that would enter an adjacent pixel from the pixel 702G(i, j) can be reduced.

### Structure Example 5 of Functional Panel 700

The functional panel 700 includes a functional film 770P (see FIG. 10A).

### Functional Film 770P and the Like

The functional film 770P includes a region overlapping with the light-emitting device 550G(i, j). The functional film 770P includes a region where the base material 770 is interposed between the light-emitting device 550G(i, j) and the functional film 770P.

An anti-reflection film, a polarizing film, a retardation film, a light diffusion film, a condensing film, or the like can be used as the functional film 770P, for example.

For example, an anti-reflection film with a thickness less than or equal to 1 µm can be used as the functional film 770P. Specifically, a stacked film in which three or more layers, preferably five or more layers, and further preferably 15 or more layers of dielectrics are stacked can be used as the functional film 770P. This allows the reflectance to be as low as 0.5 % or less, preferably 0.08% or less.

For example, a circularly polarizing film can be used as the functional film 770P.

Furthermore, an antistatic film inhibiting the attachment of a dust, a water repellent film inhibiting the attachment of a stain, an oil repellent film inhibiting the attachment of a stain, a non-glare film (anti-glare film), a hard coat film inhibiting generation of a scratch in use, a self-healing film that self-heals from generated scratches, or the like can be used as the functional film 770P.

### Structure Example 6 of Functional Panel 700

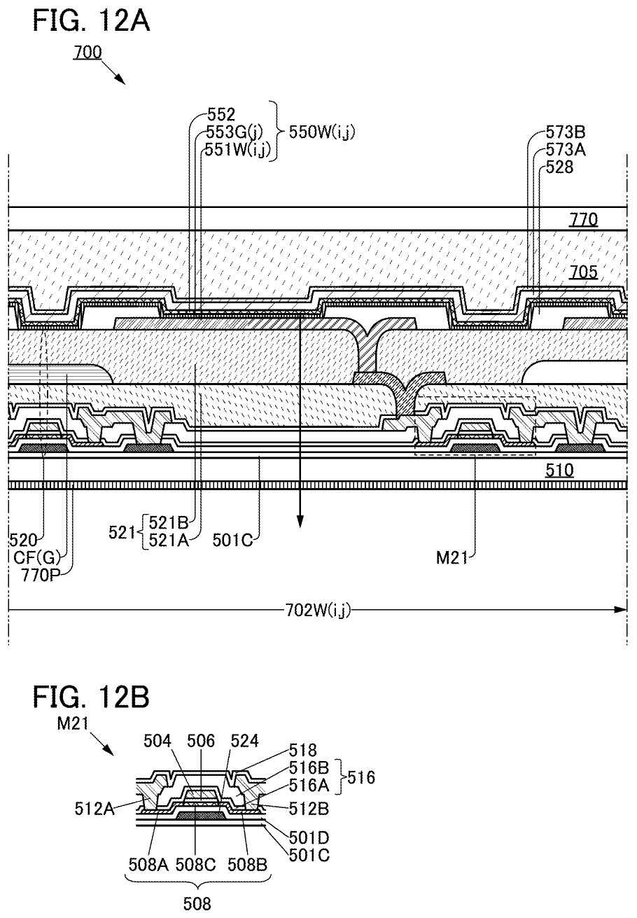

The functional panel 700 includes the insulating film 528 and the coloring film CF(G) (see FIG. 12A).

### Structure Example 2 of Insulating Film 528

The insulating film 528 includes a region interposed between the functional layer 520 and the base material 770, and the insulating film 528 includes an opening portion in a region overlapping with the light-emitting device 550W(i, j) (see FIG. 12A). The insulating film 528 includes an opening portion between the light-emitting device 550W(i, j) and another light-emitting device adjacent to the light-emitting device 550W(i, j). Thus, propagation of light emitted from the light-emitting device 550W(i, j) inside the insulating film 528 can be inhibited. Alternatively, stray light that would enter an adjacent pixel from the pixel 702W(i, j) can be reduced.

### Structure Example of Light-Emitting Device 550W(i,j)

The light-emitting device 550W(i, j) includes the electrode 551W(i, j), the electrode 552, and the layer 553G(j) (see FIG. 7C and FIG. 12A).

The electrode 551W(i, j) has the transmittance T1. The electrode 552 includes a region overlapping with the electrode 551(i, j), and the electrode 552 has the transmittance T2. The transmittance T1 is higher than the transmittance T2. Note that the electrode 552 has a higher reflectance than the electrode 551W(i, j).

### Structure Example of Layer 553G(j)

The layer 553G(j) includes a region interposed between the electrode 551(i, j) and the electrode 552. The layer 553G(j) includes the region 553A, the region 553B, and the region 553C.

The layer 553G(j) is different from the EL layer 553 described with reference to FIG. 4B in that a unit 103(13), a layer 105(13), and a layer 106(13) are provided between the layer 106 and the unit 103(12). For example, the structure that can be used for the unit 103 can be used for the unit 103(13), the structure that can be used for the layer 105 can be used for the layer 105(13), and the structure that can be used for the layer 106 can be used for the layer 106(13).

The region 553A includes a portion interposed between the region 553B and the region 553C. Note that the region 553A includes the layer 111, the layer 111(12), the layer 111(13), and the layer 111(14) each including a light-emitting material. The layer 111 has a function of emitting light EL1, the layer 111(12) has a function of emitting light EL1(2), the layer 111(13) has a function of emitting light EL1(3), and the layer 111(14) has a function of emitting light EL1(4).

For example, a light-emitting material that emits blue light can be used for the layer 111 and the layer 111(12). For example, a light-emitting material that emits yellow light can be used for the layer 111(13). For example, a light-emitting material that emits red light can be used for the layer 111(14).

The region 553B includes a region interposed between the electrode 551W(i, j) and the region 553A, and the region 553B has the refractive index n1.

The region 553C includes a region interposed between the region 553A and the electrode 552, and the region 553C has the refractive index n2.

Note that this embodiment can be combined with any of the other embodiments in this specification as appropriate.

### Embodiment 10

In this embodiment, a light-emitting apparatus including the light-emitting device described in any one of Embodiment 1 to Embodiment 6 is described.

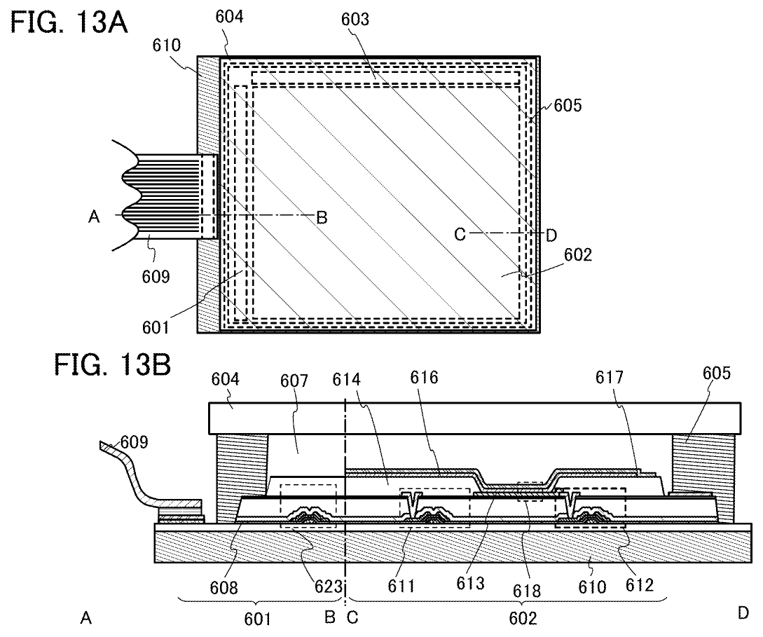

In this embodiment, a light-emitting apparatus fabricated using the light-emitting device described in any one of Embodiment 1 to Embodiment 6 is described with reference to FIG. 13. Note that FIG. 13A is a top view illustrating the light-emitting apparatus, and FIG. 13B is a cross-sectional view taken along A-B and C-D in FIG. 13A. This light-emitting apparatus includes a driver circuit portion (source line driver circuit 601), a pixel portion 602, and a driver circuit portion (gate line driver circuit 603), which are to control light emission of the light-emitting device and are illustrated with dotted lines. Furthermore, 604 denotes a sealing substrate, 605 denotes a sealant, and the inside surrounded by the sealant 605 is a space 607.

Note that a lead wiring 608 is a wiring for transmitting signals to be input to the source line driver circuit 601 and the gate line driver circuit 603 and receiving a video signal, a clock signal, a start signal, a reset signal, and the like from an FPC (flexible printed circuit) 609 serving as an external input terminal. Although only the FPC is illustrated here, a printed wiring board (PWB) may be attached to this FPC. The light-emitting apparatus in this specification includes not only the light-emitting apparatus itself but also the apparatus provided with the FPC or the PWB.

Next, a cross-sectional structure is described with reference to FIG. 13B. The driver circuit portion and the pixel portion are formed over an element substrate 610. Here, the source line driver circuit 601, which is the driver circuit portion, and one pixel of the pixel portion 602 are illustrated.

The element substrate 610 may be fabricated using a substrate containing glass, quartz, an organic resin, a metal, an alloy, a semiconductor, or the like, or a plastic substrate formed of FRP (Fiber Reinforced Plastic), PVF (polyvinyl fluoride), polyester, an acrylic resin, or the like.

There is no particular limitation on the structure of transistors used in pixels or driver circuits. For example, inverted staggered transistors or staggered transistors may be used. Furthermore, top-gate transistors or bottom-gate transistors may be used. There is no particular limitation on a semiconductor material used for the transistors, and for example, silicon, germanium, silicon carbide, gallium nitride, or the like can be used. Alternatively, an oxide semiconductor containing at least one of indium, gallium, and zinc, such as In-Ga-Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single-crystal semiconductor, and a semiconductor partly including crystal regions) may be used. A semiconductor having crystallinity is preferably used, in which case deterioration of the transistor characteristics can be suppressed.

Here, an oxide semiconductor is preferably used for semiconductor devices such as the transistors provided in the pixels or the driver circuits and transistors used for touch sensors described later, and the like. In particular, an oxide semiconductor having a wider band gap than silicon is preferably used. The use of an oxide semiconductor having a wider band gap than silicon can reduce the off-state current of the transistors.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such a material for the semiconductor layer makes it possible to achieve a highly reliable transistor in which a change in the electrical characteristics is reduced.

Charge accumulated in a capacitor through a transistor including the above-described semiconductor layer can be retained for a long time because of the low off-state current of the transistor. The use of such a transistor in pixels allows a driver circuit to stop while the gray level of an image displayed on each display region is maintained. As a result, an electronic apparatus with significantly reduced power consumption can be achieved.

For stable characteristics of the transistor or the like, a base film is preferably provided. The base film can be formed to be a single layer or a stacked layer using an inorganic insulating film such as a silicon oxide film, a silicon nitride film, a silicon oxynitride film, or a silicon nitride oxide film. The base film can be formed by a sputtering method, a CVD (Chemical Vapor Deposition) method (e.g., a plasma CVD method, a thermal CVD method, or an MOCVD (Metal Organic CVD) method), an ALD (Atomic Layer Deposition) method, a coating method, a printing method, or the like. Note that the base film is not necessarily provided when not needed.

Note that an FET 623 is illustrated as a transistor formed in the source line driver circuit 601. The driver circuit can be formed using various circuits such as a CMOS circuit, a PMOS circuit, and an NMOS circuit. Although a driver-integrated type in which the driver circuit is formed over the substrate is described in this embodiment, the driver circuit is not necessarily formed over the substrate and can be formed outside.

The pixel portion 602 is formed with a plurality of pixels including a switching FET 611, a current control FET 612, and a first electrode 613 electrically connected to a drain of the current control FET 612; however, without being limited thereto, a pixel portion in which three or more FETs and a capacitor are combined may be employed.

Note that an insulator 614 is formed to cover an end portion of the first electrode 613. The insulator 614 can be formed using a positive photosensitive acrylic resin film here.

In order to improve the coverage with an EL layer or the like to be formed later, the insulator 614 is formed so as to have a curved surface with curvature at its upper end portion or lower end portion. For example, in the case where a positive photosensitive acrylic resin is used as a material for the insulator 614, only the upper end portion of the insulator 614 preferably has a curved surface with a curvature radius (greater than or equal to 0.2 µm and less than or equal to 3 µm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material with a high work function is desirably used. For example, a single-layer film of an ITO film, an indium tin oxide film containing silicon, an indium oxide film containing zinc oxide at 2 wt% or higher and 20 wt% or lower, a titanium nitride film, a chromium film, a tungsten film, a Zn film, a Pt film, or the like, a stacked layer of a titanium nitride film and a film containing aluminum as its main component, a three-layer structure of a titanium nitride film, a film containing aluminum as its main component, and a titanium nitride film, or the like can be used. Note that the stacked-layer structure achieves low wiring resistance, a favorable ohmic contact, and a function as an anode.

The EL layer 616 is formed by any of a variety of methods such as an evaporation method using an evaporation mask, an inkjet method, and a spin coating method. The EL layer 616 has the structure described in any one of Embodiment 1 to Embodiment 6. Alternatively, a material included in the EL layer 616 may be a low molecular compound or a high molecular compound (including an oligomer or a dendrimer).

As a material used for the second electrode 617, which is formed over the EL layer 616 and functions as a cathode, a material with a low work function (e.g., Al, Mg, Li, Ca, or an alloy or a compound thereof (e.g., MgAg, MgIn, or AlLi)) is preferably used. Note that in the case where light generated in the EL layer 616 passes through the second electrode 617, it is preferable to use, for the second electrode 617, a stacked layer of a thin metal film and a transparent conductive film (e.g., ITO, indium oxide containing zinc oxide at 2 wt% or higher and 20 wt% or lower, indium tin oxide containing silicon, or zinc oxide (ZnO)).

Note that a light-emitting device 618 is formed with the first electrode 613, the EL layer 616, and the second electrode 617. The light-emitting device is the light-emitting device described in any one of Embodiment 1 to Embodiment 6. A plurality of light-emitting devices are formed in the pixel portion, and the light-emitting apparatus of this embodiment may include both the light-emitting device described in any one of Embodiment 1 to Embodiment 6 and a light-emitting device having a different structure.

The sealing substrate 604 and the element substrate 610 are attached to each other using the sealant 605, so that a structure is employed in which the light-emitting device 618 is provided in the space 607 surrounded by the element substrate 610, the sealing substrate 604, and the sealant 605. The space 607 is filled with a filler; it is filled with an inert gas (e.g., nitrogen or argon) in some cases, and filled with the sealant in some cases. The structure of the sealing substrate in which a recessed portion is formed and a desiccant is provided is preferable because deterioration due to the influence of moisture can be inhibited.

Note that an epoxy resin or glass frit is preferably used for the sealant 605. Furthermore, these materials are preferably materials that transmit moisture and oxygen as little as possible. As the material used for the sealing substrate 604, in addition to a glass substrate and a quartz substrate, a plastic substrate formed of FRP (Fiber Reinforced Plastics), PVF (polyvinyl fluoride), polyester, an acrylic resin, or the like can be used.

Although not illustrated in FIG. 13, a protective film may be provided over the second electrode. The protective film may be formed using an organic resin film or an inorganic insulating film. The protective film may be formed so as to cover an exposed portion of the sealant 605. The protective film may be provided so as to cover surfaces and side surfaces of the pair of substrates and exposed side surfaces of a sealing layer, an insulating layer, and the like.

For the protective film, a material that is less likely to transmit an impurity such as water can be used. Thus, diffusion of an impurity such as water from the outside into the inside can be effectively inhibited.

As a material included in the protective film, an oxide, a nitride, a fluoride, a sulfide, a ternary compound, a metal, a polymer, or the like can be used; for example, it is possible to use a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like; a material containing aluminum nitride, hafnium nitride, silicon nitride, tantalum nitride, titanium nitride, niobium nitride, molybdenum nitride, zirconium nitride, gallium nitride, or the like; or a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method that enables favorable step coverage. One such method is an atomic layer deposition (ALD) method. A material that can be formed by an ALD method is preferably used for the protective film. With the use of an ALD method, a dense protective film with reduced defects such as cracks or pinholes or with a uniform thickness can be formed. Furthermore, damage caused to a process member in forming the protective film can be reduced.

By an ALD method, a uniform protective film with few defects can be formed even on a surface with a complex uneven shape or upper, side, and lower surfaces of a touch panel.

As described above, the light-emitting apparatus fabricated using the light-emitting device described in any one of Embodiment 1 to Embodiment 6 can be obtained.

For the light-emitting apparatus in this embodiment, the light-emitting device described in any one of Embodiment 1 to Embodiment 6 is used and thus a light-emitting apparatus having favorable characteristics can be obtained. Specifically, since the light-emitting device described in any one of Embodiment 1 to Embodiment 6 has favorable emission efficiency, the light-emitting apparatus with low power consumption can be obtained.

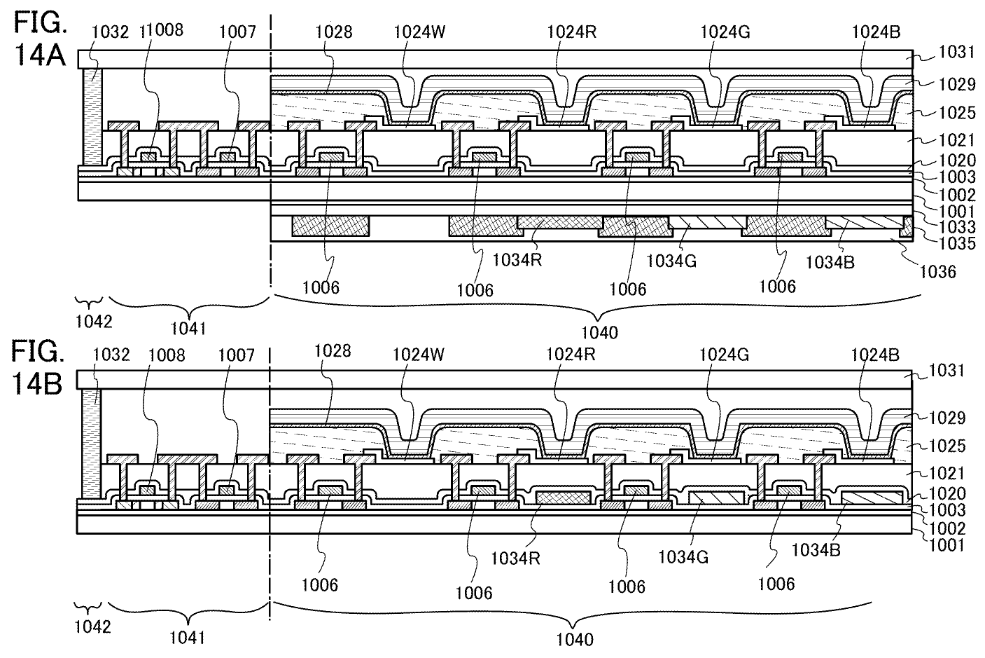

FIG. 14 illustrates examples of a light-emitting apparatus in which full color display is achieved by formation of a light-emitting device exhibiting white light emission and provision of coloring layers (color filters) and the like. FIG. 14A illustrates a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of the light-emitting devices, a partition 1025, an EL layer 1028, a second electrode 1029 of the light-emitting devices, a sealing substrate 1031, a sealant 1032, and the like.

In FIG. 14A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is positioned and fixed to the substrate 1001. Note that the coloring layers and the black matrix 1035 are covered with an overcoat layer 1036. In FIG. 14A, a light-emitting layer from which light is emitted to the outside without passing through the coloring layer and light-emitting layers from which light is emitted to the outside, passing through the coloring layers of the respective colors are shown. Since light that does not pass through the coloring layer is white and light that passes through the coloring layer is red, green, or blue, an image can be expressed by pixels of the four colors.

FIG. 14B shows an example in which the coloring layers (the red coloring layer 1034R, the green coloring layer 1034G, and the blue coloring layer 1034B) are formed between the gate insulating film 1003 and the first interlayer insulating film 1020. The coloring layers may be provided between the substrate 1001 and the sealing substrate 1031 in this manner.

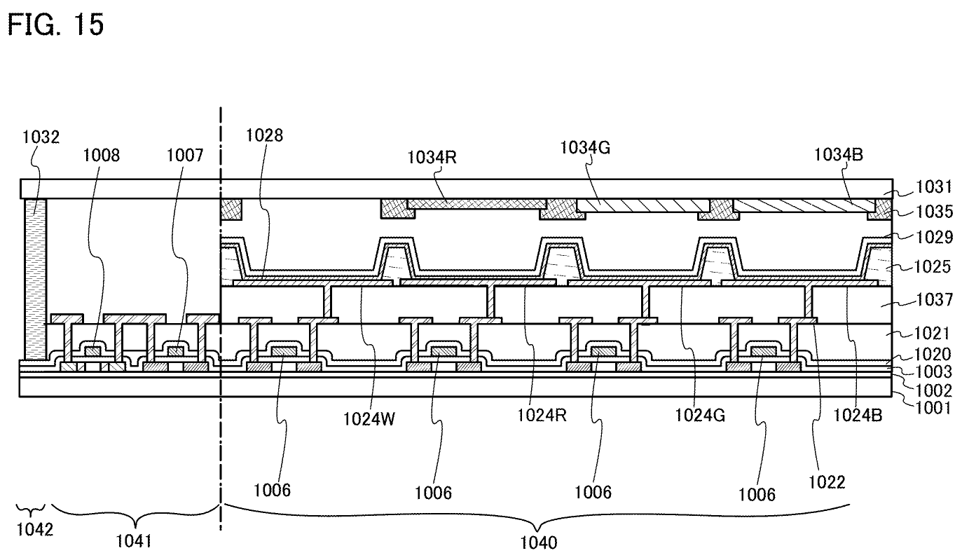

The above-described light-emitting apparatus is a light-emitting apparatus having a structure in which light is extracted to the substrate 1001 side where the FETs are formed (a bottom-emission type), but may be a light-emitting apparatus having a structure in which light emission is extracted to the sealing substrate 1031 side (a top-emission type). FIG. 15 shows a cross-sectional view of a top-emission light-emitting apparatus. In this case, a substrate that does not transmit light can be used as the substrate 1001. The top-emission light-emitting apparatus is formed in a manner similar to that of the bottom-emission light-emitting apparatus until a connection electrode which connects the FET and the anode of the light-emitting device is formed. Then, a third interlayer insulating film 1037 is formed to cover an electrode 1022. This insulating film may have a planarization function. The third interlayer insulating film 1037 can be formed using a material similar to that for the second interlayer insulating film or using any other known materials.

The first electrodes 1024W, 1024R, 1024G, and 1024B of the light-emitting devices are each an anode here, but may each be a cathode. Furthermore, in the case of the top-emission light-emitting apparatus illustrated in FIG. 15, the first electrodes are preferably reflective electrodes. The structure of the EL layer 1028 is such a structure as that of the unit 103 described in any one of Embodiment 1 to Embodiment 6, and an element structure with which white light emission can be obtained.

In the case of such a top-emission structure as in FIG. 15, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 which is positioned between pixels. The coloring layers (the red coloring layer 1034R, the green coloring layer 1034G, and the blue coloring layer 1034B) or the black matrix may be covered with the overcoat layer 1036. Note that a light-transmitting substrate is used as the sealing substrate 1031. Although an example in which full color display is performed using four colors of red, green, blue, and white is shown here, there is no particular limitation and full color display may be performed using four colors of red, yellow, green, and blue or three colors of red, green, and blue.

In the top-emission-type light-emitting apparatus, a microcavity structure can be favorably employed. A light-emitting device with a microcavity structure can be obtained with the use of a reflective electrode as the first electrode and a semi-transmissive and semi-reflective electrode as the second electrode. The light-emitting device with a microcavity structure includes at least an EL layer between the reflective electrode and the semi-transmissive and semi-reflective electrode, which includes at least a light-emitting layer serving as a light-emitting region.

Note that the reflective electrode is a film having a visible light reflectance of 40% to 100%, preferably 70% to 100%, and a resistivity of 1 × 10⁻² Ωcm or lower. In addition, the semi-transmissive and semi-reflective electrode is a film having a visible light reflectance of 20% to 80%, preferably 40% to 70%, and a resistivity of 1 × 10⁻² Ωcm or lower.

Light emitted from the light-emitting layer included in the EL layer is reflected and resonated by the reflective electrode and the semi-transmissive and semi-reflective electrode.

In the light-emitting device, by changing thicknesses of the transparent conductive film, the above-described composite material, the carrier-transport material, or the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is reflected back by the reflective electrode (first reflected light) considerably interferes with light that directly enters the semi-transmissive and semi-reflective electrode from the light-emitting layer (first incident light); therefore, the optical path length between the reflective electrode and the light-emitting layer is preferably adjusted to (2n–1)λ/4 (n is a natural number of 1 or larger and λ is a wavelength of light emission to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer; for example, in combination with the structure of the above-described tandem light-emitting device, a plurality of EL layers each including a single or a plurality of light-emitting layer(s) may be provided in one light-emitting device with a charge-generation layer interposed between the EL layers.

With the microcavity structure, emission intensity with a specific wavelength in the front direction can be increased, whereby power consumption can be reduced. Note that in the case of a light-emitting apparatus which displays images with subpixels of four colors, red, yellow, green, and blue, the light-emitting apparatus can have favorable characteristics because a microcavity structure suitable for wavelengths of the corresponding color is employed in each subpixel, in addition to the effect of an improvement in luminance owing to yellow light emission.

For the light-emitting apparatus in this embodiment, the light-emitting device described in any one of Embodiment 1 to Embodiment 6 is used and thus a light-emitting apparatus having favorable characteristics can be obtained. Specifically, since the light-emitting device described in any one of Embodiment 1 to Embodiment 6 has favorable emission efficiency, the light-emitting apparatus with low power consumption can be obtained.

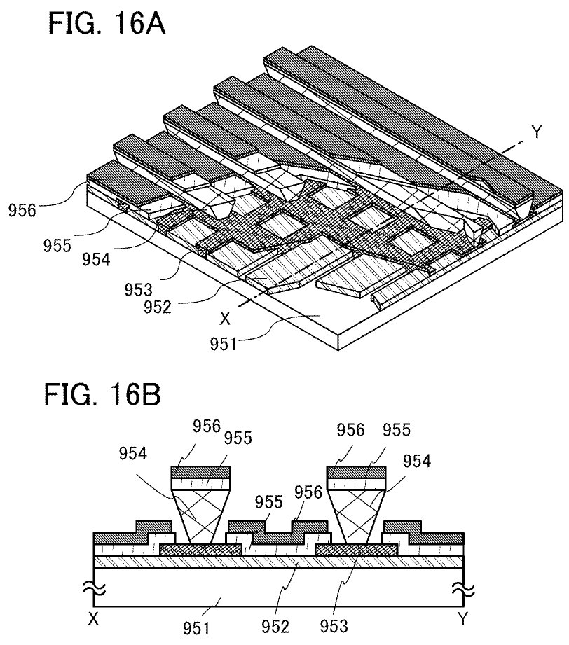

The active matrix light-emitting apparatus is described above, whereas a passive matrix light-emitting apparatus is described below. FIG. 16 illustrates a passive matrix light-emitting apparatus fabricated using the present invention. Note that FIG. 16A is a perspective view illustrating the light-emitting apparatus, and FIG. 16B is a cross-sectional view taken along X-Y in FIG. 16A. In FIG. 16, over a substrate 951, an EL layer 955 is provided between an electrode 952 and an electrode 956. An end portion of the electrode 952 is covered with an insulating layer 953. A partition layer 954 is provided over the insulating layer 953. Sidewalls of the partition layer 954 are aslope such that the distance between one sidewall and the other sidewall is gradually narrowed toward the surface of the substrate. That is, a cross section in the short side direction of the partition layer 954 is a trapezoidal shape, and the lower side (the side facing the same direction as the plane direction of the insulating layer 953 and touching the insulating layer 953) is shorter than the upper side (the side facing the same direction as the plane direction of the insulating layer 953, and not touching the insulating layer 953). By providing the partition layer 954 in this manner, defects of the light-emitting device due to static charge or the like can be prevented. The passive-matrix light-emitting apparatus also uses the light-emitting device described in any one of Embodiment 1 to Embodiment 6; thus, the light-emitting apparatus can have favorable reliability or low power consumption.

Since many minute light-emitting devices arranged in a matrix can each be controlled in the light-emitting apparatus described above, the light-emitting apparatus can be suitably used as a display device displaying images.

This embodiment can be freely combined with any of the other embodiments.

### Embodiment 11

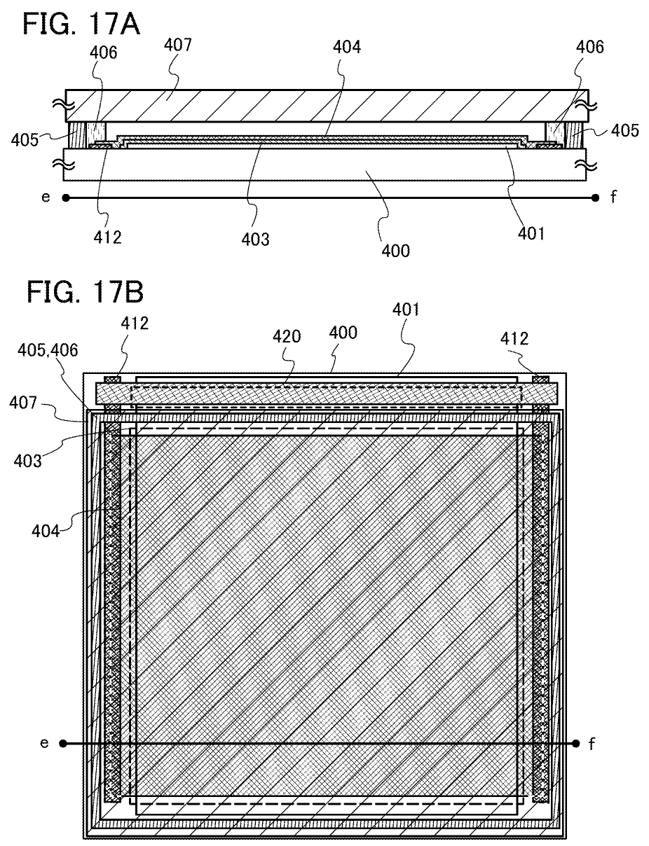

In this embodiment, an example in which the light-emitting device described in any one of Embodiment 1 to Embodiment 6 is used for a lighting device is described with reference to FIG. 17. FIG. 17B is a top view of the lighting device, and FIG. 17A is a cross-sectional view taken along e-f in FIG. 17B.

In the lighting device in this embodiment, a first electrode 401 is formed over a substrate 400 which is a support and has a light-transmitting property. The first electrode 401 corresponds to the electrode 101 in any one of Embodiment 1 to Embodiment 6. In the case where light emission is extracted from the first electrode 401 side, the first electrode 401 is formed with a material having a light-transmitting property.

A pad 412 for supplying a voltage to a second electrode 404 is formed over the substrate 400.

An EL layer 403 is formed over the first electrode 401. The EL layer 403 has a structure corresponding to the structure of the unit 103 in any one of Embodiment 1 to Embodiment 6, the structure in which the unit 103(12) and the intermediate layer 106 are combined, or the like. Note that for these structures, the corresponding description can be referred to.

The second electrode 404 is formed to cover the EL layer 403. The second electrode 404 corresponds to the electrode 102 in any one of Embodiment 1 to Embodiment 6. In the case where light emission is extracted from the first electrode 401 side, the second electrode 404 is formed with a material having high reflectance. The second electrode 404 is supplied with a voltage when connected to the pad 412.

As described above, the lighting device described in this embodiment includes a light-emitting device including the first electrode 401, the EL layer 403, and the second electrode 404. Since the light-emitting device is a light-emitting device with high emission efficiency, the lighting device in this embodiment can be a lighting device with low power consumption.

The substrate 400 over which the light-emitting device having the above structure is formed is fixed to a sealing substrate 407 with sealants 405 and 406 and sealing is performed, whereby the lighting device is completed. It is possible to use only either the sealant 405 or 406. In addition, the inner sealant 406 (not shown in FIG. 17B) can be mixed with a desiccant, which enables moisture to be adsorbed, resulting in improved reliability.

When parts of the pad 412 and the first electrode 401 are provided to extend to the outside of the sealants 405 and 406, those can serve as external input terminals. An IC chip 420 or the like mounted with a converter or the like may be provided over the external input terminals.

The lighting device described in this embodiment uses the light-emitting device described in any one of Embodiment 1 to Embodiment 6 as an EL element; thus, the light-emitting apparatus can have low power consumption.

### Embodiment 12

In this embodiment, examples of electronic devices each partly including the light-emitting device described in any one of Embodiment 1 to Embodiment 6 are described. The light-emitting device described in any one of Embodiment 1 to Embodiment 6 is a light-emitting device with favorable emission efficiency and low power consumption. As a result, the electronic devices described in this embodiment can be electronic devices each including a light-emitting portion with low power consumption.

Examples of electronic devices to which the light-emitting device is applied include a television devices (also referred to as TV or television receivers), monitors for computers and the like, digital cameras, digital video cameras, digital photo frames, mobile phones (also referred to as portable telephones or portable telephone devices), portable game machines, portable information terminals, audio playback devices, and large game machines such as pachinko machines. Specific examples of these electronic devices are shown below.

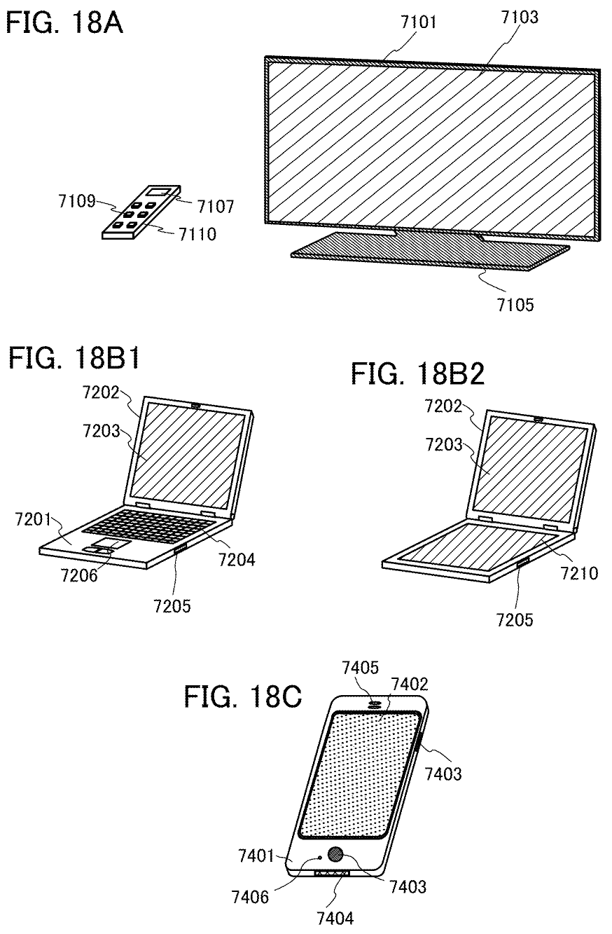

FIG. 18A shows an example of a television device. In the television device, a display portion 7103 is incorporated in a housing 7101. Here, a structure in which the housing 7101 is supported by a stand 7105 is shown. Images can be displayed on the display portion 7103, and the light-emitting devices described in any one of Embodiment 1 to Embodiment 6 are arranged in a matrix in the display portion 7103.

The television device can be operated with an operation switch of the housing 7101 or a separate remote controller 7110. With operation keys 7109 of the remote controller 7110, channels and volume can be operated and images displayed on the display portion 7103 can be operated. Furthermore, a structure may be employed in which the remote controller 7110 is provided with a display portion 7107 for displaying data output from the remote controller 7110.

Note that the television device has a structure of including a receiver, a modem, or the like. With the use of the receiver, a general television broadcast can be received, and moreover, when the television device is connected to a communication network with or without a wire via the modem, one-way (from a sender to a receiver) or two-way (between a sender and a receiver or between receivers) data communication can be performed.

FIG. 18B1 is a computer which includes a main body 7201, a housing 7202, a display portion 7203, a keyboard 7204, an external connection port 7205, a pointing device 7206, and the like. Note that this computer is fabricated using the light-emitting devices described in any one of Embodiment 1 to Embodiment 6 arranged in a matrix in the display portion 7203. The computer in FIG. 18B1 may be such a mode as illustrated in FIG. 18B2. The computer in FIG. 18B2 is provided with a second display portion 7210 instead of the keyboard 7204 and the pointing device 7206. The second display portion 7210 is of a touch-panel type, and input can be performed by operating display for input displayed on the second display portion 7210 with a finger or a dedicated pen. The second display portion 7210 can also display images other than the display for input. The display portion 7203 may also be a touch panel. Connecting the two screens with a hinge can prevent troubles such as a crack in or damage to the screens caused when the computer is stored or carried.

FIG. 18C shows an example of a portable terminal. A mobile phone includes operation buttons 7403, an external connection port 7404, a speaker 7405, a microphone 7406, and the like in addition to a display portion 7402 incorporated in a housing 7401. Note that the portable terminal includes the display portion 7402 which is fabricated by arranging the light-emitting devices described in any one of Embodiment 1 to Embodiment 6 in a matrix.

The portable terminal illustrated in FIG. 18C may have a structure in which information can be input by touching the display portion 7402 with a finger or the like. In this case, operations such as making a call and creating an e-mail can be performed by touching the display portion 7402 with a finger or the like.

The display portion 7402 has mainly three screen modes. The first one is a display mode mainly for displaying images, and the second one is an input mode mainly for inputting data such as text. The third one is a display+input mode in which two modes of the display mode and the input mode are combined.

For example, in the case of making a call or creating an e-mail, a text input mode mainly for inputting text is selected for the display portion 7402 so that an operation of inputting characters displayed on the screen may be performed. In this case, it is preferable to display a keyboard or number buttons on the entire screen of the display portion 7402.

When a sensing device including a sensor for sensing inclination, such as a gyroscope sensor or an acceleration sensor, is provided inside the portable terminal, screen display of the display portion 7402 can be automatically changed by determining the orientation of the portable terminal (vertically or horizontally).

The screen modes are changed by touching the display portion 7402 or operating the operation buttons 7403 of the housing 7401. Alternatively, the screen modes can be changed depending on the kind of image displayed on the display portion 7402. For example, when a signal of an image displayed on the display portion is moving image data, the screen mode is changed to the display mode, and when the signal is text data, the screen mode is changed to the input mode.

Moreover, in the input mode, when input by the touch operation of the display portion 7402 is not performed for a certain period while a signal sensed by an optical sensor in the display portion 7402 is sensed, the screen mode may be controlled so as to be changed from the input mode to the display mode.

The display portion 7402 can also function as an image sensor. For example, an image of a palm print, a fingerprint, or the like is taken when the display portion 7402 is touched with the palm or the finger, whereby personal authentication can be performed. Furthermore, by using a backlight which emits near-infrared light or a sensing light source which emits near-infrared light in the display portion, an image of a finger vein, a palm vein, or the like can be taken.

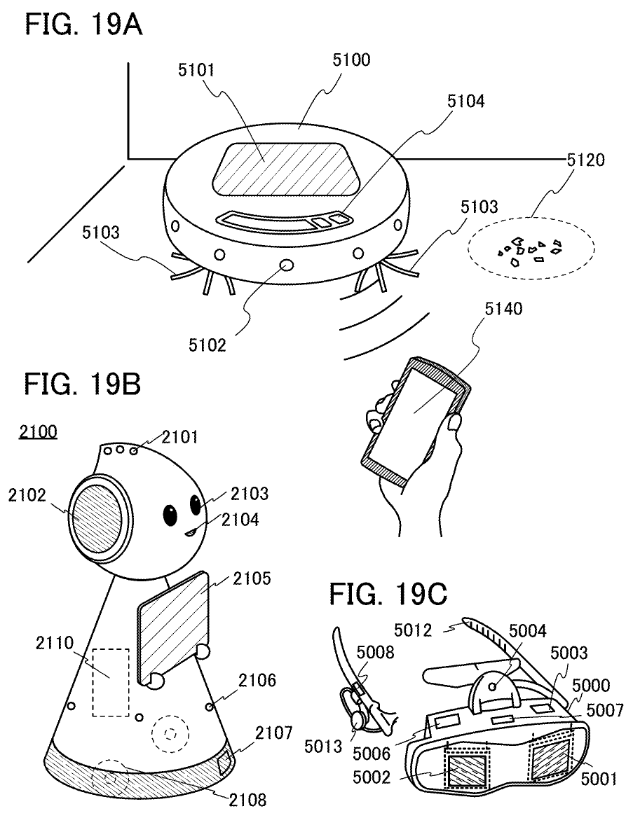

FIG. 19A is a schematic view showing an example of a cleaning robot.

A cleaning robot 5100 includes a display 5101 placed on its top surface, a plurality of cameras 5102 placed on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. In addition, the cleaning robot 5100 has a wireless communication means.

The cleaning robot 5100 is self-propelled, detects dust 5120, and sucks up the dust through the inlet provided on the bottom surface.

The cleaning robot 5100 can judge whether there is an obstacle such as a wall, furniture, or a step by analyzing images taken by the cameras 5102. When an object that is likely to be caught in the brush 5103, such as a wire, is detected by image analysis, the rotation of the brush 5103 can be stopped.

The display 5101 can display the remaining capacity of a battery, the amount of vacuumed dust, or the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. The portable electronic device 5140 can display images taken by the cameras 5102. Accordingly, an owner of the cleaning robot 5100 can monitor the room even from the outside. The display on the display 5101 can be checked by the portable electronic device such as a smartphone.

The light-emitting apparatus of one embodiment of the present invention can be used for the display 5101.

A robot 2100 illustrated in FIG. 19B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 also has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect the presence of an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 19C shows an example of a goggle-type display. The goggle-type display includes, for example, a housing 5000, a display portion 5001, a speaker 5003, an LED lamp 5004, a connection terminal 5006, a sensor 5007 (a sensor having a function of measuring force, displacement, position, speed, acceleration, angular velocity, rotational frequency, distance, light, liquid, magnetism, temperature, a chemical substance, sound, time, hardness, an electric field, current, voltage, power, radiation, flow rate, humidity, gradient, oscillation, odor, or infrared ray), a microphone 5008, a display portion 5002, a support 5012, and an earphone 5013.

The light-emitting apparatus of one embodiment of the present invention can be used for the display portion 5001 and the display portion 5002.

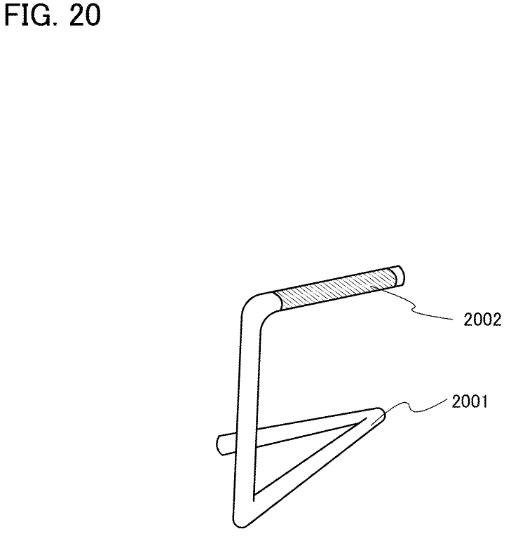

FIG. 20 shows an example in which the light-emitting device described in any one of Embodiment 1 to Embodiment 6 is used for a table lamp which is a lighting device. The table lamp illustrated in FIG. 20 includes a housing 2001 and a light source 2002, and the lighting device described in Embodiment 11 may be used for the light source 2002.

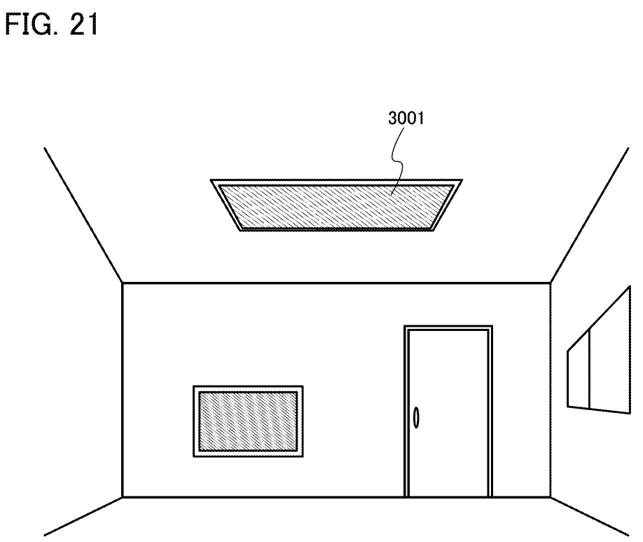

FIG. 21 shows an example in which the light-emitting device described in any one of Embodiment 1 to Embodiment 6 is used for an indoor lighting device 3001. Since the light-emitting device described in any one of Embodiment 1 to Embodiment 6 is a light-emitting device with high emission efficiency, the lighting device can have low power consumption. Furthermore, the light-emitting device described in any one of Embodiment 1 to Embodiment 6 can have a larger area, and thus can be used for a large-area lighting device. Furthermore, the light-emitting device described in any one of Embodiment 1 to Embodiment 6 is thin, and thus can be used for a lighting device having a reduced thickness.

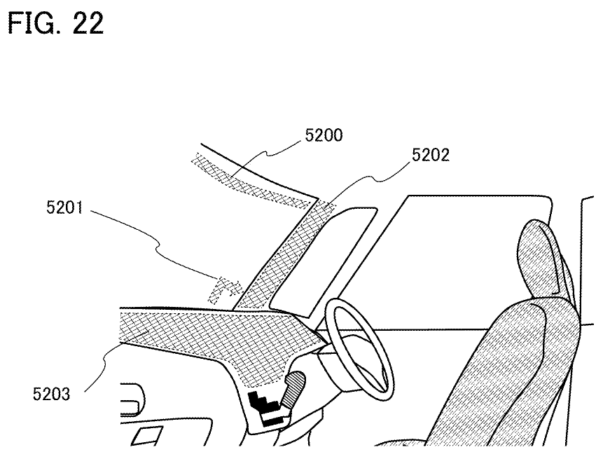

The light-emitting device described in any one of Embodiment 1 to Embodiment 6 can also be incorporated in an automobile windshield or an automobile dashboard. FIG. 22 illustrates one mode in which the light-emitting device described in any one of Embodiment 1 to Embodiment 6 is used for a windshield or a dashboard of an automobile. A display region 5200 to a display region 5203 are each a display provided using the light-emitting device described in any one of Embodiment 1 to Embodiment 6.

The display region 5200 and the display region 5201 are display devices provided in the automobile windshield, in which the light-emitting devices described in any one of Embodiment 1 to Embodiment 6 are incorporated. When the light-emitting devices described in any one of Embodiment 1 to Embodiment 6 are fabricated using electrodes having light-transmitting properties as a first electrode and a second electrode, what is called see-through display devices, through which the opposite side can be seen, can be obtained. See-through display can be provided without hindering the vision even when being provided in the automobile windshield. Note that in the case where a driving transistor or the like is provided, a transistor having a light-transmitting property, such as an organic transistor using an organic semiconductor material or a transistor using an oxide semiconductor, is preferably used.

The display region 5202 is a display device provided in a pillar portion, in which the light-emitting devices described in any one of Embodiment 1 to Embodiment 6 are incorporated. The display region 5202 can compensate for the view hindered by the pillar by displaying an image taken by an imaging means provided on the car body. Similarly, the display region 5203 provided in the dashboard portion can compensate for the view hindered by the car body by displaying an image taken by an imaging means provided on the outside of the automobile. Thus, blind areas can be compensated for and the safety can be enhanced. Showing an image so as to compensate for the area that cannot be seen makes it possible to confirm safety more naturally and comfortably.

The display region 5203 can provide a variety of kinds of information by displaying navigation data, a speedometer, a tachometer, a mileage, a fuel meter, a gearshift state, air-condition setting, and the like. The content or layout of the display can be changed freely in accordance with the preference of a user. Note that such information can also be provided on the display region 5200 to the display region 5202. The display region 5200 to the display region 5203 can also be used as lighting devices.

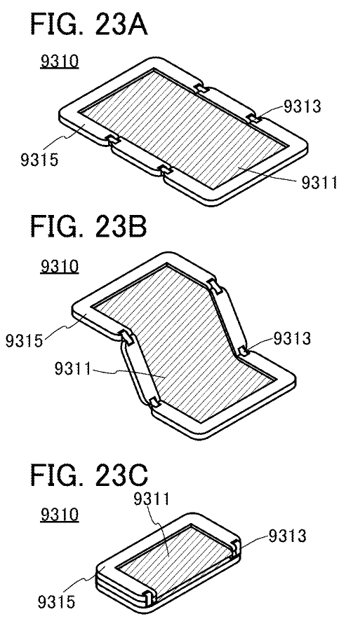

FIG. 23A to FIG. 23C illustrate a foldable portable information terminal 9310. FIG. 23A illustrates the portable information terminal 9310 that is opened. FIG. 23B illustrates the portable information terminal 9310 that is in the state of being changed from one of an opened state and a folded state to the other. FIG. 23C illustrates the portable information terminal 9310 that is folded. The portable information terminal 9310 is excellent in portability when folded, and is excellent in display browsability when opened because of a seamless large display region.

A display panel 9311 is supported by three housings 9315 joined together by hinges 9313. Note that the display panel 9311 may be a touch panel (an input/output device) including a touch sensor (an input device). By folding the display panel 9311 at the hinges 9313 between two housings 9315, the portable information terminal 9310 can be reversibly changed in shape from the opened state to the folded state. A light-emitting apparatus of one embodiment of the present invention can be used for the display panel 9311.

Note that the structures described in this embodiment can be combined with the structures described in any of Embodiment 1 to Embodiment 6 as appropriate.

As described above, the application range of the light-emitting apparatus including the light-emitting device described in any one of Embodiment 1 to Embodiment 6 is wide, so that this light-emitting apparatus can be applied to electronic devices in a variety of fields. With the use of the light-emitting device described in any one of Embodiment 1 to Embodiment 6, an electronic device with low power consumption can be obtained.

Note that this embodiment can be combined with any of the other embodiments in this specification as appropriate.

### Example 1

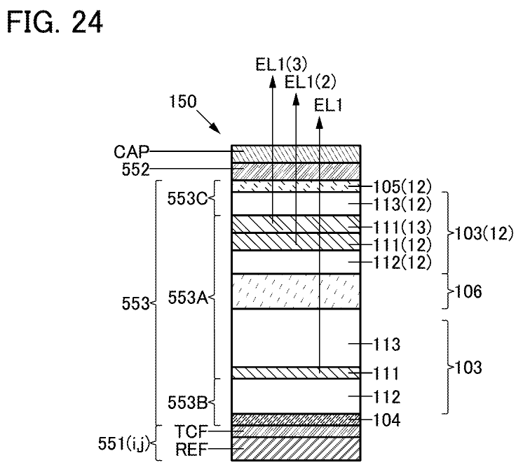

In this example, structures of Light-emitting device 1 to Light-emitting device 3 of one embodiment of the present invention are described with reference to FIG. 24 to FIG. 26.

FIG. 24 is a diagram illustrating the structures of Light-emitting device 1 to Light-emitting device 3.

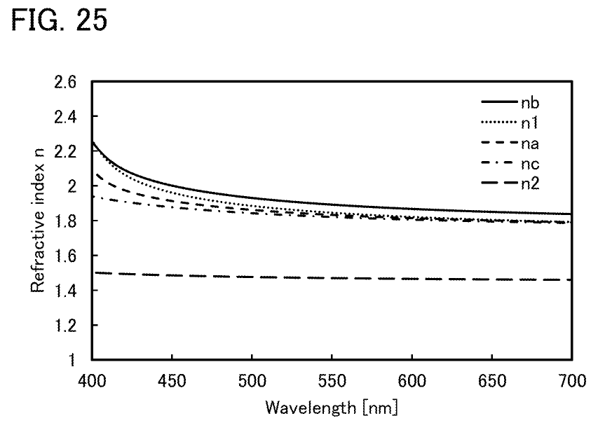

FIG. 25 is a diagram illustrating wavelength-ordinary refractive index characteristics of materials used for Light-emitting device 1 to Light-emitting device 3.

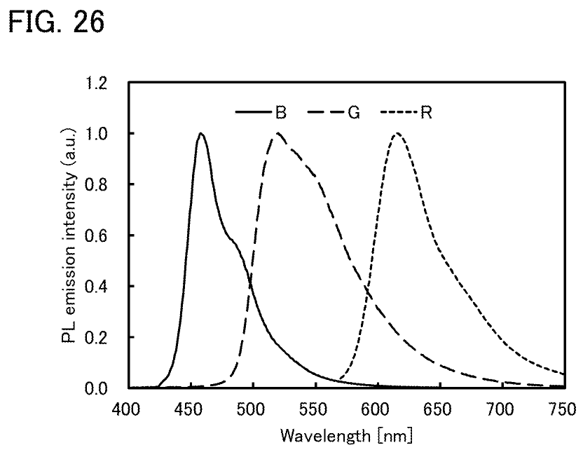

FIG. 26 is a diagram showing emission spectra of light-emitting materials used for Light-emitting device 1 to Light-emitting device 3.

### Light-Emitting Device 1 to Light-Emitting Device 3

Light-emitting device 1 to Light-emitting device 3 described in this embodiment each include the electrode 551(i, j), the electrode 552, and the EL layer 553 (see FIG. 24).

The electrode 551(i, j) includes a light-transmitting conductive film TCF and a reflective film REF. The electrode 551(i, j) has the transmittance T1. The electrode 552 includes a region overlapping with the electrode 551(i, j). Note that the electrode 552 has the second transmittance T2, and the transmittance T2 is higher than the transmittance T1.

### Structure of EL Layer 553

The EL layer 553 includes a region interposed between the electrode 551(i, j) and the electrode 552, and the EL layer 553 includes the region 553A, the region 553B, and the region 553C.

The region 553A includes a portion interposed between the region 553B and the region 553C. Note that the region 553A includes the layer 111, the layer 111(12), and the layer 111(13) each including a light-emitting material.

The region 553B includes a region interposed between the electrode 551(i, j) and the region 553A, and the region 553B has the refractive index n1. The region 553B includes the layer 104 and the layer 112, and the region 553B includes a material HTM. Note that the material HTM has the refractive index n1 (see FIG. 25). The refractive index n1 was used to calculate light extraction efficiency.

The region 553C includes a region interposed between the region 553A and the electrode 552, and the region 553C has the refractive index n2. The refractive index n2 is lower than the refractive index n1. The region 553C also includes the layer 113(12) and the layer 105(12), and the region 553C includes a material ETM_Low. Note that the material ETM_Low has the refractive index n2 (see FIG. 25). The refractive index n2 was used to calculate light extraction efficiency.

The EL layer 553 includes the unit 103 the unit 103(12), and the intermediate layer 106 (see FIG. 24).

### Structure of Intermediate Layer 106

The intermediate layer 106 is interposed between the unit 103 and the unit 103(12). The intermediate layer 106 has a function of supplying holes to one of the unit 103 and the unit 103(12) and supplying electrons to the other thereof.

### Structure of Unit 103

The unit 103 is interposed between the electrode 551(i, j) and the intermediate layer 106, and the unit 103 includes the layer 111 including a light-emitting material.

### Structure of Unit 103(12)

The unit 103(12) is interposed between the intermediate layer 106 and the electrode 552, and the unit 103(12) includes the layer 111(12) including a light-emitting material.

### Structure of Region 553A

The region 553A includes the layer 111 including a light-emitting material and the layer 111(12) including a light-emitting material.

The unit 103(12) includes a layer 111(13) including a light-emitting material (see FIG. 24). For example, the layer 111(12) including a light-emitting material includes a region interposed between the layer 111 including a light-emitting material and the electrode 552, and the layer 111(13) including a light-emitting material includes a region interposed between the layer 111(12) including a light-emitting material and the electrode 552.

### Structure of Layers Including Light-Emitting Material

The layer 111 including a light-emitting material has a function of emitting blue light; the layer 111(12) including a light-emitting material has a function of emitting red light; and the layer 111(13) including a light-emitting material has a function of emitting green light (see FIG. 26). Note that the light extraction efficiency was calculated using the spectrum B for the blue light, the spectrum G for the green light, and the spectrum R for the red light.

### Structure of Light-Emitting Device 1 to Light-Emitting Device 3

Table 1 shows the structures of Light-emitting device 1 to Light-emitting device 3. Structural formulae of the materials used in the light-emitting devices described in this example are shown below.

TABLE 1

| Structure Reference numeral | Material | Refractive index | Thickness/nm |
|---|---|---|---|
| Cap layer CAP | DBT3P-II | nc | 70 |
| Electrode 502 | Ag:Mg | | 15 |
| Layer 105(12) | ETM_Low | n2 | 40 |
| Layer 113(12) | ETM_ref | nb | 10 |
| Layer 111(13) | Host:dopant_G | na | 20 |
| Layer 111(12) | Host:dopant_R | na | 20 |
| Layer 113+Layer 106+Layer 112(12) | ETM+CGM+HTM | n1 | 70 |
| Layer 111 | Host:dopant_B | na | 20 |
| Layer 104+Layer 112 | HTM | n1 | 55 |
| Conductive film TCF | ITSO | | X |
| Reflective film REF | APC | | 100 |

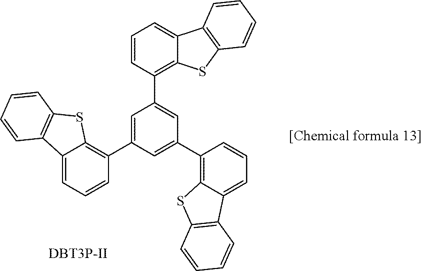

In Light-emitting device 1 to Light-emitting device 3, an alloy (APC) containing silver, palladium, and copper was used for the reflective film REF, and indium oxide-tin oxide (ITSO) containing silicon oxide was used for the light-transmitting conductive film TCF. Note that Light-emitting device 1 to Light-emitting device 3 include the light-transmitting conductive films TCF with different thicknesses (see Table 2).

The hole-transport material HTM was used for the layer 104 and the layer 112, and n1 was used as the refractive index of each of the layer 104 and the layer 112.

A host material Host and a light-emitting material dopant_B were used for the layer 111, and na was used as the refractive index of the layer 111.

The electron-transport material ETM was used for the layer 113, a material CGM which can be used for the intermediate layer was used for the intermediate layer 106, and the hole-transport material HTM was used for the layer 112(12). As the refractive index of each of the layer 113, the intermediate layer 106, and the layer 112(12), n1 was used.

The host material Host and the light-emitting material dopant_R were used for the layer 111(12), and the host material Host and the light-emitting material dopant_G were used for the layer 111(13). As the refractive index of each of the layer 111(12) and the layer 111(13), na was used.

An electron-transport material ETM_ref was used for the layer 113(12), and nb was used as the refractive index of the layer 113(12). The electron-transport material ETM_Low with a low refractive index was used for the layer 105(12), and n2 was used as the refractive index of the layer 105(12). Note that the refractive index n2 is lower than the refractive index n1 (see FIG. 25).

An alloy Ag:Mg containing silver and magnesium was used for the electrode 552. In addition, 4,4′,4″-(benzene-1,3,5-triyl)tri(dibenzothiophene) (abbreviation: DBT3P-II) was used for a cap layer CAP.

### Characteristics of Light-Emitting Device 1 to Light-Emitting Device 3

The external quantum efficiency was calculated with a computer and an organic EL device simulation software (setfos, produced by Cybernet Systems Co., Ltd.). The results are shown in Table 2. Note that Light-emitting device 1 to Light-emitting device 3 include the EL layers 553 having the same structure. The thickness of each electrode 551(i, j) was optimized so that light of the desired color can be efficiently emitted.

The external quantum efficiency of each of Light-emitting device 1 to Light-emitting device 3 was in the range of 33.2% to 40.0% inclusive.

TABLE 2

| | Region 533C | Conductive film TCO nm | Emission color | External quantum efficiency (%) |
|---|---|---|---|---|
| Light-emitting device 1 | ETM_Low | 82.0 | Blue | 33.2 |
| Light-emitting device 2 | ETM_Low | 8.9 | Green | 40.0 |
| Light-emitting device 3 | ETM_Low | 74.3 | Red | 39.4 |
| Comparative Light-emitting device 1 | ETM_ref | 84.1 | Blue | 29.4 |
| Comparative Light-emitting device 2 | ETM_ref | 19.3 | Green | 28.8 |
| Comparative Light-emitting device 3 | ETM_ref | 84.1 | Red | 30.1 |

Light-emitting device 1 to Light-emitting device 3 were each found to exhibit better characteristics than the comparative light-emitting devices. The external quantum efficiency of each of Light-emitting device 2 and Light-emitting device 3 was better than that of Light-emitting device 1. The evanescent loss in each of Light-emitting device 2 and Light-emitting device 3 was able to be inhibited compared with that in Light-emitting device 1. Using the material with a low refractive index for the region 553A was able to improve the reflectance of the electrode 552. Thus, it can be confirmed that the light emitted from the region 553A was efficiently extracted from the electrode 552. As a result, a novel optical functional device that is highly convenient, useful, or reliable was successfully provided.

### (Reference Example 1)

Comparative light-emitting device 1 to Comparative light-emitting device 3 were different from Light-emitting device 1 to Light-emitting device 3 in that the electron-transport material ETM_ref was used for the layer 105(12) (see Table 1). Different portions are described in detail here, and the above description is referred to for portions that can use similar structures.

Comparative light-emitting device 1 to Comparative light-emitting device 3 each include the layer 113(12) and the layer 105(12) in the region 553C. The electron-transport material ETM_ref was used for the layer 113(12) and the layer 105(12), and nb was used as the refractive index of each of the layer 113(12) and the layer 105(12). Note that the refractive index nb is higher than the refractive index n1 (see FIG. 25).

### Characteristics of Comparative Light-Emitting Device 1 to Comparative Light-Emitting Device 3

The calculated external quantum efficiency is shown in Table 2. The external quantum efficiency of each of Comparative light-emitting device 1 to Comparative light-emitting device 3 is in the range of 28.8 % to 30.1 % inclusive.

### Synthesis Example 1

In this example, a method of synthesizing the material having an electron-transport property with a low refractive index described in Embodiment 2 is described.

First, a synthesis method of 2-{(3′,5′-di-tert-butyl)-1,1′-biphenyl-3-yl}-4,6-bis(3,5-di-tert-butylphenyl)-1,3,5-triazine (abbreviation: mmtBumBP-dmmtBuPTzn), which is an organic compound represented by Structural Formula (200) below, is described in detail. The structure of mmtBumBP-dmmtBuPTzn is shown below.

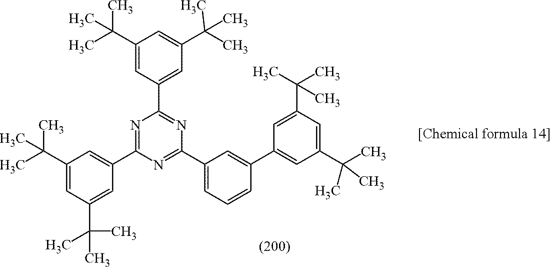

### Step 1: Synthesis of 3-bromo-3′,5′-di-tert-butylbiphenyl

Into a three-neck flask were put 1.0 g (4.3 mmol) of 3,5-di-t-butylphenylboronic acid, 1.5 g (5.2 mmol) of 1-bromo-3-iodobenzene, 4.5 mL of an aqueous solution of potassium carbonate (2 mol/L), 20 mL of toluene, and 3 mL of ethanol, and the mixture was degassed by being stirred under reduced pressure. To this mixture were added 52 mg (0.17 mmol) of tris(2-methylphenyl)phosphine (abbreviation: P(o-tolyl)₃) and 10 mg (0.043 mmol) of palladium(II) acetate, and reaction was caused under a nitrogen atmosphere at 80° C. for 14 hours. After the reaction, extraction was performed with toluene and the obtained organic layer was dried with magnesium sulfate. This mixture was subjected to gravity filtration, and the obtained filtrate was purified by silica gel column chromatography with a developing solvent of hexane to give 1.0 g of a target white solid in a yield of 68%. The synthesis scheme of Step 1 is shown in the formula below.

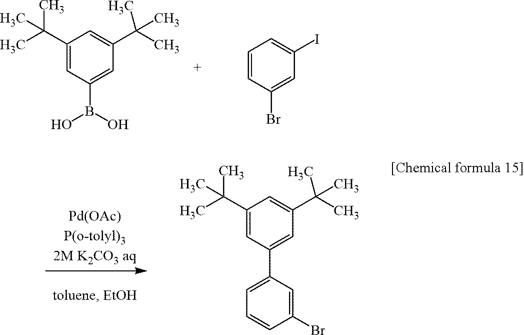

### Step 2: 2-(3′6,5′-di-tert-butylbiphenyl-3-yl)-4,4,5,5-tetramethyl-1,3,2-dioxaborolane

Into a three-neck flask were put 1.0 g (2.9 mmol) of 3-bromo-3′,5′-di-tert-butylbiphenyl, 0.96 g (3.8 mmol) of bis(pinacolato)diboron, 0.94 g (9.6 mmol) of potassium acetate, and 30 mL of 1,4-dioxane, and the mixture was degassed by being stirred under reduced pressure. To this mixture were added 0.12 g (0.30 mmol) of 2-dicyclohexylphosphino-2′,6′-dimethoxybiphenyl (abbreviation: SPhos) and 0.12 g (0.15 mmol) of [1,1′-bis(diphenylphosphino)ferrocene]palladium(II) dichloride dichloromethane adduct, and reaction was caused under a nitrogen atmosphere at 110° C. for 24 hours. After the reaction, extraction was performed with toluene and the obtained organic layer was dried with magnesium sulfate. This mixture was subjected to gravity filtration. The resulting filtrate was purified by silica gel column chromatography with a developing solvent of toluene to give 0.89 g of a target yellow oil in a yield of 78%. The synthesis scheme of Step 2 is shown in the formula below.

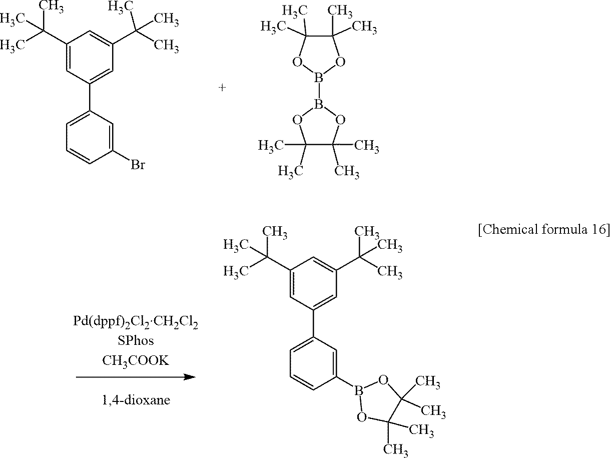

### Step 3: Synthesis of mmtBumBP-dmmtBuPTzn

Into a three-neck flask were put 0.8 g (1.6 mmol) of 4,6-bis(3,5-di-tert-butyl-phenyl)-2-chloro-1,3,5-triazine, 0.89 g (2.3 mmol) of 2-(3′,5′-di-tert-butylbiphenyl-3-yl)-4,4,5,5-tetramethyl-1,3,2-dioxaborolane, 0.68 g (3.2 mmol) of tripotassium phosphate, 3 mL of water, 8 mL of toluene, and 3 mL of 1,4-dioxane, and the mixture was degassed by being stirred under reduced pressure. To this mixture were added 3.5 mg (0.016 mmol) of palladium(II) acetate and 10 mg (0.032 mmol) of tris(2-methylphenyl)phosphine, and the mixture was heated and refluxed under a nitrogen atmosphere for 12 hours. After the reaction, extraction was performed with ethyl acetate and the obtained organic layer was dried with magnesium sulfate. This mixture was subjected to gravity filtration. The resulting filtrate was concentrated, followed by purification by silica gel column chromatography with a developing solvent of ethyl acetate and hexane in a ratio of 1:20 to give a solid. This solid was purified by silica gel column chromatography with a developing solvent of chloroform and hexane in a ratio of 5:1, which was then changed to 1:0. The obtained solid was recrystallized with hexane to give 0.88 g of a target white solid in a yield of 76%. The synthesis scheme of Step 3 is shown in the formula below.

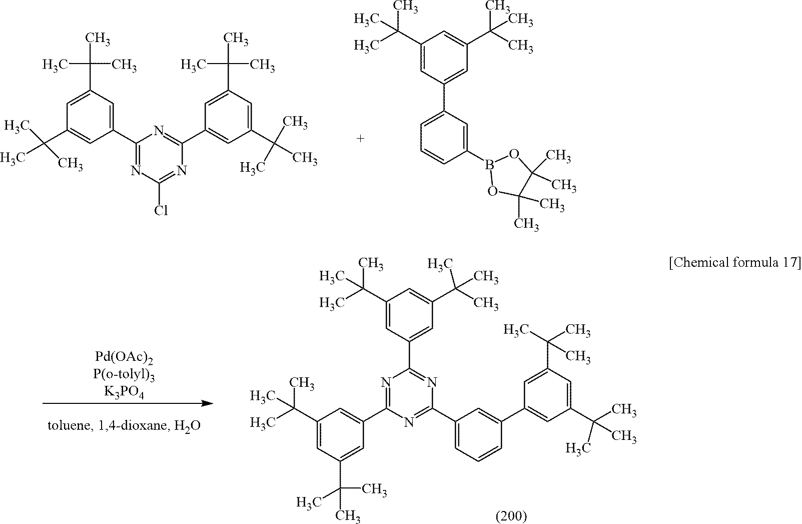

Then, 0.87 g of the obtained white solid was purified by a train sublimation method at 230° C. under a pressure of 5.8 Pa while an argon gas was made to flow. After the purification by sublimation, 0.82 g of a target white solid was obtained at a collection rate of 95%.

Analysis results by nuclear magnetic resonance spectroscopy (¹H-NMR) of the white solid obtained in Step 3 are shown below. The results show that mmtBumBP-dmmtBuPTzn represented by Structural Formula (200) shown above was obtained in this synthesis example.

H¹ NMR (CDCl₃, 300 MHz):δ = 1.42-1.49 (m, 54H), 7.50 (s, 1H), 7.61-7.70 (m, 5H), 7.87 (d, 1H), 8.68-8.69 (m, 4H), 8.78 (d, 1H), 9.06 (s, 1H).

Similarly, the organic compounds represented by Structural Formulae (201) to (204) were synthesized.

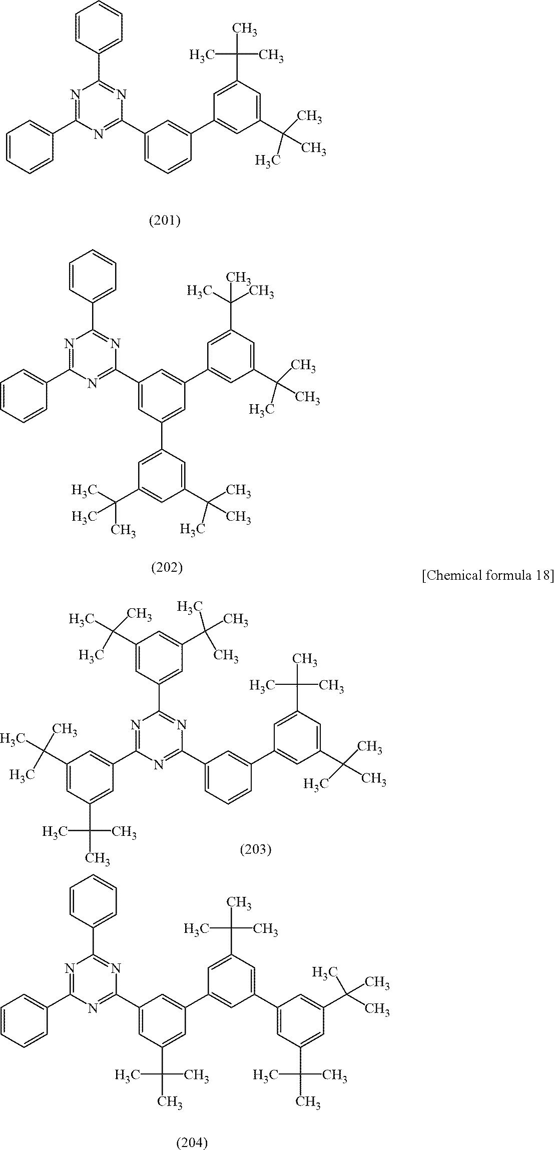

Analysis results by nuclear magnetic resonance spectroscopy (¹H-NMR) of the above organic compound are shown below.

### Structural Formula (201): 2-{(3′,5′-di-tert-butyl)-1,1′-biphenyl-3-yl}-4,6-diphenyl-1,3,5-triazine (Abbreviation: mmtBumBPTzn)

H¹ NMR (CDCl₃, 300 MHz):δ = 1.44 (s, 18H), 7.51-7.68 (m, 10H), 7.83 (d, 1H), 8.73-8.81 (m, 5H), 9.01 (s, 1H).

### Structural Formula (202): 2-(3,3′,5′,5″-tetra-tert-butyl-1,1′:3′,1″-phenyl-5′-yl)-4,6-diphenyl-1,3,5-triazine (Abbreviation: mmtBumTPTzn)

H¹ NMR (CDCl₃, 300 MHz):δ = 1.44 (s, 36H), 7.54-7.62 (m, 12H), 7.99 (t, 1H), 8.79 (d, 4H), 8.92 (d, 2H).

### Structural Formula (203): 2-{(3′,5′-di-tert-butyl)-1,1′-biphenyl-3-yl}-4,6-bis(3,5-di-tert-butylphenyl)-1,3-pyrimidine (Abbreviation: mmtBumBP-dmmtBuPPm)

H¹ NMR (CDCl₃, 300 MHz):δ = 1.39-1.45 (m, 54H), 7.47 (t, 1H), 7.59-7.65 (m, 5H), 7.76 (d, 1H), 7.95 (s, 1H), 8.06 (d, 4H), 8.73 (d, 1H), 8.99 (s, 1H).

### Structural Formula (204): 2-(3,3′,5′,5″-tetra-tert-butyl-1,1′:3′,1″-terphenyl-5-yl)-4,6-diphenyl-1,3,5-triazine (Abbreviation: mmtBumTPTzn-02)

H¹ NMR (CDCl₃, 300 MHz):δ = 1.41 (s, 18H), 1.49 (s, 9H), 1.52 (s, 9H), 7.49 (s, 3H), 7.58-7.63 (m, 7H), 7.69-7.70 (m, 2H), 7.88 (t, 1H), 8.77-8.83 (m, 6H).

The substances described above each have an ordinary refractive index higher than or equal to 1.50 and lower than or equal to 1.75 in a blue light emission range (455 nm to 465 nm) or an ordinary refractive index higher than or equal to 1.45 and lower than or equal to 1.70 with respect to light of wavelength 633 nm, which is usually used for measurement of refractive indices.

### Synthesis Example 2

In this example, a method of synthesizing the material having a hole-transport property with a low refractive index described in Embodiment 2 is described.

First, a method of synthesizing N,N-bis(4-cyclohexylphenyl)-N-(9,9-dimethyl-9H-fluoren-2yl)amine (abbreviation: dchPAF) is described in detail. The structure of dchPAF is shown below.

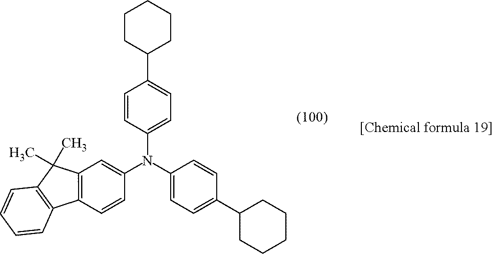

### Step 1: Synthesis of N,N-bis(4-cyclohexylphenyl)-N-(9,9-dimethyl-9H-fluoren-2yl)amine (Abbreviation: dchPAF)

In a three-neck flask were put 10.6 g (51 mmol) of 9,9-dimethyl-9H-fluoren-2-amine, 18.2 g (76 mmol) of 4-cyclohexyl-1-bromobenzene, 21.9 g (228 mmol) of sodium-tert-butoxide, and 255 mL of xylene. The mixture was degassed under reduced pressure, and then the air in the flask was replaced with nitrogen. This mixture was stirred while being heated to approximately 50° C. Then, 370 mg (1.0 mmol) of allylpalladium(II) chloride dimer (abbreviation: (AllylPdCl)₂) and 1660 mg (4.0 mmol) of di-tert-butyl(1-methyl-2,2-diphenylcyclopropyl)phosphine (abbreviation: cBRIDP (registered trademark)) were added, and the mixture was heated at 120° C. for approximately 5 hours. After that, the temperature of the flask was lowered to approximately 60° C., and approximately 4 mL of water was added to the mixture, so that a solid was precipitated. A precipitated solid was separated by filtration. The filtrate was concentrated, and the obtained solution was purified by silica gel column chromatography. The obtained solution was concentrated to give a concentrated toluene solution. This toluene solution was dropped into ethanol for reprecipitation. The precipitate was collected by filtration at approximately 10° C. and the obtained solid was dried at approximately 80° C. under reduced pressure, whereby 10.1 g of a target white solid was obtained in a yield of 40%. The synthesis scheme of dchPAF in Step 1 is shown below.

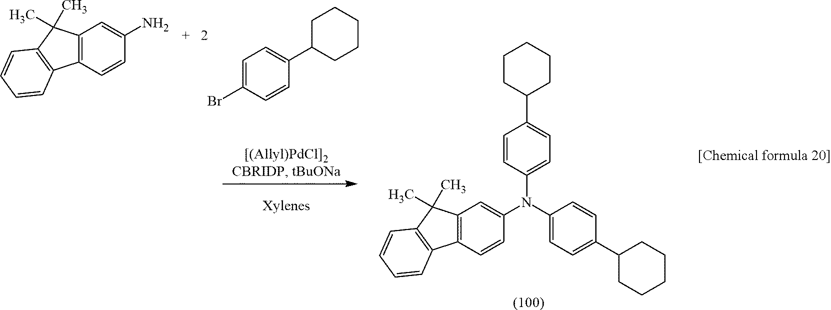

Analysis results by nuclear magnetic resonance spectroscopy (¹H-NMR) of the white solid obtained in Step 1 are shown below. The results show that dchPAF was synthesized in this synthesis example.

¹H-NMR. δ (CDCl₃): 7.60 (d, 1H, J = 7.5 Hz), 7.53 (d, 1H, J = 8.0 Hz), 7.37 (d, 2H, J = 7.5 Hz), 7.29 (td, 1H, J = 7.5 Hz, 1.0 Hz), 7.23 (td, 1H, J = 7.5 Hz, 1.0 Hz), 7.19 (d, 1H, J = 1.5 Hz), 7.06 (m, 8H), 6.97 (dd, 1H, J = 8.0 Hz, 1.5 Hz), 2.41-2.51 (brm, 2H), 1.79-1.95 (m, 8H), 1.70-1.77 (m, 2H), 1.33-1.45 (brm, 14H), 1.19-1.30 (brm, 2H).

Similarly, the organic compounds represented by Structural Formulae (101) to (109) were synthesized.

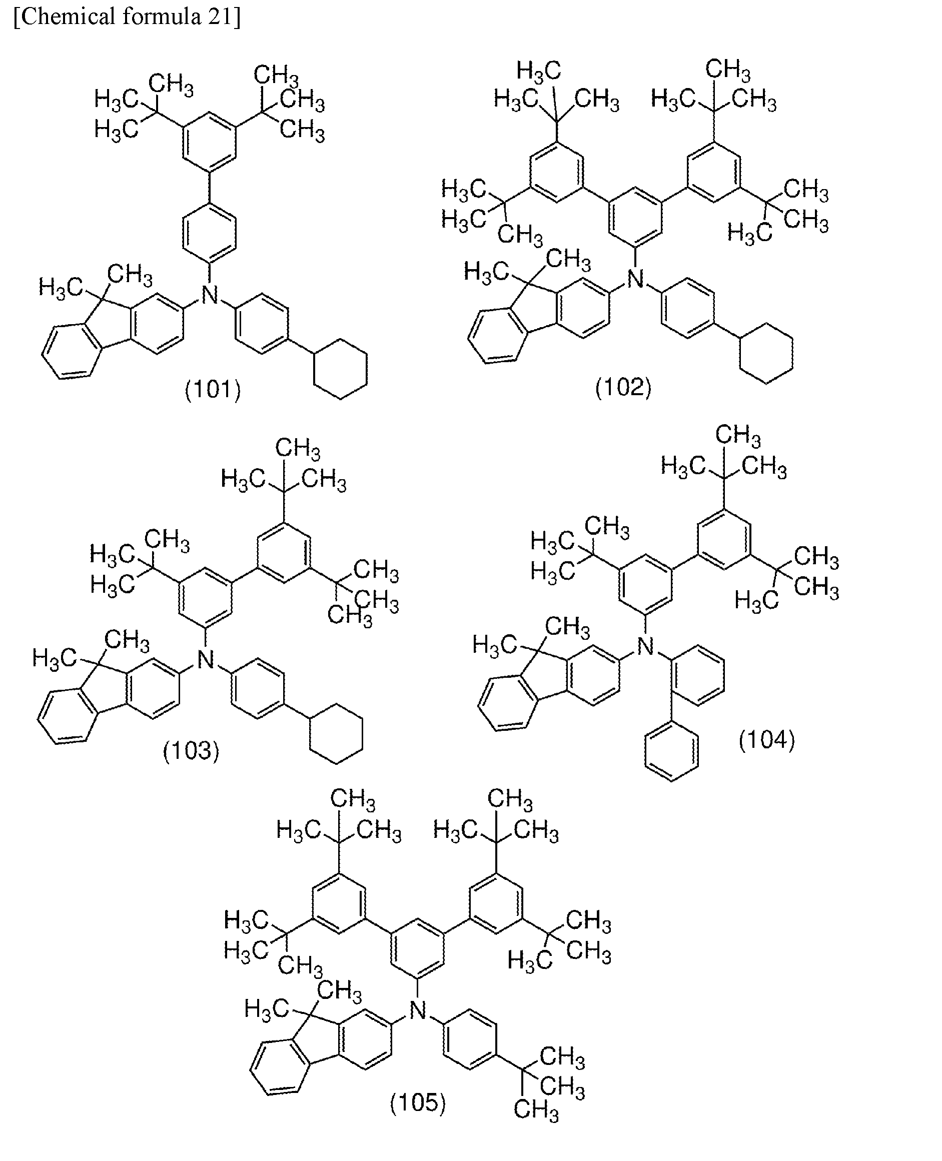

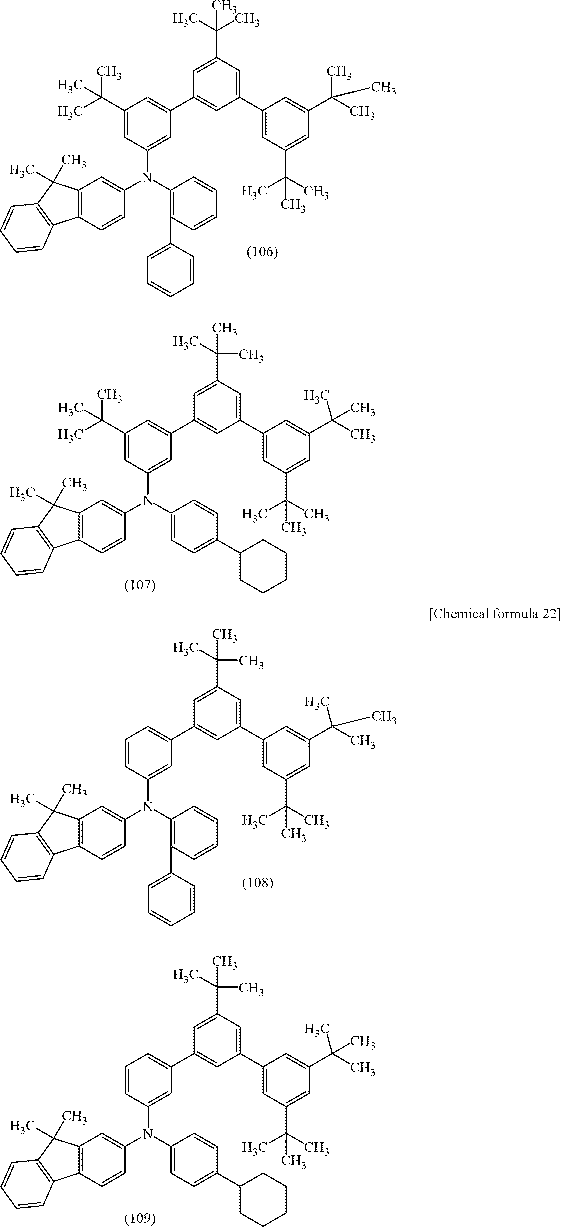

Analysis results by nuclear magnetic resonance spectroscopy (¹H-NMR) of the above organic compound are shown below.

### Structural Formula (101): N-(4-cyclohexylphenyl)-N-(3″,5″-ditertiarybutyl-1,1″-biphenyl-4-yl)-N-(9,9-dimethyl-9H-fluoren-2yl)amine (Abbreviation: mmtBuBichPAF)

¹H-NMR. δ (CDCl₃): 7.63 (d, 1H, J = 7.5 Hz), 7.57 (d, 1H, J = 8.0 Hz), 7.44-7.49 (m, 2H), 7.37-7.42 (m, 4H), 7.31 (td, 1H, J = 7.5 Hz, 2.0 Hz), 7.23-7.27 (m, 2H), 7.15-7.19 (m, 2H), 7.08-7.14 (m, 4H), 7.05 (dd, 1H, J = 8.0 Hz, 2.0 Hz), 2.43-2.53 (brm, 1H), 1.81-1.96 (m, 4H), 1.75 (d, 1H, J = 12.5 Hz), 1.32-1.48 (m, 28H), 1.20-1.31 (brm, 1H).

### Structural Formula (102): N-(3,3″,5,5″-tetra-t-butyl-1,1′:3′,1″-terphenyl-5′-yl)-N(4-cyclohexylphenyl)-9,9-dimethyl-9H-fluoren-2-amine (Abbreviation: mmtBumTPchPAF)

¹H-NMR (300 MHz, CDCl₃): δ = 7.63 (d, J = 6.6 Hz, 1H), 7.58 (d, J = 8.1 Hz, 1H), 7.42-7.37 (m, 4H), 7.36-7.09 (m, 14H), 2.55-2.39 (m, 1H), 1.98-1.20 (m, 51H).

### Structural Formula (103): N-(3,3′,5′-t-butyl)-1,1′-biphenyl-5-yl-N-(4-cyclohexylphenyl)-9,9-dimethyl-9H-fluoren-2-amine (Abbreviation: mmtBumBichPAF)

¹H-NMR. δ (CDCl₃): 7.63 (d, 1H, J = 7.5 Hz), 7.56 (d, 1H, J = 8.5 Hz), 7.37-40 (m, 2H), 7.27-7.32 (m, 4H), 7.22-7.25 (m, 1H), 7.16-7.19 (brm, 2H), 7.08-7.15 (m, 4H), 7.02-7.06 (m, 2H), 2.43-2.51 (brm, 1H), 1.80-1.93 (brm, 4H), 1.71-1.77 (brm, 1H), 1.36-1.46 (brm, 10H), 1.33 (s, 18H), 1.22-1.30 (brm, 10H).

### Structural Formula (104): N(1,1′-biphenyl-2-yl)-N-(3,3′,5′-tri-t-butyl)-1,1′-biphenyl-5-yl-9,9-dimethyl-9H-fluoren-2-amine (Abbreviation: mmtBumBioFBi)

¹H-NMR. δ (CDCl₃): 7.57 (d, 1H, J = 7.5 Hz), 7.40-7.47 (m, 2H), 7.32-7.39 (m, 4H), 7.27-7.31 (m, 2H), 7.27-7.24 (m, 5H), 6.94-7.09 (m, 6H), 6.83 (brs, 2H), 1.33 (s, 18H), 1.32 (s, 6H), 1.20 (s, 9H).

### Structural Formula (105): N-(4-tert-butylphenyl)-N-(3,3″,5,5″-tetra-t-butyl-1,1′:3′,1″-terphenyl-5′-yl)-9,9,-dimethyl-9H-fluoren-2-amine (Abbreviation: mmtBumTPtBuPAF)

¹H-NMR. δ (CDCl₃): 7.64 (d, 1H, J = 7.5 Hz), 7.59 (d, 1H, J = 8.0 Hz), 7.38-7.43 (m, 4H), 7.29-7.36 (m, 8H), 7.24-7.28 (m, 3H), 7.19 (d, 2H, J = 8.5 Hz), 7.13 (dd, 1H, J = 1.5 Hz, 8.0 Hz), 1.47 (s, 6H), 1.32 (s, 45H).

### Structural Formula (106): N-(1,1′-biphenyl-2-yl)-N-(3,3″,5′,5″-tetra-t-butyl-1,1′:3′,1″-terphenyl-5-yl)-9,9-dimethyl-9H-fluoren-2-amine (Abbreviation: mmtBumTPoFBi-02)

¹H-NMR. δ (CDCl₃): 7.56 (d, 1H, J = 7.4 Hz), 7.50 (dd, 1H, J = 1.7 Hz), 7.33-7.46 (m, 11H), 7.27-7.29 (m, 2H), 7.22 (dd, 1H, J = 2.3 Hz), 7.15 (d, 1H, J = 6.9 Hz), 6.98-7.07 (m, 7H), 6.93 (s, 1H), 6.84 (d, 1H, J = 6.3 Hz), 1.38 (s, 9H), 1.37 (s, 18H), 1.31 (s, 6H), 1.20 (s, 9H).

### Structural Formula (107): N-(4-cyclohexylphenyl)-N-(3,3″,5′,5″-tetra-t-butyl-1,1′:3′,1″-terphenyl-5-yl)-9,9-dimethyl-9H-fluoren-2-amine (Abbreviation: mmtBumTPchPAF-02)

¹H-NMR. δ (CDCl₃): 7.62 (d, 1H, J = 7.5 Hz), 7.56 (d, 1H, J = 8.0 Hz), 7.50 (dd, 1H, J = 1.7 Hz), 7.46 = 7.47 (m, 2H), 7.43 (dd, 1H, J = 1.7 Hz), 7.37 = 7.39 (m, 3H), 7.29 = 7.32 (m, 2H), 7.23 = 7.25 (m, 2H), 7.20 (dd, 1H, J = 1.7 Hz), 7.09-7.14 (m, 5H), 7.05 (dd, 1H, J = 2.3 Hz), 2.46 (brm, 1H), 1.83 = 1.88 (m, 4H), 1.73 = 1.75 (brm, 1H), 1.42 (s, 6H), 1.38 (s, 9H), 1.36 (s, 18H), 1.29 (s, 9H).

### Structural Formula (108): N-(1,1′-biphenyl-2-yl)-N-(3″,5′,5″-tri-t-butyl-1,1′:3′,1″-terphenyl-5-yl)-9,9-dimethyl-9H-fluoren-2-amine (Abbreviation: mmtBumTPoFBi-03)

¹H-NMR. δ (CDCl₃): 7.55 (d, 1H, J = 7.4 Hz), 7.50 (dd, 1H, J = 1.7 Hz), 7.42-7.43 (m, 3H), 7.27-7.39 (m, 10H), 7.18-7.25 (m, 4H), 7.00-7.12 (m, 4H), 6.97 (dd, 1H, J = 6.3 Hz, 1.7 Hz), 6.93 (d, 1H, J = 1.7 Hz), 6.82 (dd, 1H, J = 7.3 Hz, 2.3 Hz), 1.37 (s, 9H), 1.36 (s, 18H), 1.29 (s, 6H).

### Structural Formula (109): N-(4-cyclohexylphenyl)-N-(3″,5′,5″-tri-t-butyl-1,1′:3′,1″-terphenyl-5-yl)-9,9-dimethyl-9H-fluoren-2-amine (Abbreviation: mmtBumTPchPAF-03)

¹H-NMR. δ (CDCl₃): 7.62 (d, 1H, J = 7.5 Hz), 7.56 (d, 1H, J = 8.6 Hz), 7.51 (dd, 1H, J = 1.7 Hz), 7.48 (dd, 1H, J = 1.7 Hz), 7.46 (dd, 1H, J = 1.7 Hz), 7.42 (dd, 1H, J = 1.7 Hz), 7.37-7.39 (m, 4H), 7.27-7.33 (m, 2H), 7.23-7.25 (m, 2H), 7.05-7.13 (m, 7H), 2.46 (brm, 1H), 1.83-1.90 (m, 4H), 1.73-1.75 (brm, 1H), 1.41 (s, 6H), 1.37 (s, 9H), 1.35 (s, 18H).

The substances described above each have an ordinary refractive index higher than or equal to 1.50 and lower than or equal to 1.75 in a blue light emission range (455 nm to 465 nm) or an ordinary refractive index higher than or equal to 1.45 and lower than or equal to 1.70 with respect to light of wavelength 633 nm, which is usually used for measurement of refractive indices.

### REFERENCE NUMERALS

ANO: conductive film, CAP: cap layer, CP: conductive material, FPC1: flexible printed circuit, G1: conductive film, MD: transistor, M21: transistor, N21: node, N22: node, S1g: conductive film, SW21: switch, SW23: switch, TCF: conductive film, VCOM2: conductive film, V0: conductive film, 101: electrode, 102: electrode, 103: unit, 104: layer, 105: layer, 106: middle/intermediate layer, 106A: layer, 106B: layer, 111: layer, 112: layer, 113: layer, 150: light-emitting device, 231: region, 400: substrate, 401: electrode, 403: EL layer, 404: electrode, 405: sealant, 406: sealant, 407: sealing substrate, 412: pad, 420: IC chip, 501C: insulating film, 501D: insulating film, 504: conductive film, 506: insulating film, 508: semiconductor film, 508A: region, 508B: region, 508C: region, 510: base material, 512A: conductive film, 512B: conductive film, 516: insulating film, 516A: insulating film, 516B: insulating film, 518: insulating film, 519B: terminal, 520: functional layer, 521: insulating film, 521A: insulating film, 521B: insulating film, 524: conductive film, 528: insulating film, 530G: pixel circuit, 550G: light-emitting device, 550W: light-emitting device, 551(i, j): electrode, 551G: electrode, 551W: electrode, 552: electrode, 553: ELlayer, 553A: region, 553B: region, 553C: region, 553G: layer, 573: insulating film, 573A: insulating film, 573B: insulating film, 591G: opening portion, 601: source line driver circuit, 602: pixel portion, 603: gate line driver circuit, 604: sealing substrate, 605: sealant, 607: space, 608: wiring, 610: element substrate, 611: switching FET, 612: current control FET, 613: electrode, 614: insulator, 616: EL layer, 617: electrode, 618: light-emitting device, 623: FET, 700: functional panel, 702B: pixel, 702G: pixel, 702R: pixel, 702W: pixel, 703: pixel, 705: sealant, 720: functional layer, 770: base material, 770P: functional film, 771: insulating film, 951: substrate, 952: electrode, 953: insulating layer, 954: partition layer, 955: EL layer, 956: electrode, 1001: substrate, 1002: base insulating film, 1003: gate insulating film, 1006: gate electrode, 1007: gate electrode, 1008: gate electrode, 1020: interlayer insulating film, 1021: interlayer insulating film, 1022: electrode, 1024B: electrode, 1024G: electrode, 1024R: electrode, 1024W: electrode, 1025: partition, 1028: EL layer, 1029: electrode, 1031: sealing substrate, 1032: sealant, 1033: base material, 1034B: coloring layer, 1034G: coloring layer, 1034R: coloring layer, 1035: black matrix, 1036: overcoat layer, 1037: interlayer insulating film, 1040: pixel portion, 1041: driver circuit portion, 1042: peripheral portion, 2001: housing, 2002: light source, 2100: robot, 2101: illuminance sensor, 2102: microphone, 2103: upper camera, 2104: speaker, 2105: display, 2106: lower camera, 2107: obstacle sensor, 2108: moving mechanism, 2110: arithmetic device, 3001: lighting device, 5000: housing, 5001: display portion, 5002: display portion, 5003: speaker, 5004: LED lamp, 5006: connection terminal, 5007: sensor, 5008: microphone, 5012: support, 5013: earphone, 5100: cleaning robot, 5101: display, 5102: camera, 5103: brush, 5104: operation button, 5120: dust, 5140: portable electronic device, 5200: display region, 5201: display region, 5202: display region, 5203: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: display portion, 7401: housing, 7402: display portion, 7403: operation button, 7404: external connection port, 7405: speaker, 7406: microphone, 9310: portable information terminal, 9311: display panel, 9313: hinge, 9315: housing

1. A light-emitting device comprising:
a first electrode;
a second electrode; and
an EL layer between the first electrode and the second electrode,
wherein the first electrode has a first transmittance,
wherein the second electrode comprises a region overlapping with the first electrode,
wherein the second electrode has a second transmittance,
wherein the second transmittance is higher than the first transmittance,
wherein the EL layer comprises a first region, a second region, and a third region,
wherein the first region comprises a portion interposed between the second region and the third region,
wherein the second region comprises a region interposed between the first electrode and the first region,
wherein the second region has a first refractive index,
wherein the third region comprises a region interposed between the first region and the second electrode,
wherein the third region has a second refractive index,
wherein the second refractive index is lower than the first refractive index,
wherein the EL layer comprises a first unit, a second unit, and an intermediate layer,
wherein the intermediate layer is interposed between the first unit and the second unit,
wherein the intermediate layer is configured to supply a hole to one of the first unit and the second unit and supply an electron to the other of the first unit and the second unit,
wherein the first unit is interposed between the first electrode and the intermediate layer,
wherein the first unit comprises a first layer comprising a first light-emitting material,
wherein the second unit is interposed between the intermediate layer and the second electrode,
wherein the second unit comprises a second layer comprising a second light-emitting material, and
wherein the first region comprises the first layer and the second layer .

2. The light-emitting device according to claim 1,
wherein the first layer is configured to emit blue light, and
wherein the second layer is configured to emit blue light.

3. The light-emitting device according to claim 1,
wherein the second unit comprises a third layer comprising a third light-emitting material,
wherein the first layer is configured to emit blue light,
wherein the second layer is configured to emit red light, and
wherein the third layer is configured to emit green light.

4. The light-emitting device according to claim 1
wherein the third region has a more excellent electron-transport property than the second region.

5. The light-emitting device according to claim 1,
wherein the third region has a more excellent hole-transport property than the second region.

6. A display panel comprising:
a functional layer; and
a pixel,
wherein the functional layer comprises a pixel circuit,
wherein the pixel comprises the pixel circuit and the light-emitting device according to claim 1,
wherein the first electrode comprises a region interposed between the functional layer and the second electrode, and
wherein the first electrode is electrically connected to the pixel circuit.

7. A light-emitting apparatus comprising:
the light-emitting device according to claim 1 ; and
a transistor or a substrate.

8. A display device comprising:
the light-emitting device according to claim 1 ; and
at least one of a transistor and a substrate.

9. A lighting device comprising:
the light-emitting apparatus according to claim 7; and
a housing.

10. An electronic device comprising:
the display device according to claim 8; and
at least one of a sensor, an operation button, a speaker, and a microphone.
